(19) United States
(12) Patent Application Publication
(10) Pub. No.: US 2026/0330074 A1
(43) Pub. Date: Oct. 22, 2026

(54) SHAPE SYSTEMS AND METHODS

(71) Applicant: Georgia Tech Research Corporation, Atlanta, GA (US)

(72) Inventors: Athanassios Economou, Atlanta, GA (US); Russell Newton, Atlanta, GA (US)

(21) Appl. No.: 19/638,697

(22) Filed: Apr. 3, 2026

Related U.S. Application Data
(60) Provisional application No. 63/783,271, filed on Apr. 4, 2025.

(51) Int. Cl. G06F 30/10

(52) U.S. Cl. CPC G06F 30/10

(57) ABSTRACT

The present disclosure relates generally to computer-aided design systems and more particularly to shape embedding and shape replacement. A system includes processors and memory storing instructions causing the system to receive, via a communication layer, a shape rule including a left-hand-side shape and a right-hand-side shape and a design including geometric elements. The system converts geometric elements into a maximal element representation by grouping elements on equivalent carriers and computing an average carrier for each group, derives registration points from carrier intersections, calculates weights for registration points based on geometric features of intersecting maximal elements, and ranks registration points to reduce a search space. The system computes transformation matrices by matching registration points of the left-hand-side shape to design registration points, determines whether the left-hand-side shape is embedded under a geometric transformation, and applies the shape rule using Boolean difference and union operations.

### CROSS-REFERENCE TO RELATED APPLICATIONS

This application claims the benefit of U.S. Provisional Application Ser. No. 63/783,271, filed on 4 Apr. 2025, which is incorporated herein by reference in its entirety as if fully set forth below.

### FIELD OF INVENTION

The present disclosure relates to computer-aided design systems and shape grammar interpreters, and more particularly to systems and methods for shape embedding and shape replacement in generative modeling within computer-aided design environments.

### BACKGROUND

Computer-aided design (CAD) systems have become integral tools in architectural, engineering, and manufacturing workflows. These systems enable designers to create, modify, and analyze digital representations of physical objects and structures. As design processes have evolved, there has been growing interest in generative modeling approaches that can automate aspects of design exploration and manipulation.

Shape grammars represent one approach to generative design that emphasizes visual rules over symbolic programming instructions. In shape grammar systems, designers define shape rules that specify how one shape configuration can be transformed into another. The application of these rules to a design involves finding instances of a query shape within a larger design and replacing those instances according to the rule specification. This find-and-replace paradigm offers an intuitive approach to design manipulation that aligns with how designers naturally think about form and composition.

Despite the theoretical appeal of shape grammar approaches, their practical implementation in CAD environments presents numerous challenges. One fundamental difficulty arises from the gap between the continuous nature of geometric representations and the discrete numerical precision available in digital computing systems. Shapes represented as geometric primitives such as points, lines, and curves are constructed on the real number system, yet digital environments can only provide limited precision to represent numerical values. This limitation can lead to precision errors that accumulate throughout computation processes, affecting operations from shape instantiation to geometric Boolean operations.

The process of shape embedding, which involves determining whether and how one shape can be found within another under various geometric transformations, presents additional computational challenges. Different transformation types, including isometries, similarities, affine transformations, and linear transformations, require different numbers of reference points to compute the necessary transformation matrices. The computational complexity of shape embedding operations can increase significantly as the number of geometric elements in a design grows, potentially limiting the practical applicability of shape grammar systems for complex designs.

Furthermore, certain embedding scenarios may be indeterminate when a query shape does not contain sufficient geometric information to fully specify the transformation parameters. These indeterminate cases require special handling to produce meaningful results while maintaining computational tractability.

Integrating shape grammar capabilities within existing CAD systems presents its own set of challenges, as the internal representations used by CAD systems may not readily support the computations required for shape embedding and replacement operations. Therefore, improved systems and methods for shape computation within CAD environments are desired.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

A system for shape computation in a computer-aided design environment can include one or more processors and a memory storing instructions. The instructions, when executed by the one or more processors, can cause the system to receive, via a communication layer, a shape rule including a left-hand-side shape and a right-hand-side shape from a computer-aided design application. The instructions can cause the system to receive, via the communication layer, a design including a plurality of geometric elements. The instructions can cause the system to convert the plurality of geometric elements into a maximal element representation by grouping elements on equivalent carriers and computing an average carrier for each group. The instructions can cause the system to derive registration points from intersections of carriers associated with the maximal element representation. The instructions can cause the system to calculate a weight for each registration point based on geometric features of maximal elements intersecting at the registration point. The instructions can cause the system to rank the registration points based on the calculated weights to reduce a search space for shape embedding. The instructions can cause the system to compute one or more transformation matrices by matching registration points of the left-hand-side shape to registration points of the design. The instructions can cause the system to determine whether the left-hand-side shape is embedded in the design under a geometric transformation defined by the one or more transformation matrices. The instructions can cause the system to apply the shape rule to the design by performing a Boolean difference operation to remove a transformed instance of the left-hand-side shape from the design and performing a Boolean union operation to add a corresponding transformed instance of the right-hand-side shape to the design.

A method for shape embedding and shape replacement in a computer-aided design system can include receiving, by one or more processors, a shape rule including a left-hand-side shape and a right-hand-side shape. The method can include receiving, by the one or more processors, a design including a plurality of geometric elements from a computer-aided design application. The method can include maximizing, by the one or more processors, the plurality of geometric elements by grouping elements on equivalent carriers and replacing each group with a minimal number of maximal elements. The method can include calibrating, by the one or more processors, the maximal elements by computing an average carrier for each group and projecting element boundaries onto the average carrier. The method can include computing, by the one or more processors, registration points at intersections of carriers associated with the maximal elements. The method can include calculating, by the one or more processors, a weight for each registration point based on a number of hyperplanes and maximal elements intersecting at the registration point. The method can include ranking, by the one or more processors, the registration points based on the calculated weights. The method can include sampling, by the one or more processors, registration points from the left-hand-side shape and the design based on the ranking. The method can include deriving, by the one or more processors, transformation matrices from the sampled registration points. The method can include determining, by the one or more processors, whether the left-hand-side shape is embedded in the design under a transformation defined by the transformation matrices. The method can include applying, by the one or more processors, the shape rule by subtracting a transformed left-hand-side shape from the design and adding a transformed right-hand-side shape to the design.

A non-transitory computer-readable medium can store instructions that, when executed by one or more processors, cause the one or more processors to receive a shape rule including a left-hand-side shape and a right-hand-side shape from a computer-aided design application via a communication layer. The instructions can cause the one or more processors to receive a design including geometric elements from the computer-aided design application. The instructions can cause the one or more processors to convert the geometric elements into a maximal element representation including maximal lines, maximal arcs, or maximal points by grouping elements on equivalent carriers, computing an average carrier for each group, and replacing each group with a minimal number of maximal elements having the average carrier. The instructions can cause the one or more processors to compute a shape signature for the design, the shape signature including registration points derived from carrier intersections and registration point weights based on geometric features at each registration point. The instructions can cause the one or more processors to match registration points of the left-hand-side shape to registration points of the design to compute candidate transformation matrices. The instructions can cause the one or more processors to verify each candidate transformation matrix by applying the transformation to the left-hand-side shape and checking whether the transformed shape is embedded in the design. The instructions can cause the one or more processors to apply the shape rule by performing Boolean operations to subtract a transformed left-hand-side shape from the design and add a transformed right-hand-side shape to the design.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIGS. 1A-1G illustrate a shape computation process, according to examples of the disclosed technology.

FIG. 2A illustrates an identity transformation applied to a shape, according to examples of the disclosed technology.

FIG. 2B illustrates direct linear transformations applied to a shape, according to examples of the disclosed technology.

FIG. 2C illustrates indirect linear transformations applied to a shape, according to examples of the disclosed technology.

FIG. 3A illustrates an equilateral triangle represented in an ideal Cartesian plane, according to examples of the disclosed technology.

FIG. 3B illustrates an equilateral triangle represented in a CAD system with limited precision, according to examples of the disclosed technology.

FIGS. 4A-4E illustrate shape configurations and registration points, according to examples of the disclosed technology.

FIG. 4F illustrates instances of an embedding schema with different scaling assignments, according to examples of the disclosed technology.

FIG. 5A illustrates an architectural plan comprising maximal lines, according to examples of the disclosed technology.

FIG. 5B illustrates the architectural plan of FIG. 5A with registration points marked, according to examples of the disclosed technology.

FIG. 6 is a block diagram of an example computing device architecture 100 used to provide shape computation in a computer-aided design environment, according to examples of the disclosed technology.

FIG. 7 is a block diagram of an example system that may be used to provide shape computation in a computer-aided design environment, according to examples of the disclosed technology. The system includes a Shape Machine 200, a communication layer 300, a shape rule compiler 400, a design initializer 500, a maximal line modeler 600, a shape embedding engine 700, and a rule application unit 800.

FIG. 8 illustrates a communication layer 300 including shape loading 310, parameter loading 320, shape visualizing 330, and compiling/display messages 340, according to examples of the disclosed technology.

FIG. 9 illustrates a shape rule and a corresponding design, according to examples of the disclosed technology.

FIG. 10 illustrates a shape rule compiler 400 including a shape rule unpacking process 410, a parameter fetching process 420, an attribute fetching process 430, an endpoint extraction process 440, a hyperplane derivation process 450, a hyperplane grouping process 460, and a data packaging process 470, according to examples of the disclosed technology.

FIG. 11 illustrates a data structure of a shape comprising lines, according to examples of the disclosed technology.

FIG. 12 illustrates a design initializer 500 including an attributes fetching process 510, an endpoint coordinate extracting process 520, a hyperplane derivation process 530, a data grouping process 540, and a packing process 550, according to examples of the disclosed technology.

FIGS. 13A-13B illustrate a maximal line modeler 600 including a line relationships checking process 610, a line grouping process 620, and a boolean union with calibration process 630, according to examples of the disclosed technology.

FIG. 14A illustrates a data structure of lines before processing by a maximal line modeler 600, according to examples of the disclosed technology.

FIG. 14B illustrates a data structure of lines after processing by a maximal line modeler 600, according to examples of the disclosed technology.

FIG. 15 illustrates a shape embedding engine 700 including a registration point derivation and reduction process 710, a registration point weight calculation process 720, a registration point ranking process 730, a registration point sampling process 740, a derivation of transformation matrices process 750, a process for intermediate embedding process 760, an LHS candidates generating process 770, an embedding checking process 780, an RHS candidate generating process 790, and an equivalency reduction process 795, according to examples of the disclosed technology.

FIG. 16 illustrates a rule application unit 800 including a single-application process 810, an all-application process 820, an each-application process 830, and an all-preview printing process 840, according to examples of the disclosed technology.

FIG. 17 illustrates calibration tolerance between two lines, according to examples of the disclosed technology.

FIG. 18A illustrates two collinear lines without precision error, according to examples of the disclosed technology.

FIG. 18B illustrates two collinear lines with precision error, according to examples of the disclosed technology.

FIG. 19 illustrates maximization of lines with a calibration process, according to examples of the disclosed technology.

FIG. 20A illustrates two lines before a maximization process, according to examples of the disclosed technology.

FIG. 20B illustrates two lines after a maximization process with calibration, according to examples of the disclosed technology.

FIGS. 21A-21B illustrate collinear lines before and after a Boolean difference operation, according to examples of the disclosed technology.

FIGS. 22A-22F illustrate geometric operations, according to examples of the disclosed technology.

FIG. 23A illustrates registration points for deriving a linear transformation, according to examples of the disclosed technology.

FIG. 23B illustrates targeted registration points for deriving a linear transformation, according to examples of the disclosed technology.

FIG. 24 illustrates steps of a pictorial approach to derive a transformation for shape embedding, according to examples of the disclosed technology.

FIG. 25 illustrates additional steps of a pictorial approach to derive a transformation for shape embedding, according to examples of the disclosed technology.

FIGS. 26A-26D illustrate results of a pictorial approach for derivation of linear transformation, according to examples of the disclosed technology.

FIGS. 27A-27D illustrate registration point embedding and hyperplane arrangements for shape embedding operations, according to examples of the disclosed technology.

FIG. 28 illustrates shape embedding results under similar transformation, according to examples of the disclosed technology.

FIG. 29A illustrates a shape comprising maximal lines embedded in hyperplanes, according to examples of the disclosed technology.

FIG. 29B illustrates a registration point intersected by maximal lines embedded in hyperplanes, according to examples of the disclosed technology.

FIG. 30A illustrates a registration point not occurring on a maximal line, according to examples of the disclosed technology.

FIG. 30B illustrates a registration point occurring on an endpoint of a maximal line, according to examples of the disclosed technology.

FIG. 30C illustrates a registration point occurring on the body of a maximal line, according to examples of the disclosed technology.

FIG. 31A illustrates normalized maximal lines intersecting at a registration point for a first hyperplane, according to examples of the disclosed technology.

FIG. 31B illustrates normalized maximal lines intersecting at a registration point for a second hyperplane, according to examples of the disclosed technology.

FIG. 31C illustrates normalized maximal lines intersecting at a registration point for a third hyperplane, according to examples of the disclosed technology.

FIGS. 32A-32D illustrate supersets of a normalized weight of a registration point, according to examples of the disclosed technology.

FIGS. 32E-32H illustrate additional supersets of a normalized weight of a registration point, according to examples of the disclosed technology.

FIG. 33 illustrates a data representation of the weight of a registration point, according to examples of the disclosed technology.

FIG. 34A illustrates a registration point at which hyperplanes intersect, according to examples of the disclosed technology.

FIG. 34B illustrates a normalized form of the registration point of FIG. 34A, according to examples of the disclosed technology.

FIG. 35A illustrates a fitting process for embedding registration points, according to examples of the disclosed technology.

FIG. 35B illustrates a cyclic fitting process for embedding registration point weights, according to examples of the disclosed technology.

FIG. 35C illustrates a continuation of the cyclic fitting process of FIG. 35B, according to examples of the disclosed technology.

FIG. 35D illustrates fitting an item into a data structure during shape computation, according to examples of the disclosed technology.

FIG. 36A illustrates a circular diagram with line segments and hyperplane indicators, according to examples of the disclosed technology.

FIG. 36B illustrates a circular diagram with line segments and registration points, according to examples of the disclosed technology.

FIG. 36C illustrates a circular diagram with line segments and hyperplane indicators, according to examples of the disclosed technology.

FIG. 37 is a flow diagram for a method for shape embedding and shape replacement in a computer-aided design system, according to examples of the disclosed technology.

FIG. 38 illustrates spatial relations between two collinear lines, according to examples of the disclosed technology.

FIG. 39 illustrates transformation types and registration point configurations, according to examples of the disclosed technology.

FIG. 40 illustrates Ptolemy's construction of a regular pentagon inscribed in a circle, according to examples of the disclosed technology.

FIG. 41 illustrates types of intersection points based on spatial relations between descriptors, according to examples of the disclosed technology.

FIGS. 42-43 illustrate application of a rule schema on shapes to produce intersection points, according to examples of the disclosed technology.

FIG. 44 illustrates geometric constructions for intersection point derivation, according to examples of the disclosed technology.

FIG. 45 illustrates shape rules and symbolic rules for implementation of shape operations, according to examples of the disclosed technology.

FIGS. 46-47 illustrate construction of a perpendicular bisector, according to examples of the disclosed technology.

FIG. 48 illustrates construction of a perpendicular bisector parallel to a previously constructed bisector, according to examples of the disclosed technology.

FIG. 49 illustrates a sequence of geometric constructions with elliptical shapes, according to examples of the disclosed technology.

FIG. 50 illustrates Ptolemy's method for inscribing a regular pentagon within a circle, according to examples of the disclosed technology.

FIG. 51 illustrates a construction process for establishing geometric relationships, according to examples of the disclosed technology.

FIG. 52 illustrates derivation of a point on a circle with equal distance relationships, according to examples of the disclosed technology.

FIG. 53 illustrates shape transformation steps for determining a point on a circle, according to examples of the disclosed technology.

FIG. 54 illustrates Ptolemy's method for inscribing a regular pentagon with auxiliary circles, according to examples of the disclosed technology.

FIG. 55 illustrates construction steps for building sides of a regular pentagon, according to examples of the disclosed technology.

FIG. 56 illustrates three families of Gothic rosette patterns, according to examples of the disclosed technology.

FIG. 57 illustrates progressive division of a circle into equal sectors, according to examples of the disclosed technology.

FIG. 58 illustrates inscription of a circle within a circular sector, according to examples of the disclosed technology.

FIG. 59 illustrates rules for implementation of an inscribed circle in a circle sector, according to examples of the disclosed technology.

FIG. 60 illustrates construction of a bisector of an angle, according to examples of the disclosed technology.

FIG. 61 illustrates a sequence diagram for a bisector construction process, according to examples of the disclosed technology.

FIG. 62 illustrates construction of a line perpendicular to a bisector and tangent to a circle, according to examples of the disclosed technology.

FIG. 63 illustrates construction of three circles with specified center points, according to examples of the disclosed technology.

FIG. 64 illustrates a sequence of geometric construction steps using circles and lines, according to examples of the disclosed technology.

FIG. 65 illustrates construction steps for creating an inscribed circle within a circular sector, according to examples of the disclosed technology.

FIG. 66 illustrates construction of an inscribed circle in a sector, according to examples of the disclosed technology.

FIG. 67 illustrates construction steps for an inscribed circle within a Gothic Rosette window, according to examples of the disclosed technology.

FIG. 68 illustrates variations of scaffolds for Gothic rosette patterns, according to examples of the disclosed technology.

FIG. 69 illustrates progressive development of circular rosette patterns, according to examples of the disclosed technology.

FIGS. 70-71 illustrate variations of circular shapes divided into sectors with inscribed elements, according to examples of the disclosed technology.

FIG. 72 illustrates a geometric construction with a circle and inscribed quadrilateral, according to examples of the disclosed technology.

FIG. 73 illustrates shape grammar rules for constructing a foil motif, according to examples of the disclosed technology.

FIG. 74 illustrates variations of n-foil Gothic rosette windows, according to examples of the disclosed technology.

FIG. 75 is a flow diagram for a method for shape embedding and shape replacement in a computer-aided design system, according to examples of the disclosed technology.

FIG. 76 is a flow diagram for a method for shape embedding and shape replacement in a computer-aided design system, according to examples of the disclosed technology.

FIG. 77 is a flow diagram for a method for shape embedding and shape replacement in a computer-aided design system, according to examples of the disclosed technology.

FIG. 78 illustrates two arcs undergoing calibration and maximization, according to examples of the disclosed technology.

FIG. 79 illustrates two arcs with angular boundary ranges, according to examples of the disclosed technology.

FIG. 80 illustrates a shape made of points before calibration and maximization, according to examples of the disclosed technology.

FIG. 81 illustrates a shape made of calibrated points, according to examples of the disclosed technology.

FIG. 82 illustrates a shape made of points, lines, and arcs, according to examples of the disclosed technology.

FIG. 83 illustrates carriers and registration point locations of a shape, according to examples of the disclosed technology.

FIG. 84 illustrates registration point signatures corresponding to registration points of a shape, according to examples of the disclosed technology.

FIG. 85 illustrates a hypergraph incidence matrix, according to examples of the disclosed technology.

FIG. 86 illustrates shape elements and their relationships within a shape computation system, according to examples of the disclosed technology.

FIG. 87 illustrates signatures of a design and queries for shape embedding calculations, according to examples of the disclosed technology.

FIG. 88 illustrates stages of a shape embedding process with phantom registration points, according to examples of the disclosed technology.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

A detailed description of systems, devices, and methods consistent with embodiments of the present disclosure is provided below. While several embodiments are described, it should be understood that disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

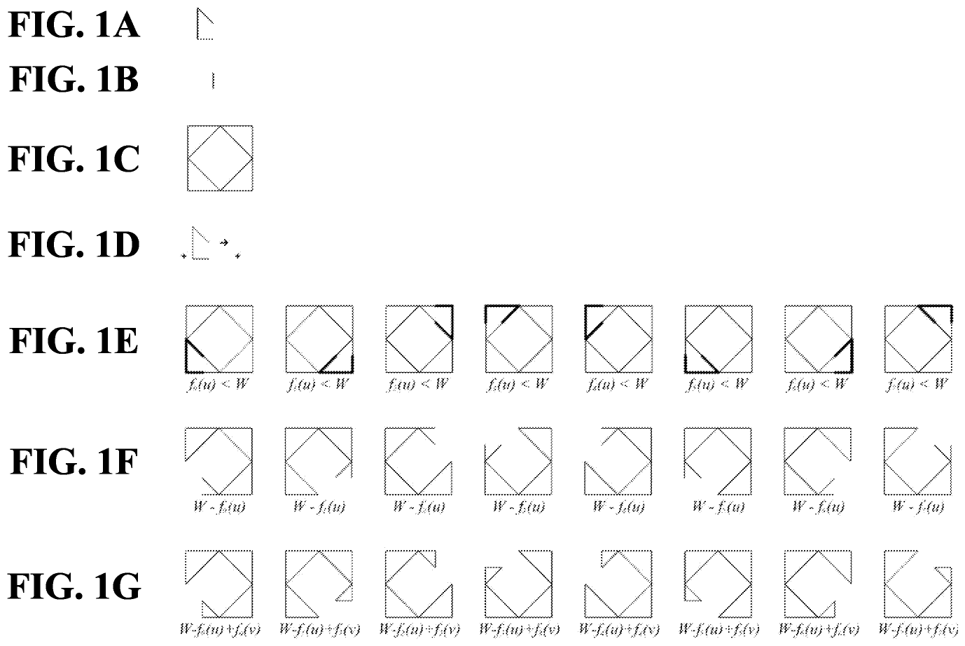

Referring to FIGS. 1A-1G, a shape computation process can involve the recognition and replacement of shapes within a design under various geometric transformations. Shape computation can be implemented through five distinct processes that operate on shapes to perform shape embedding and shape replacement operations.

FIGS. 1A-1C illustrate three shapes u, v, and W that can be used in a shape computation. Shape u, shown in FIG. 1A, can comprise two line segments forming an angular configuration. Shape v, shown in FIG. 1B, can comprise a single vertical line segment. Shape W, shown in FIG. 1C, can comprise a square with two diagonal lines crossing through the center of the square, forming an X pattern within the square boundary. Shape W can be referred to herein as a design, and shapes u and v can be referred to herein as a left-hand-side shape and a right-hand-side shape, respectively.

FIG. 1D illustrates a shape rule u-v that specifies a transformation from the left-hand-side shape u to the right-hand-side shape v. The shape rule can define how one shape configuration can be transformed into another shape configuration. The shape rule can include a rule template that separates the left-hand-side shape from the right-hand-side shape.

With continued reference to FIGS. 1A-1G, a shape grammar interpreter can process the shape rule by performing the following operations. First, the shapes u, v, and W can be encoded in a maximal element representation, which can specify each shape using a minimal number of basic elements. Second, the system can inquire whether there is a transformation f that embeds the shape f(u) in W, where f(u) represents the left-hand-side shape u transformed under the transformation f. Third, if such a transformation exists, the system can subtract the shape f(u) from W. Fourth, the system can add the shape f(v) to the result W−f(u). Fifth, the system can repeat these processes for all applicable transformations of the shape f(u) in W.

FIG. 1E illustrates eight matches of the shape f(u) in W. Each match corresponds to a different transformation fᵢ that embeds the left-hand-side shape u within the design W. In the example shown, the shape rule can be applied under an isometric transformation, which can keep shape and size invariant while varying handedness and position. The eight transformations f₀ through f₇ can each embed the shape f(u) in the shape W, making the shape f(u) part of the shape W.

FIG. 1F illustrates the subtractions of the eight instances of the shape f(u) from W. Each subtraction operation can remove a transformed instance of the left-hand-side shape from the design, resulting in eight intermediate shapes W−fᵢ(u). The subtraction operation can be implemented as a Boolean difference operation between the design W and the transformed left-hand-side shape fᵢ(u).

FIG. 1G illustrates the additions of the eight instances of the shape f(v) to the corresponding eight instances of the shape W−f(u). Each addition operation can add a transformed instance of the right-hand-side shape to the intermediate result, producing eight final shapes W−fᵢ(u)+fᵢ(v). The addition operation can be implemented as a Boolean union operation between the intermediate shape W-fᵢ(u) and the transformed right-hand-side shape fᵢ(v).

The formal expression for the shape computation operation can be written as: if f(u)≤W, then W=W−f(u)+f(v), where the symbol ≤ denotes the part relation indicating that the transformed shape f(u) is embedded in the design W. After N iterations of the shape rule application, the result can be expressed as W minus the sum of all fᵢ(u) plus the sum of all fᵢ(v), where fᵢ( ) represents the applied transformation for the i^{th} iteration.

The transformation f can be a Euclidean transformation, an affine transformation, or a linear transformation. Euclidean transformations can include isometries that preserve distances, such as translation, rotation, and reflection. Similarity transformations can extend isometries to include uniform scaling. Affine transformations can further extend similarity transformations to include stretching and shearing. Linear transformations can encompass all of the above and additionally include perspectivity transformations. A 3×3 matrix can be used to represent transformations up to linear transformations in two-dimensional space.

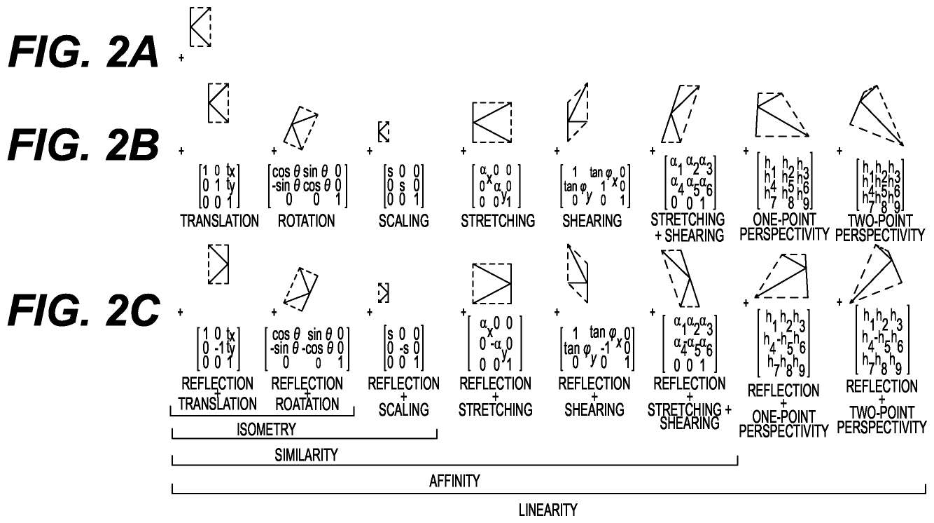

Referring to FIGS. 2A-2C, linear transformations can be applied to shapes in two-dimensional space to enable shape embedding and shape replacement operations. A 3×3 matrix can be used to represent transformations up to linear transformations in two-dimensional space, and the corresponding calculation of transformations between two shapes can be performed by the derivation of a 3×3 matrix.

FIG. 2A illustrates an identity transformation where a shape remains unchanged. The identity transformation can preserve all geometric properties of the shape including position, orientation, and size.

FIG. 2B illustrates direct transformations that can be applied to shapes. The direct transformations shown from left to right include translation, rotation, scale, stretch, shear, one-point perspective, and two-point perspective. Translation can shift the position of a shape without changing the shape's orientation or size. Rotation can change the angular orientation of a shape about a point. Scale can uniformly change the size of a shape. Stretch can non-uniformly scale a shape along different axes. Shear can introduce angular distortion to a shape. One-point perspective and two-point perspective can introduce perspectival distortions to a shape.

FIG. 2C illustrates indirect or handed versions of the transformations shown in FIG. 2B. The indirect transformations can incorporate reflection operations combined with the direct transformations. The indirect transformations include reflection combined with translation, reflection combined with rotation, reflection combined with scaling, reflection combined with stretching, reflection combined with shearing, reflection combined with one-point perspectivity, and reflection combined with two-point perspectivity.

With continued reference to FIGS. 2A-2C, the transformations can be organized into hierarchical categories based on the geometric properties that the transformations preserve. Isometries can preserve distances and can include translation, rotation, and reflection operations. Similarity transformations can extend isometries to include uniform scaling while preserving angles. Affine transformations can further extend similarity transformations to include stretching and shearing while preserving parallelism. Linear transformations can encompass all of the above categories and can additionally include perspectivity transformations.

To derive a 3×3 isometry matrix that represents isometric transformations, two points from a left-hand-side shape u and two points from a design W can be used to resolve three unknown variables including a rotation angle θ, a translation vector in the x direction tₓ, and a translation vector in the y direction t_{y}.

To derive a 3×3 similarity matrix that represents similarity transformations, two points from the left-hand-side shape u and two points from the design W can be used to resolve four unknown variables including a scaling factor s, the rotation angle θ, the translation vector in the x direction tₓ, and the translation vector in the y direction t_{y}.

To derive a 3×3 affine matrix that represents affine transformations, three points from the left-hand-side shape u and three points from the design W can be used to resolve unknown variables contained in the matrix. The affine matrix can include stretching factors αₓ and α_{y} representing stretching in the x direction and y direction, and shearing angles φₓ and φ_{y} representing shearing in the x direction and y direction.

To derive a 3×3 homography matrix that represents linear transformations including perspectivities, four points from the left-hand-side shape u and four points from the design W can be used to derive nine unknown variables contained in the matrix.

A transformation between two shapes can be represented as a product of a sequence of component transformations. For isometric transformations, the transformation can be represented as a product of a sequence of reflection, translation, and rotation. For similarity transformations, the transformation can be represented as a product of a sequence of reflection, translation, rotation, and scaling. For affine transformations, the transformation can be represented as a product of a sequence of reflection, translation, rotation, scaling, shearing, and stretching. For linear transformations including perspectivities, the transformation can be represented as a product of a sequence of reflection, translation, rotation, scaling, one-point perspectival transformation, and two-point perspectival transformation.

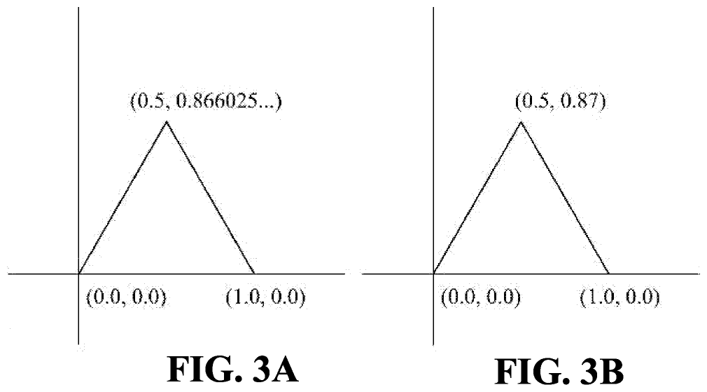

Referring to FIGS. 3A-3B, precision errors in CAD systems can present challenges for shape computation. A gap can exist between the continuum of geometries and the discreteness of digital infrastructure. Shapes represented as geometries such as points, lines, and curves can be constructed on the real number system. However, digital environments such as CAD systems can only provide limited digits to represent real numerical values, and precision errors can show up and accumulate in the computation.

FIG. 3A illustrates three endpoints of an equilateral triangle represented in an ideal Cartesian plane. In the ideal representation, the three vertices of the equilateral triangle can be located at coordinates (0.0, 0.0), (1.0, 0.0), and (0.5, 0.866025 . . . ), where the y-coordinate of the apex can be an irrational number representing the square root of three divided by two.

FIG. 3B illustrates three endpoints of an equilateral triangle represented in a Cartesian plane of a CAD system with a resolution of 0.01 unit. In the CAD system representation, the three vertices can be located at coordinates (0.0, 0.0), (1.0, 0.0), and (0.5, 0.87), where the y-coordinate of the apex can be truncated to two decimal places due to the limited precision available in the digital environment.

With continued reference to FIGS. 3A-3B, the comparison between the ideal representation and the CAD system representation demonstrates how the continuous nature of geometric values in an ideal mathematical representation can differ from the discrete approximation required in digital CAD environments, where precision can be limited by the system's numerical resolution.

In general, precision errors can be ignored in the modeling process, since the precision errors in CAD systems can be smaller than the precision errors in manufacture processes. Nevertheless, precision errors may not be allowed in shape computation as this type of computation can be based on zero tolerance. For example, a conditional statement that checks whether a variable equals a specific value may not execute as expected when the variable contains a value that differs from the target by a small precision error, regardless of how close the value is to the target.

Rounding errors can be accumulated throughout the entire computation process from the instantiations of shapes, to the mechanisms checking the relationships among these shapes, and the shape Boolean operations included for the maximal representation of these shapes, rendering the computation process unstable and unreliable.

The precision errors can affect multiple stages of shape computation. During shape instantiation, the coordinates of geometric elements can be subject to floating-point representation limitations. During relationship checking, comparisons between geometric elements can produce incorrect results when precision errors cause values that should be equal to differ slightly. During Boolean operations, the accumulation of precision errors can cause operations such as union and difference to produce unexpected results.

The implementation of shape embedding under linear transformations, including isometric, similar, affine and perspectival transformations, through the derivation of a 3×3 homography matrix can include complicated computations that can produce precision errors and incorrect matchings. These problems can be exacerbated in the calculations of perspectival transformations.

The derivation of a planar homography matrix can involve heavy calculations that can cause a precision problem because of the accumulation of rounding errors. The derivation of a 3×3 matrix can work for all linear transformations, but the heavy computation load, especially for perspectival transformations, can cause precision errors which may not be recoverable easily by calibration mechanisms.

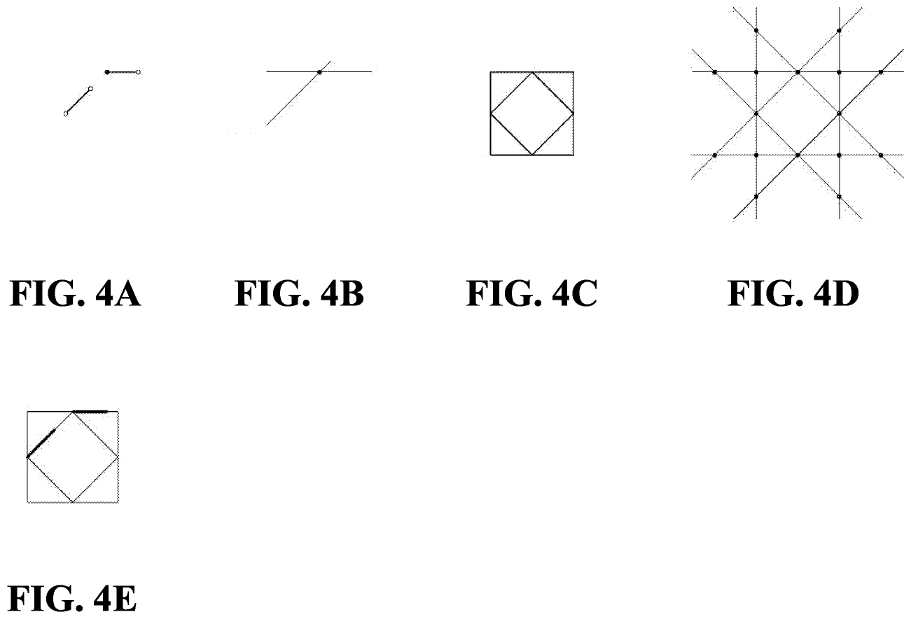

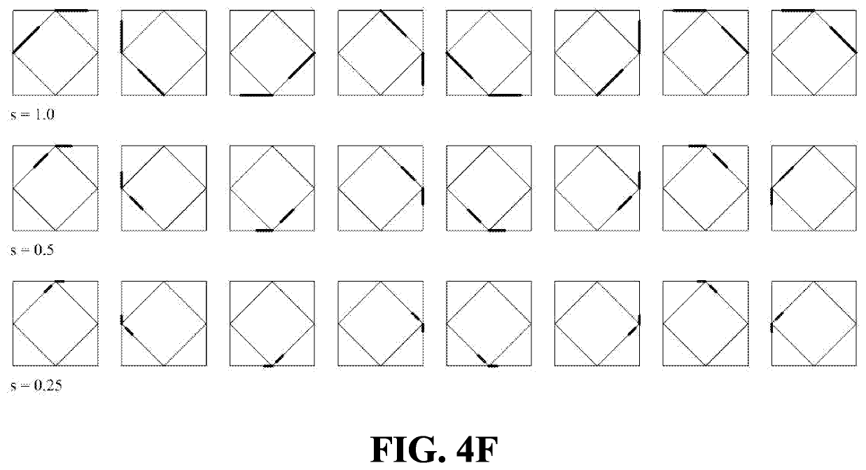

Referring to FIGS. 4A-4E, shape configurations and registration points can be used in shape embedding calculations. Registration points can be derived from intersections of carriers associated with geometric elements in a shape. The registration points can serve as reference marks for computing transformation matrices during shape embedding operations.

FIG. 4A illustrates a first shape configuration comprising two short line segments meeting at an angle with small circles at endpoints of the line segments. The two line segments can form an angular configuration. The endpoints of the line segments can be represented by the small circles.

FIG. 4B illustrates a second shape configuration comprising two longer line segments intersecting at an angle. The two line segments can form a more extended angular shape compared to the configuration shown in FIG. 4A.

FIG. 4C illustrates a third shape configuration comprising a square with a diamond shape inscribed within the square. The diamond shape can be a square rotated approximately forty-five degrees relative to the outer square. The vertices of the diamond can touch or approach the midpoints of the sides of the outer square.

FIG. 4D illustrates a fourth shape configuration comprising a grid-like pattern of intersecting lines. The grid-like pattern can include horizontal, vertical, and diagonal lines that cross at regular intervals. Small dots can mark intersection points throughout the configuration. The intersection points can represent registration points derived from the carriers of the line elements. The registration points can be created at locations where two or more carriers intersect.

FIG. 4E illustrates a fifth shape configuration comprising a square with internal diagonal lines connecting opposite corners and lines connecting midpoints of opposite sides. The internal lines can create a pattern of triangular subdivisions within the square boundary.

With continued reference to FIGS. 4A-4E, registration points can be computed from intersections of carriers in a shape. A carrier can be a hyperplane that extends beyond the actual geometric boundaries of a shape element. For line elements, the carrier can be a line that extends infinitely in both directions along the direction of the line element. Registration points can occur at locations where two or more carriers intersect.

The registration points can be used to establish correspondences between a query shape and a design shape during shape embedding calculations. A shape embedding engine 700 can derive registration points from the carriers associated with maximal elements in both a left-hand-side shape and a design. The shape embedding engine 700 can then match registration points of the left-hand-side shape to registration points of the design to compute candidate transformation matrices.

The number of registration points in a shape can depend on the number of carriers and the geometric relationships among the carriers. As shown in FIG. 4D, a shape with multiple intersecting lines can produce a large number of registration points at the various intersection locations. The registration points can be weighted based on geometric features of the maximal elements intersecting at each registration point. The weights can be used to rank the registration points and reduce a search space for shape embedding operations.

In some cases, a shape can have fewer registration points than required to derive a transformation matrix for a specified transformation type. For example, a similarity transformation can require two registration points to resolve four unknown variables including a rotation angle, translation in an x direction, translation in a y direction, and a scaling factor. When a left-hand-side shape has fewer than two registration points, the embedding can be indeterminate under similarity transformation. The shape embedding engine 700 can detect such indeterminate embedding conditions and can request additional input to specify values for indeterminate transformation parameters.

Referring to FIG. 4F, instances of an embedding schema with different scaling assignments can be illustrated. FIG. 4F can depict a grid of geometric diagrams arranged in three rows and nine columns, where each diagram shows a square oriented at forty-five degrees (diamond orientation) containing internal line segments in various configurations. The three rows can correspond to different scaling parameter values, with s=1.0 for the top row, s=0.5 for the middle row, and s=0.25 for the bottom row. Within each row, the nine diagrams can represent equivalent embeddings generated by the actions of a symmetry group applied to a shape W.

With continued reference to FIG. 4F, an indeterminate embedding condition can arise when a left-hand-side shape has fewer registration points than required to derive transformation matrices for a specified transformation type. For a similarity transformation, two registration points can be used to resolve four unknown variables including a rotation angle θ, a translation in an x direction tₓ, a translation in a y direction t_{y}, and a scaling factor s. When a left-hand-side shape u has fewer than two registration points, the shape embedding engine 700 can determine that the embedding is indeterminate under similarity transformation.

In the example shown in FIGS. 4A-4F, the left-hand-side shape u can have one registration point. The shape embedding engine 700 can address the indeterminate embedding condition using a multi-step process. A first step can be processed automatically by taking one registration point of a parameterized shape g(U) to derive the translation variables tₓ and t_{y}. A second step can be processed automatically by taking one registration point and one endpoint of the parameterized shape g(U) to derive the rotation angle θ. A third step can include an additional input for the scaling factor s because the indeterminacy can occur in scaling.

The shape embedding engine 700 can parameterize the shape embedding with a scaling parameter s that has a scaling range defined by a lower bound and an upper bound. In the example of FIG. 4F, the lower bound can equal zero and the upper bound can equal one. The calculation of the lower bound and the upper bound can be context-sensitive, and the indeterminacy can show up as multiple parameters in some cases.

As shown in FIG. 4F, a single embedding schema of a transformed parameterized shape f(g(U)) in the shape W can produce eight matches under the symmetry group of the shape W. For each of the eight matches, there can be an assignment g parameterized with the scaling factor s with a range 0≤s≤1. The internal line configurations within each diamond can vary in position and orientation across the columns, demonstrating the different transformation results. As the scaling parameter decreases from 1.0 to 0.25, the internal line configurations can become progressively smaller relative to the containing diamond shape, illustrating how the embedding schema produces different geometric results based on the assigned scaling value.

The shape embedding engine 700 can include a process for intermediate embedding process 760 that handles indeterminate embedding cases. For each case of indeterminate embedding, the shape embedding engine 700 can pre-calculate respective parameter ranges and send the ranges to the communication layer 300 to compile a message and echo the message back to users to ask for further parameters. After receiving the parameters, the shape embedding engine 700 can continue the embedding process with the received parameters.

The shape embedding engine 700 can include three components to achieve the indeterminate embedding mechanism: a component to detect indeterminacy of embedding and classify the case, a component to calculate the range for each parameter, and an interactive interface that can communicate with users without disrupting the workflow. The communication layer 300 can facilitate the interactive interface by requesting user input via the communication layer 300 to specify a value for an indeterminate transformation parameter.

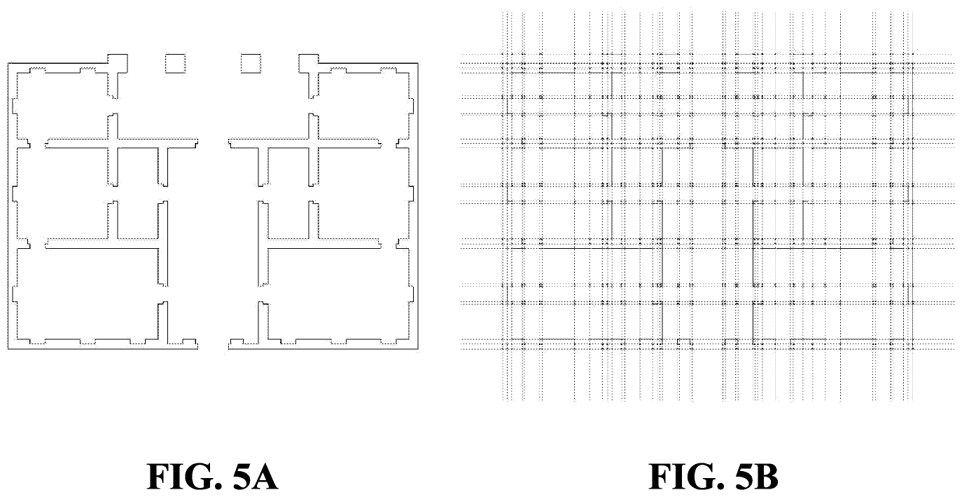

Referring to FIGS. 5A-5B, an architectural plan can illustrate the computational complexity associated with shape embedding operations when a design contains a large number of maximal lines. FIG. 5A illustrates an architectural plan comprising a series of interconnected rectangular rooms arranged in a grid-like pattern. The architectural plan can consist of maximal lines forming walls, doorways, and openings between spaces. The layout can include multiple quadrants, each containing smaller subdivided spaces with various wall configurations and openings.

FIG. 5B illustrates the same architectural plan with registration points marked at the intersections of the maximal lines. The registration points can be depicted as small marks at locations where the hyperplanes of the lines intersect. The dense pattern of registration points in FIG. 5B demonstrates the large number of intersection points that can result from the maximal lines in the architectural plan. Registration points can appear at every location where two or more line carriers cross, including endpoints and intersection points throughout the design.

With continued reference to FIGS. 5A-5B, the architectural plan can comprise 240 maximal lines and 1125 registration points including endpoints and intersection points. The number of registration points in a design can affect the computational complexity of shape embedding operations. The complexity of embedding can follow the number of registration points available in the current design W.

For shape embedding under Euclidean transformations, the complexity can be O(n²) for n the number of registration points of W. For affine transformations, the complexity can increase to O(n³). For linear transformations, the complexity can increase to O(n⁴).

The derivation of transformation matrices for shape embedding under Euclidean transformations can include the automated comparison of at least two registration points sampled in the left-hand-side shape u versus all pairs of registration points in the design W. For the architectural plan example with 1125 registration points, there can be

$${C}_{2}^{1125} = 632 , 250$$

candidates for the system to test if the embedding is processed under Euclidean transformations.

The derivation of transformation matrices for shape embedding under affine transformations can include the automated comparison of at least three registration points sampled in the left-hand-side shape u versus all triplets of registration points in the design W. For the architectural plan example, there can be

$${C}_{3}^{1125} = 23 , 672 , 250$$

candidates to test if the embedding is processed under affine transformations.

The derivation of transformation matrices for shape embedding under linear transformations can include the automated comparison of at least four registration points sampled in the left-hand-side shape u versus all quadruples of registration points in the design W. For the architectural plan example, there can be approximately

$${C}_{4}^{1125} ≅ 6.6 \times 1 {0}^{10}$$

candidates to test if the embedding is processed under linear transformations.

The large number of candidate transformation matrices demonstrates the computational challenge associated with shape embedding in designs containing many geometric elements. The shape embedding engine 700 can address this challenge through a registration point weighting and ranking mechanism. By weighting and ranking registration points before sampling, the shape embedding engine 700 can reduce the search space for shape embedding operations.

Not every registration point of a left-hand-side shape u can be embedded in any registration point of a design W after applying a transformation. The shape embedding engine 700 can calculate a weight for each registration point based on geometric features of maximal elements intersecting at the registration point. The weights can help the shape embedding engine 700 rank and sample registration points from the left-hand-side shape u and the design W so that the search body can be reduced. The registration point ranking process 730 can rank the registration points based on the calculated weights. The registration point sampling process 740 can sample registration points from the left-hand-side shape and the design based on the ranking.

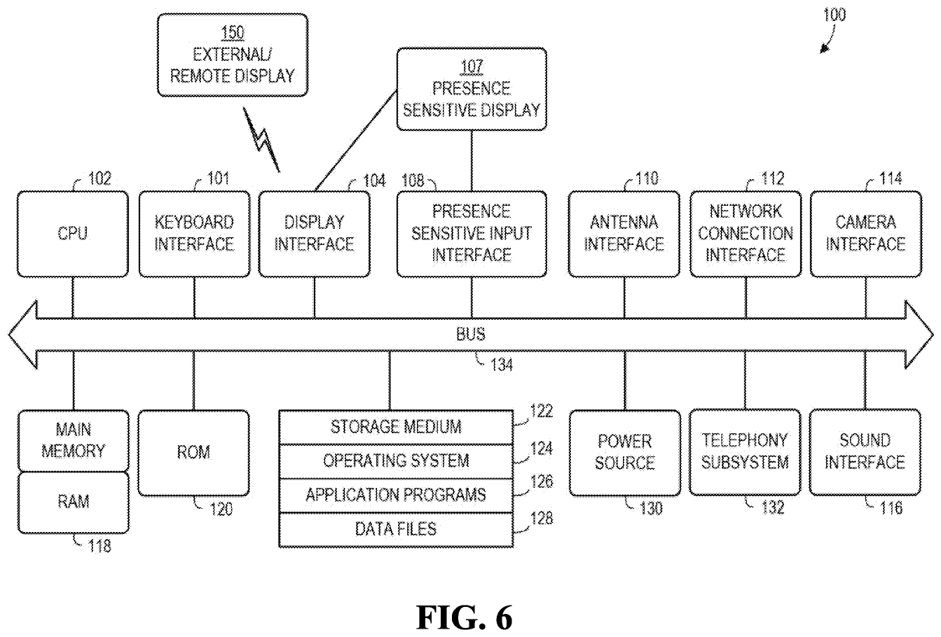

Referring to FIG. 6, a computing device architecture 100 can be used to provide shape computation in a computer-aided design environment. The computing device architecture 100 can include a central processing unit (CPU) 102 where computer instructions can be processed. The CPU 102 can have appropriate structure to be a computer processor. In some cases, the CPU 102 can include more than one processing unit.

The computing device architecture 100 can include a display interface 104 that acts as a communication interface and provides functions for rendering video, graphics, images, and texts on a display 150. In some cases, the display interface 104 can be directly connected to a local display, such as a touch-screen display associated with a mobile computing device. In some cases, the display interface 104 can be configured for providing data, images, and other information for an external or remote display 150 that is not necessarily physically connected to the computing device. The display interface 104 can wirelessly communicate, for example, via a Wi-Fi channel or other available network connection interface 112 to the external or remote display 150.

With continued reference to FIG. 6, the computing device architecture 100 can include a presence sensitive display 107 connected via a presence sensitive input interface 108. The presence sensitive input interface 108 can provide a communication interface to various devices such as a pointing device, a touch screen, or a depth camera, which can or cannot be associated with a display. The computing device architecture 100 can be configured to use an input device via one or more input/output interfaces to allow a user to capture information into the computing device architecture 100. The input device can include a mouse, a trackball, a directional pad, a track pad, a touch-verified track pad, a presence-sensitive track pad, a presence-sensitive display, a scroll wheel, a digital camera, a digital video camera, a web camera, a microphone, a sensor, or a smartcard. The input device can be integrated with the computing device architecture 100 or can be a separate device.

The computing device architecture 100 can include an antenna interface 110 that provides a communication interface to an antenna. The computing device architecture 100 can include a network connection interface 112 that provides a communication interface to a network. The network connection interface 112 can be configured as a communication interface and can provide functions for rendering video, graphics, images, text, other information, or any combination thereof on the display 150. A communication interface can include a serial port, a parallel port, a general purpose input and output port, a game port, a universal serial bus port, a micro-USB port, a high definition multimedia port, a video port, an audio port, a Bluetooth port, a near-field communication port, another communication interface, or any combination thereof.

The computing device architecture 100 can include a camera interface 114 that acts as a communication interface and provides functions for capturing digital images from a camera. The computing device architecture 100 can include a sound interface 116 that is provided as a communication interface for converting sound into electrical signals using a microphone and for converting electrical signals into sound using a speaker.

With continued reference to FIG. 6, the computing device architecture 100 can include a main memory 118 comprising random access memory (RAM) where computer instructions and data can be stored in a volatile memory device for processing by the CPU 102. The RAM 118 can interface with a bus 134 to provide quick RAM storage to the CPU 102 during the execution of software programs such as an operating system 124, application programs 126, and device drivers. The CPU 102 can load computer-executable process steps from a storage medium 122 or other media into a field of the RAM 118 in order to execute software programs. Data can be stored in the RAM 118, where the data can be accessed by the CPU 102 during execution.

The computing device architecture 100 can include a read-only memory (ROM) 120 where invariant low-level system code or data for basic system functions such as basic input and output, startup, or reception of keystrokes from a keyboard can be stored in a non-volatile memory device.

The computing device architecture 100 can include a storage medium 122 or other suitable type of memory such as RAM, ROM, programmable read-only memory, erasable programmable read-only memory, electrically erasable programmable read-only memory, magnetic disks, optical disks, floppy disks, hard disks, removable cartridges, or flash drives. The storage medium 122 can store files including the operating system 124, application programs 126, and data files 128. The application programs 126 can include a web browser application, a widget or gadget engine, a shape grammar interpreter application, a computer-aided design application, or other applications. The storage medium 122 can include a number of physical drive units, such as a redundant array of independent disks, a floppy disk drive, a flash memory, a USB flash drive, an external hard disk drive, a thumb drive, a pen drive, a key drive, a high-density digital versatile disc optical disc drive, an internal hard disk drive, a Blu-Ray optical disc drive, or a holographic digital data storage optical disc drive.

The computing device architecture 100 can include a power source 130 that provides an appropriate alternating current or direct current to power components of the computing device architecture 100.

The computing device architecture 100 can include a telephony subsystem 132 that allows the computing device architecture 100 to transmit and receive sound over a telephone network.

The constituent devices including the CPU 102, the display interface 104, the presence sensitive input interface 108, the antenna interface 110, the network connection interface 112, the camera interface 114, the sound interface 116, the main memory 118, the ROM 120, the storage medium 122, the power source 130, and the telephony subsystem 132 can communicate with each other over the bus 134.

In the context of shape computation operations, the CPU 102 can execute instructions stored in the main memory 118 or the storage medium 122 to perform shape embedding and shape replacement operations. The application programs 126 stored in the storage medium 122 can include a Shape Machine 200 application that interfaces with a computer-aided design application to receive shape rules and designs via a communication layer 300. The CPU 102 can process shape rule compilation, design initialization, maximal element modeling, shape embedding calculations, and rule application operations. The display interface 104 can render visual representations of shapes, shape rules, and design modifications on the display 150, allowing a user to interact with the shape computation system through the presence sensitive display 107 or other input devices connected via the presence sensitive input interface 108. The data files 128 stored in the storage medium 122 can include shape data, transformation parameters, and design files used in shape computation operations.

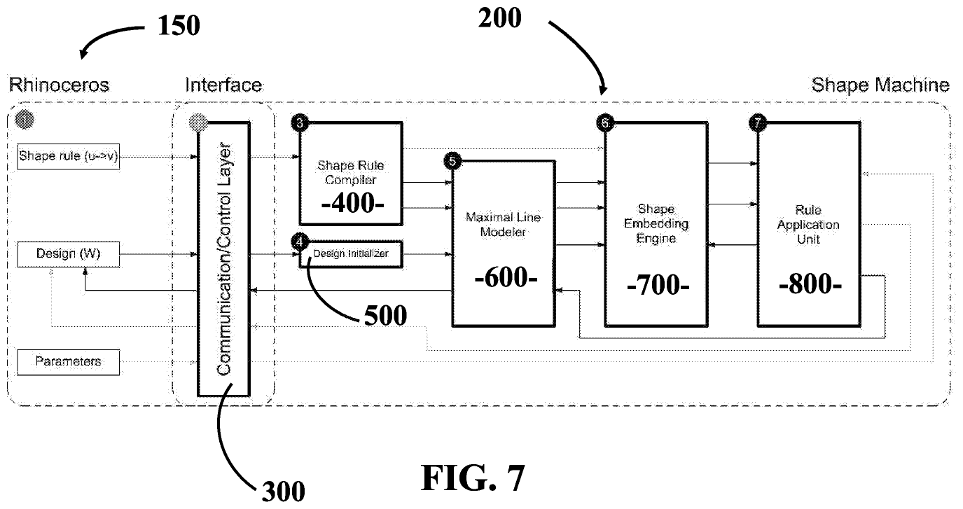

Referring to FIG. 7, a Shape Machine 200 can include a layered system architecture that joins functionality of the Shape Machine 200 with functionality of a computer-aided design (CAD) system. The system architecture can include six major components: a communication layer 300, a shape rule compiler 400, a design initializer 500, a maximal line modeler 600, a shape embedding engine 700, and a rule application unit 800. The communication layer 300 can be referred to herein as a communication/control layer.

With continued reference to FIG. 7, the CAD system can be represented by a display 150 where users instantiate shapes, shape rules, and input parameters. In some cases, the CAD system can be a Rhinoceros interface or another CAD application. The Shape Machine 200 can receive shape rule and design inputs from the CAD system via the communication layer 300. The shape rule can include a left-hand-side shape u and a right-hand-side shape v. The design can include a plurality of geometric elements.

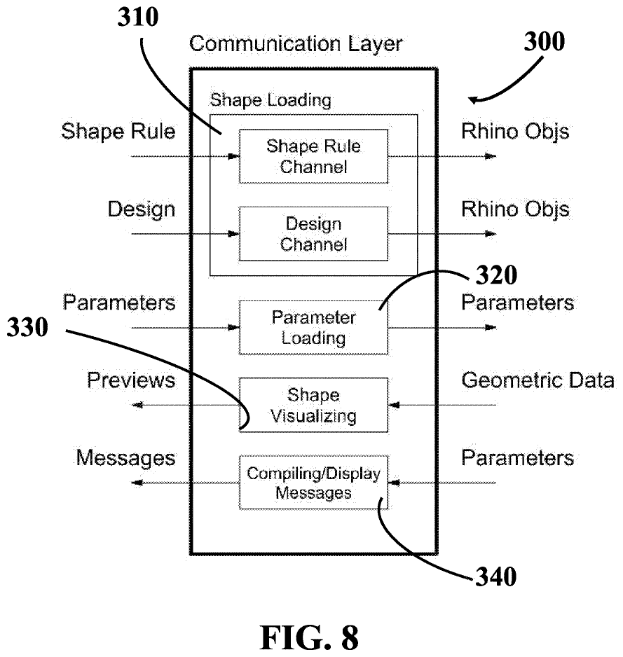

The communication layer 300 can serve as a component between the kernel of the Shape Machine 200 and the CAD system. Referring to FIG. 8, the communication layer 300 can include four major procedures: shape loading 310, parameter loading 320, shape visualizing 330, and compiling/display messages 340. The shape loading 310 procedure can load shapes into the Shape Machine 200, including shape rules and designs that are in a format defined by the CAD system. The shape loading 310 procedure can be implemented with an application programming interface (API) of the CAD system because data representations of shapes can vary from one CAD system to another CAD system.

The parameter loading 320 procedure can load settings, typically represented as integers, into the Shape Machine 200 for users to communicate with and control the Shape Machine 200. The parameter loading 320 procedure can be linked to a communication component of the CAD system, such as a prompt window where the CAD system shows messages and information to users.

The shape visualizing 330 procedure can instantiate shapes on a canvas as another communication mode. For example, if there are multiple results of a shape rule application, the Shape Machine 200 can send the results in numerical format to the communication layer 300 and the results can be visualized directly on the design for users.

The compiling/display messages 340 procedure can compile results and show messages to users according to a status of the Shape Machine 200. For instance, if shape embedding is indeterminate, the Shape Machine 200 can show ranges of parameters to users and ask for further information from users. The communication layer 300 can be responsible for bidirectional communication with users via the CAD system.

With continued reference to FIG. 7, the communication layer 300 can be abstracted to provide an interface that, when implemented, facilitates communication between the Shape Machine 200 and a target program. The target program can include Rhinoceros, Revit, or other CAD applications. By abstracting the communication layer 300, the Shape Machine 200 can be extended to different CAD platforms. Portions of the shape rule compiler 400 and the design initializer 500 can be delegated to the communication layer 300 interface. Processes related to shape rule unpacking, parameter fetching, attribute fetching, and converting model objects to Shape Machine objects can be delegated to the communication layer 300. By delegating these processes to the communication layer 300, the structure of a rule and the translations of model objects to Shape Machine objects can be platform-specific.

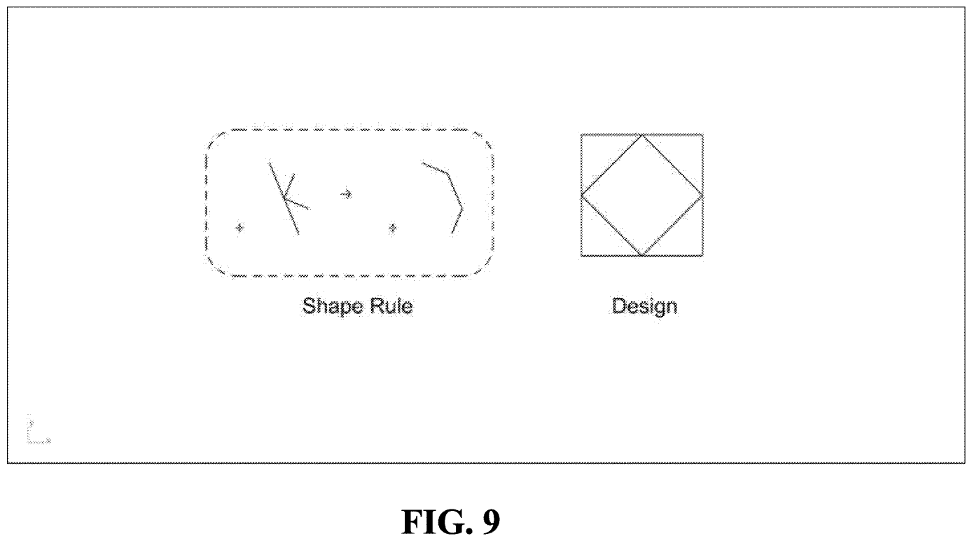

Referring to FIG. 9, a shape rule can be shown in a dashed-line block including a left-hand-side shape comprising three maximal lines in an arrangement resembling a letter K, and a right-hand-side shape comprising three maximal lines in an arrangement resembling a letter C. A rule template can comprise seven maximal lines in an arrangement resembling a right arrow and two crosses. A design can comprise eight maximal lines in an arrangement resembling two nested squares.

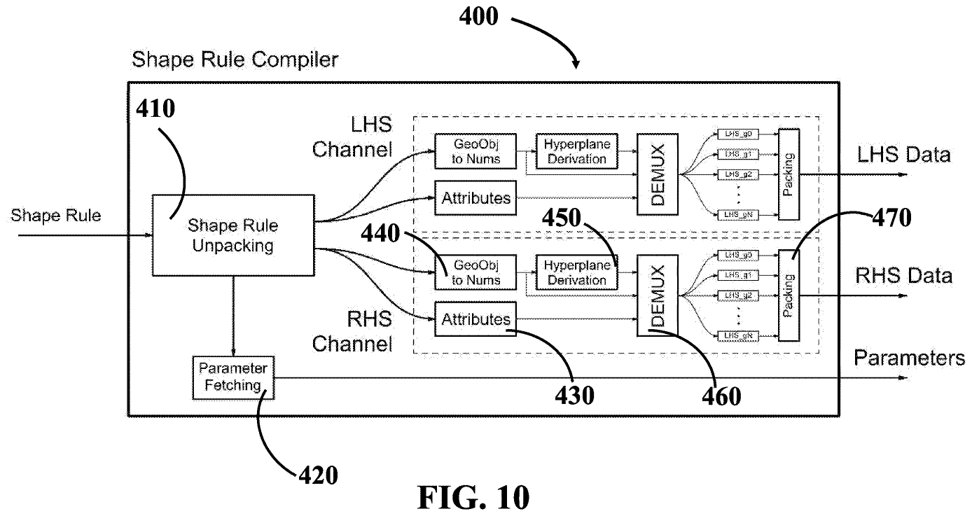

Referring to FIG. 10, the shape rule compiler 400 can translate a shape rule into a Shape Machine 200 format. The shape rule compiler 400 can include seven functionalities: a shape rule unpacking process 410, a parameter fetching process 420, an attribute fetching process 430, an endpoint extraction process 440, a hyperplane derivation process 450, a hyperplane grouping process 460, and a data packaging process 470.

After a shape rule is input into the shape rule compiler 400 from the communication layer 300, the shape rule unpacking process 410 can unpack the shape rule into three parts: the left-hand-side shape u, the right-hand-side shape v, and the shape rule template. The parameter fetching process 420 can extract transformation parameters from the rule template. The attribute fetching process 430 can extract attributes from each line, including name, layer, color, line type, and line width, and attach the attributes as part of a data representation.

The endpoint extraction process 440 can extract coordinates of endpoints of each line and translate a data format of both the left-hand-side shape u and the right-hand-side shape v from CAD objects to endpoint coordinates in the form of pure numerical values. The hyperplane derivation process 450 can calculate a hyperplane for each line. The hyperplane grouping process 460 can attach the hyperplane to the data representation as a vector with three floating point numbers. The data packaging process 470 can package coordinates, hyperplanes, and attributes for both the left-hand-side shape u and the right-hand-side shape v.

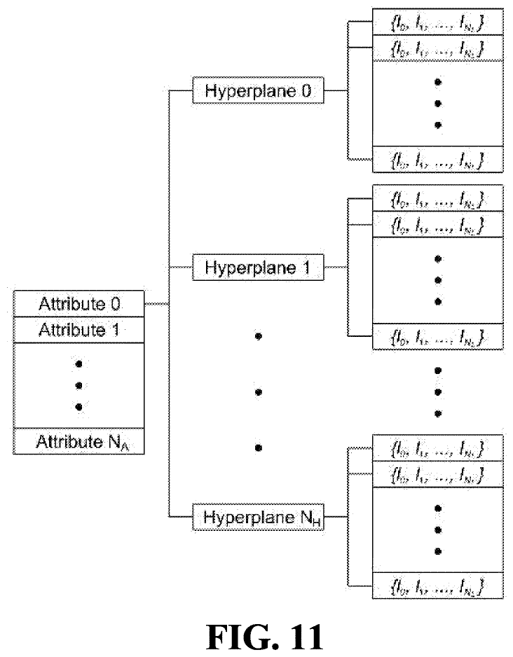

Referring to FIG. 11, a data structure of a shape comprising lines can include a hierarchical organization showing relationships between attributes, hyperplanes, and line indices. Attributes can connect to hyperplanes, and each hyperplane can connect to multiple sets of line indices. The data structure can enable efficient storage, retrieval, and manipulation of shape information during shape embedding and shape replacement operations.

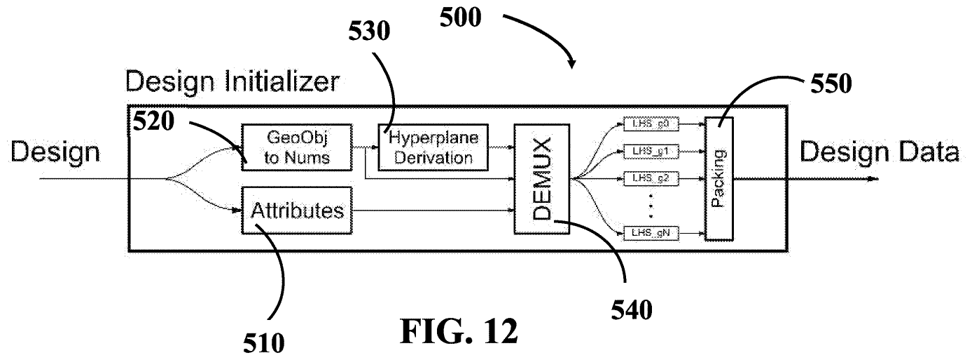

Referring to FIG. 12, the design initializer 500 can function as a subset of the shape rule compiler 400. The design initializer 500 can include an attributes fetching process 510, an endpoint coordinate extracting process 520, a hyperplane derivation process 530, a data grouping process 540, and a packing process 550. After processing all procedures in the design initializer 500, a data format of a design W can be translated from CAD objects to endpoint coordinates, which are pure numerical values. Attributes of lines can be extracted and attached as part of the data representation. The system can calculate a hyperplane for each line and attach the hyperplane to the data representation.

The organization of the Shape Machine 200 engine can be separated into two parts: geometry calculations and rule application. The geometry calculations can resemble the maximal line modeler 600 and the shape embedding engine 700. The rule application can resemble the rule application unit 800. With these two components separated, commands can either make use of rule application functionality in the engine or execute geometry calculations manually.

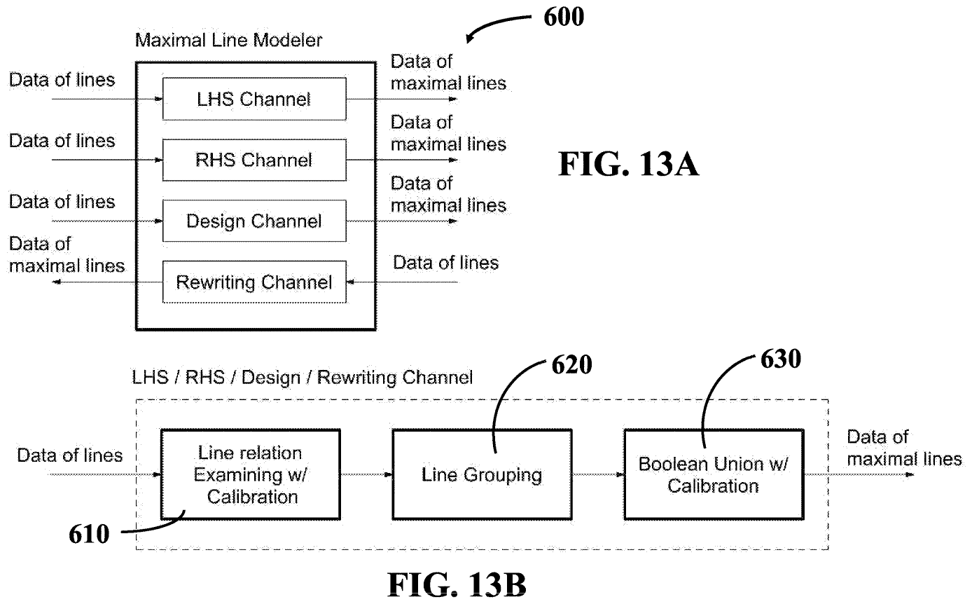

Referring to FIGS. 13A-13B, the maximal line modeler 600 can translate line elements of the left-hand-side shape u, the right-hand-side shape v, and the design W into a maximal line representation with calibration. The maximal line modeler 600 can include three major functionalities: a line relationships checking process 610, a line grouping process 620, and a boolean union with calibration process 630.

As shown in FIG. 13A, the maximal line modeler 600 can include four channels: an LHS channel, an RHS channel, a design channel, and a rewriting channel. The LHS channel, the RHS channel, and the design channel can input data from the CAD system and output data of maximal lines to the shape embedding engine 700. The rewriting channel can be reversed because the rewriting channel is used to maximize lines after shape rule application and output data back to the CAD system. The rewriting channel can ensure all lines are in maximal representation before being sent back to the CAD system.

As shown in FIG. 13B, in each channel, lines in groups can be sent to the line relationships checking process 610 where any two lines are examined with calibration. If two lines are in a relationship that they should be merged, the system can label the two lines with each other's line index. After labeling, the line grouping process 620 can group all lines that should be merged. Lines can be grouped within attribute groups and hyperplane groups. Each line can be labeled with a hyperplane where the line is embedded and attributes of the line. For lines in each group, the boolean union with calibration process 630 can perform a Boolean union operation to combine the lines into one maximal line.

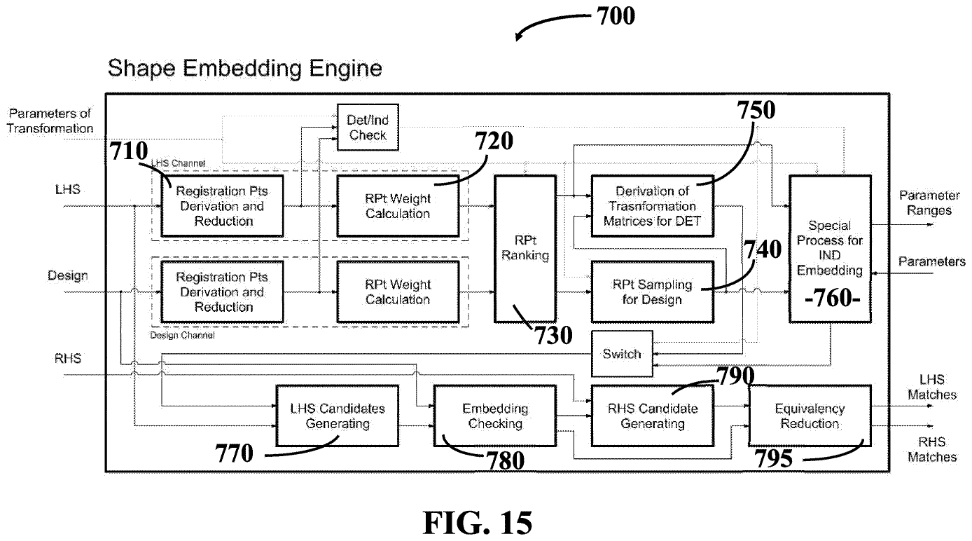

Referring to FIG. 15, the shape embedding engine 700 can be a component in the Shape Machine 200 that performs shape embedding calculations. The shape embedding engine 700 can include ten major procedures: a registration point derivation and reduction process 710, a registration point weight calculation process 720, a registration point ranking process 730, a registration point sampling process 740, a derivation of transformation matrices process 750, a process for intermediate embedding process 760, an LHS candidates generating process 770, an embedding checking process 780, an RHS candidate generating process 790, and an equivalency reduction process 795.

The registration point derivation and reduction process 710 can derive intersections of maximal lines for both the left-hand-side shape u and the design W. Intersections between maximal lines with different attributes can be derived, and attributes of lines can be attached to registration points. If multiple intersections coincide at the same point, the intersections can be reduced into one registration point and attributes of removed registration points can be attached to the remaining registration point.

The registration point weight calculation process 720 can calculate a weight for each registration point for both the left-hand-side shape u and the design W. The weights of registration points can help the shape embedding engine 700 rank and sample registration points from the left-hand-side shape u and the design W so that a search space can be reduced. The registration point ranking process 730 can rank registration points based on calculated weights. The registration point sampling process 740 can sample registration points from the left-hand-side shape and the design based on the ranking. The derivation of transformation matrices process 750 can derive transformation matrices from sampled registration points.

The LHS candidates generating process 770 can generate all candidates f(u) with derived transformations f. The embedding checking process 780 can check all candidates to determine if the candidates can be embedded into the design W and exclude transformations that cannot make the left-hand-side shape u embedded in the design W. The RHS candidate generating process 790 can use a set of transformations f′ that can make the left-hand-side shape u embedded in the design W to generate all corresponding candidates of the right-hand-side shape f′(v). The equivalency reduction process 795 can eliminate identical copies, both for left-hand-side shapes and right-hand-side shapes, to keep results nonequivalent.

For indeterminate embedding, the process for intermediate embedding process 760 can determine an embedding case at the beginning of the process by checking a number of registration points of the left-hand-side shape u and transformation parameters. If embedding is indeterminate, a special process can be activated to calculate ranges of included parameters and send the ranges to the communication layer 300 to compile a message and echo the message back to users to ask for further parameters. After receiving parameters, the shape embedding engine 700 can continue the embedding process with the received parameters.

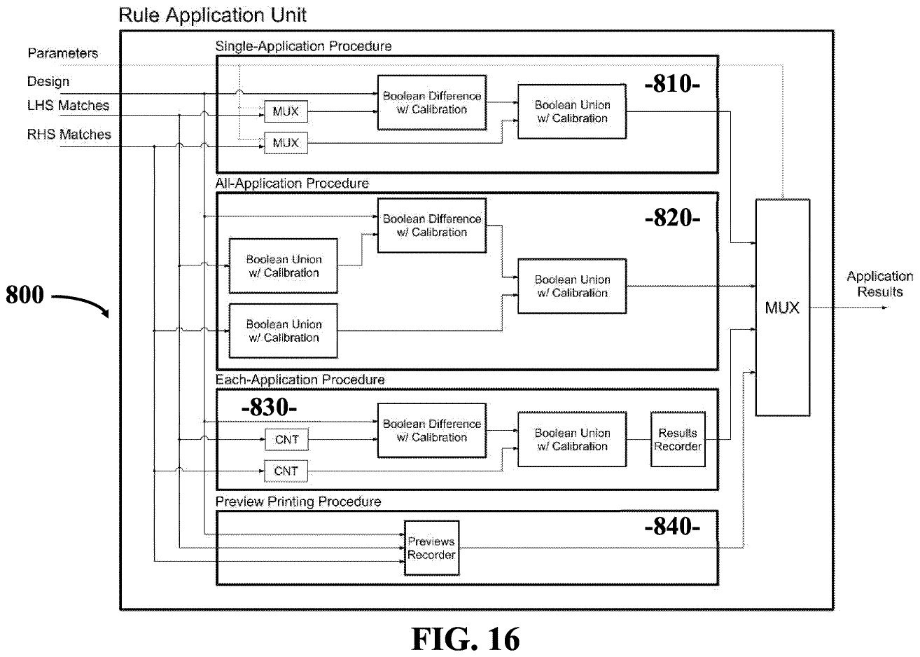

Referring to FIG. 16, the rule application unit 800 can include four major procedures: a single-application process 810, an all-application process 820, an each-application process 830, and an all-preview printing process 840.

After the shape embedding engine 700 processes shape embedding, all matches fₙ(u) and fₙ(v) can be sent to the communication layer 300 to generate previews and control parameters for users. Previews of rule application can be generated in real-time and shown on the design. Users can input different parameters to control the system. For example, the system can show a preview of a next match if users press an enter key. A current match can be applied if users input a first selection. All matches can be applied in parallel if users input a second selection. Matches can be processed one by one and all results can be recorded if users input a third selection. All previews can be printed if users input a fourth selection. The system can exit without any change if users press a cancel selection.

Parameters can be sent to the rule application unit 800 to activate corresponding procedures to finish the process. Each procedure can be implemented with multiple Boolean union units and Boolean difference units in addition to a control system. Each Boolean operation unit can be implemented with a calibration mechanism.

Geometry calculations within the Shape Machine 200 engine can start at a shape level. The communication layer 300 can convert model geometry into shapes that the Shape Machine 200 can use. The communication layer 300 can instantiate a shape with collections of elements. During instantiation, the shape can maximize geometry using the maximal line modeler 600 to create a unique, minimal representation of the geometry.

Different types of rules can each correspond to their own type of object within a Shape Machine library. Geometry in a model can be compiled into these objects in the communication layer 300 and applied by the engine. Each type of rule can define how the rule behaves on a design and how to use the communication layer 300. More rule types can be defined in the library, and new rule types can be defined at an application-specific plugin layer.

Rule sequences can be applied to a design in order by the engine. Rule sequences can be compiled by the communication layer 300 and a format of rule sequences can be plugin or application specific. Rule sequences can be compiled at a command level or communication layer 300 but executed at an engine level.

Referring to FIG. 8, the communication layer 300 can serve as a component between a kernel of the Shape Machine 200 and a computer-aided design (CAD) system. The communication layer 300 can include four major procedures: a shape loading 310 procedure, a parameter loading 320 procedure, a shape visualizing 330 procedure, and a compiling/display messages 340 procedure.

The shape loading 310 procedure can load shapes into the Shape Machine 200, including shape rules and designs that are in a format defined by the CAD system. The shape loading 310 procedure can be implemented with an application programming interface (API) of the CAD system because data representations of shapes can vary from one CAD system to another CAD system. The shape loading 310 procedure can include a shape rule channel and a design channel, where the shape rule channel receives shape rule inputs and outputs objects compatible with the Shape Machine 200, and the design channel receives design inputs and outputs corresponding objects.

The parameter loading 320 procedure can load settings, typically represented as integers, into the Shape Machine 200 for users to communicate with and control the Shape Machine 200. The parameter loading 320 procedure can be implemented with the API of the CAD system and can be linked to a communication component of the CAD system, such as a prompt window where the CAD system shows messages and information to users.

The shape visualizing 330 procedure can instantiate shapes on a canvas as another communication mode. For example, if there are multiple results of a shape rule application, the Shape Machine 200 can send the results in numerical format to the communication layer 300 and the results can be visualized directly on the design for users. The shape visualizing 330 procedure can receive previews and process geometric data for visualization purposes.

With continued reference to FIG. 8, the compiling/display messages 340 procedure can compile results and show messages to users according to a status of the Shape Machine 200. For instance, if shape embedding is indeterminate, the Shape Machine 200 can show ranges of parameters to users and ask for further information from users. The communication layer 300 can be responsible for bidirectional communication with users via the CAD system.

The communication layer 300 can be abstracted to provide an interface that, when implemented, facilitates communication between the Shape Machine 200 and a target program. The target program can include Rhinoceros, Revit, or other CAD applications. By abstracting the communication layer 300, the Shape Machine 200 can be extended to different CAD platforms. Portions of the shape rule compiler 400 and the design initializer 500 can be delegated to the communication layer 300 interface. Processes related to shape rule unpacking, parameter fetching, attribute fetching, and converting model objects to Shape Machine 200 objects can be delegated to the communication layer 300. By delegating these processes to the communication layer 300, the structure of a rule and the translations of model objects to Shape Machine 200 objects can be platform-specific.

Commands can initiate processes with the Shape Machine 200 and facilitate operations that are to be performed. The initiation and orchestration can be handled by commands that operate entirely within the program side, sequencing together operations provided by the program-specific communication layer 300 and the general Shape Machine 200 engine. Separating commands in this manner can allow for a Shape Machine 200 plugin in one program to have different commands from a Shape Machine 200 plugin in another program. Although the commands can perform the same operations, stepping the command logic out can enable program-specific behavior.

With continued reference to FIG. 8, the communication layer 300 can provide feedback to and request feedback from users. Feedback can be provided or requested at any point during the execution of a command, which means the communication layer 300 interface can outline functionality for both providing and requesting feedback. A reference to the communication layer 300 can be available to both the command and to the Shape Machine 200 engine. This arrangement can allow the engine to provide and request feedback while remaining platform-agnostic. Each command can instantiate the appropriate communication layer 300 and then instantiate the Shape Machine 200 engine, providing the engine with the communication layer 300 that the command creates.

In some cases, commands can run asynchronously. By default, a command can run on a main user interface thread, preventing a user from interacting with the CAD system in any way until either the command or engine requests feedback from the user, or until the command finishes. Some commands, however, can enable the user to interact with the CAD system while the command is running in the background. These commands can run in their own thread, only blocking the user interface thread when the commands update or modify the CAD model or when feedback is requested. These commands can use their own communication layer 300, created on the asynchronous thread, which executes behavior on the user interface thread where necessary. To the commands and engine, this communication layer 300 can appear identical to a standard communication layer 300 because the interface is the same, but the implementation is where differences appear.

Two sets of commands can be asynchronous: rule sequence commands and marquee replacement commands. The Shape Machine 200 can execute predefined sequences of replacement rules or programs made of rules using the rule sequence commands. These commands can run in the background so that processing can be paused or stopped partway through. The marquee replacement commands can be a family of commands that allow a user to modify a design in one location and apply that modification elsewhere within the design. A user can select a design to modify, followed by a region in which to make changes. The command can set up a custom view of the model in which everything not in the design is hidden, the original design is made transparent and locked, and the modification region remains. The user can modify this region using regular CAD commands. Because this is performed while the marquee replacement command is still running, the command can run in an asynchronous thread. The user can then choose to apply or cancel changes, ending the command.

Rule sequences can be applied to a design in order by the engine. Rule sequences can be compiled by the communication layer 300 and a format of rule sequences can be plugin or application specific. Rule sequences can be compiled at a command level or communication layer 300 but executed at an engine level. A program can be a collection of rule sequences that can be jumped between using specialized jump rules. Jump rules can be unconditional or based on queries made against the design. Conditional queries can check for the presence or absence of a shape in the design at the point of condition assertion, and an associated jump can be taken only if all queries pass. Programs can be compiled by the communication layer 300 and a format of programs can be plugin or application specific.

When an embedding transformation is indeterminate, the communication layer 300 can be used to ask a user what value to set an indeterminate property to. Different types of rules can each correspond to their own type of object within a Shape Machine 200 library. Geometry in a model can be compiled into these objects in the communication layer 300 and applied by the engine. Each type of rule can define how the rule behaves on a design and how to use the communication layer 300. Additional rule types can be defined in the library, and new rule types can be defined at an application-specific plugin layer.

Referring to FIG. 9, a shape rule and a corresponding design can be illustrated in the context of shape computation. The shape rule can be shown in a dashed-line block that includes a left-hand-side shape and a right-hand-side shape. The left-hand-side shape can comprise three maximal lines arranged in a configuration resembling a letter K. The right-hand-side shape can comprise three maximal lines arranged in a configuration resembling a letter C. An arrow between the left-hand-side shape and the right-hand-side shape can indicate a direction of transformation from the left-hand-side shape to the right-hand-side shape.

With continued reference to FIG. 9, a rule template can be included as part of the shape rule representation. The rule template can comprise seven maximal lines arranged in a configuration resembling a right arrow and two crosses. The two crosses can signify origin points in a Euclidean plane, and the three lines forming the arrow can signify a separation between the left-hand-side shape and the right-hand-side shape. The rule template can be assigned to a special layer so that the Shape Machine 200 can detect the rule template and distinguish the rule template from other shapes in a canvas.

The design can be shown on a right side of FIG. 9 and can comprise eight maximal lines arranged in a configuration of two nested squares. One of the two nested squares can be rotated approximately forty-five degrees relative to the other nested square to form a diamond shape within a square boundary. The design can represent a shape W to which the shape rule can be applied during shape computation operations.

The shape rule can define a transformation from one shape configuration to another shape configuration. When the Shape Machine 200 processes the shape rule, the Shape Machine 200 can search for instances of the left-hand-side shape within the design under various geometric transformations. For each instance where the left-hand-side shape can be embedded in the design, the Shape Machine 200 can subtract the transformed left-hand-side shape from the design and add a corresponding transformed right-hand-side shape to the design.

The shape rule compiler 400 can receive the shape rule from the communication layer 300 and can unpack the shape rule into three parts: the left-hand-side shape, the right-hand-side shape, and the rule template. The shape rule compiler 400 can extract transformation parameters from the rule template and can extract attributes from each line, including name, layer, color, line type, and line width. The shape rule compiler 400 can extract coordinates of endpoints of each line and can translate a data format of both the left-hand-side shape and the right-hand-side shape from CAD objects to endpoint coordinates in the form of numerical values.

The design initializer 500 can receive the design from the communication layer 300 and can process the design to translate a data format of the design from CAD objects to endpoint coordinates. The design initializer 500 can extract attributes of lines and can calculate a hyperplane for each line. The maximal line modeler 600 can then process the left-hand-side shape, the right-hand-side shape, and the design to convert line elements into a maximal line representation with calibration.

The shape embedding engine 700 can derive registration points from intersections of carriers associated with the maximal lines in both the left-hand-side shape and the design. For the design comprising two nested squares, registration points can occur at corners of the squares and at intersection points where lines of the two squares cross. The shape embedding engine 700 can calculate weights for the registration points and can rank the registration points to reduce a search space for shape embedding operations. The shape embedding engine 700 can then match registration points of the left-hand-side shape to registration points of the design to compute candidate transformation matrices for determining whether the left-hand-side shape can be embedded in the design.

Referring to FIG. 10, a shape rule compiler 400 can translate a shape rule into a format compatible with a Shape Machine 200. The shape rule compiler 400 can receive a shape rule from a communication layer 300 and can process the shape rule through a series of procedures to generate compiled data structures for use in shape computation operations. The shape rule compiler 400 can include seven functionalities: a shape rule unpacking process 410, a parameter fetching process 420, an attribute fetching process 430, an endpoint extraction process 440, a hyperplane derivation process 450, a hyperplane grouping process 460, and a data packaging process 470.

After a shape rule is input into the shape rule compiler 400 from the communication layer 300, the shape rule unpacking process 410 can unpack the shape rule into three parts: a left-hand-side shape u, a right-hand-side shape v, and a shape rule template. The shape rule unpacking process 410 can separate the constituent components of the shape rule to enable parallel processing of the left-hand-side shape and the right-hand-side shape through respective processing channels.

With continued reference to FIG. 10, the parameter fetching process 420 can extract transformation parameters from the rule template. The transformation parameters can specify a type of geometric transformation to be used during shape embedding operations, such as an isometry, a similarity transformation, an affine transformation, or a linear transformation. The parameter fetching process 420 can be connected to the shape rule unpacking process 410 and can output the extracted parameters separately from shape data channels.

The attribute fetching process 430 can extract attributes from each line element in the shape rule. The attributes can include a name represented as a string, a layer represented as a string, a color represented as a three-integer vector, a line type represented as a string, and a line width represented as an integer. The attribute fetching process 430 can attach the extracted attributes as part of a data representation for each line element.

The endpoint extraction process 440 can extract coordinates of endpoints of each line element and can translate a data format of both the left-hand-side shape u and the right-hand-side shape v from CAD objects to endpoint coordinates in the form of numerical values. The endpoint extraction process 440 can convert geometric objects received from the CAD system into numerical representations suitable for subsequent processing by the shape embedding engine 700.

The hyperplane derivation process 450 can calculate a hyperplane for each line element. A hyperplane can represent a carrier that extends beyond actual geometric boundaries of a line element. For line elements in two-dimensional space, the hyperplane can be represented as a vector with three floating point numbers corresponding to coefficients of a line equation. The hyperplane derivation process 450 can receive output from the endpoint extraction process 440 and can derive hyperplane equations from the extracted endpoint coordinates.

The hyperplane grouping process 460 can attach the derived hyperplane to the data representation and can organize the hyperplanes using a demultiplexing operation. The hyperplane grouping process 460 can separate the hyperplanes into individual groups for the left-hand-side shape, labeled as LHS_g0, LHS_g1, LHS_g2 through LHS_gN, and corresponding groups for the right-hand-side shape. The hyperplane grouping process 460 can organize line elements according to the hyperplanes in which the line elements are embedded.

The data packaging process 470 can package coordinates, hyperplanes, and attributes for both the left-hand-side shape u and the right-hand-side shape v. The data packaging process 470 can receive grouped hyperplanes from the hyperplane grouping process 460 and attributes from the attribute fetching process 430, combining the grouped hyperplanes and attributes into packaged data structures. The data packaging process 470 can output LHS Data and RHS Data from respective processing channels, along with Parameters extracted by the parameter fetching process 420.

Referring to FIG. 11, a data structure of a shape comprising lines can include a hierarchical organization showing relationships between attributes, hyperplanes, and line indices. The data structure can organize line elements according to attributes and hyperplanes in which the line elements are embedded. Attributes can connect to hyperplanes, and each hyperplane can connect to multiple sets of line indices. The line indices can be represented in a notation including a set of indices from l₀ through l_{NL}, where NL represents a number of line indices associated with each hyperplane.

With continued reference to FIG. 11, the hierarchical data structure can enable efficient storage, retrieval, and manipulation of shape information during shape embedding and shape replacement operations performed by the Shape Machine 200. The attributes can provide classification information for shape elements. The hyperplanes can serve as geometric descriptors or carriers for the lines. The line indices can identify specific maximal lines that are embedded within each hyperplane.

The shape rule compiler 400 can process the left-hand-side shape and the right-hand-side shape through parallel processing channels. An LHS channel can process the left-hand-side shape through the attribute fetching process 430, the endpoint extraction process 440, the hyperplane derivation process 450, the hyperplane grouping process 460, and the data packaging process 470. An RHS channel can process the right-hand-side shape through corresponding processes. The parallel processing channels can enable simultaneous compilation of both shapes in the shape rule.

In some cases, portions of the shape rule compiler 400 can be delegated to the communication layer 300 interface. Processes related to shape rule unpacking, parameter fetching, attribute fetching, and converting model objects to Shape Machine 200 objects can be delegated to the communication layer 300. By delegating these processes to the communication layer 300, a structure of a rule and translations of model objects to Shape Machine 200 objects can be platform-specific, enabling the Shape Machine 200 to be extended to different CAD platforms.

Referring to FIG. 11, a data structure of a shape comprising lines can include a hierarchical organization showing relationships between attributes, hyperplanes, and line indices. The data structure can organize line elements according to attributes and hyperplanes in which the line elements are embedded. The hierarchical organization can enable efficient storage, retrieval, and manipulation of shape information during shape embedding and shape replacement operations performed by the Shape Machine 200.

With continued reference to FIG. 11, a vertical stack of attribute boxes can be shown on a left side of the data structure. The attribute boxes can include Attribute 0, Attribute 1, and continuing through Attribute NA, where NA represents a total number of attributes. The attributes can provide classification information for shape elements. The attributes can include a name represented as a string, a layer represented as a string, a color represented as a three-integer vector, a line type represented as a string, and a line width represented as an integer.

The attributes can connect to a series of hyperplanes arranged in a middle portion of the data structure. The hyperplanes can be labeled as Hyperplane 0, Hyperplane 1, and continuing through Hyperplane NH, where NH represents a total number of hyperplanes. Each hyperplane can be connected to the attributes on the left side, indicating that multiple attributes can be associated with multiple hyperplanes. The hyperplanes can serve as geometric descriptors or carriers for the lines. A hyperplane can be represented as a vector with three floating point numbers corresponding to coefficients of a line equation.

On a right side of the data structure, each hyperplane can connect to multiple sets of line indices. The line index sets can be represented in a notation {l₀, l₁, . . . , l_{NL}}, where NL represents a number of line indices associated with each hyperplane. Multiple rows of line index sets can be shown for each hyperplane, indicating that each hyperplane can contain multiple collections of line indices. The line indices can identify specific maximal lines that are embedded within each hyperplane.

The data structure can group all lines according to the attributes of the lines and the hyperplanes in which the lines are embedded. Lines sharing the same attributes and embedded in the same hyperplane can be grouped together within the hierarchical structure. The grouping can facilitate subsequent processing by the maximal line modeler 600, where lines within each group can be examined for relationships and merged through Boolean union operations with calibration.

The data representation of a maximal line in a shape can include three components packaged together. A first component can include the attributes of the line, comprising the name, layer, color as a three-integer vector (r, g, b), line type, and print width. A second component can include the hyperplane coefficients represented as a vector [a, b, c]. A third component can include the endpoint coordinates, where a head endpoint can be represented as (x_{H}, y_{H}, z_{H}) and a tail endpoint can be represented as (x_{T}, y_{T}, z_{T}).

The shape rule compiler 400 can process a left-hand-side shape and a right-hand-side shape through parallel processing channels to generate data structures following the hierarchical organization shown in FIG. 11. The design initializer 500 can process a design to generate a corresponding data structure. After processing by the shape rule compiler 400 and the design initializer 500, the data format of shapes can be translated from CAD objects to endpoint coordinates in the form of numerical values, with attributes and hyperplanes attached as part of the data representation.

Referring to FIG. 12, a design initializer 500 can receive a design from a communication layer 300 and can process the design through a series of procedures to produce design data as output. The design initializer 500 can function as a subset of a shape rule compiler 400, performing similar operations on design geometry as the shape rule compiler 400 performs on shape rule geometry. The design initializer 500 can include five procedures: an attributes fetching process 510, an endpoint coordinate extracting process 520, a hyperplane derivation process 530, a data grouping process 540, and a packing process 550.

With continued reference to FIG. 12, the design can flow into the design initializer 500 where the design can be processed by the endpoint coordinate extracting process 520. The endpoint coordinate extracting process 520 can convert geometric objects received from a CAD system into numerical representations. The endpoint coordinate extracting process 520 can extract coordinates of endpoints of each line element and can translate a data format of the design from CAD objects to endpoint coordinates in the form of numerical values. The endpoint coordinate extracting process 520 can be labeled as GeoObj to Nums in FIG. 12, indicating the conversion from geometric objects to numerical values.

The attributes fetching process 510 can operate in parallel with the endpoint coordinate extracting process 520 to extract attribute information from the design. The attributes fetching process 510 can extract attributes from each line element in the design. The attributes can include a name represented as a string, a layer represented as a string, a color represented as a three-integer vector in the form (r, g, b), a line type represented as a string, and a line width represented as an integer. The attributes fetching process 510 can attach the extracted attributes as part of a data representation for each line element.

The hyperplane derivation process 530 can receive output from the endpoint coordinate extracting process 520 and can derive hyperplane information from the numerical data. The hyperplane derivation process 530 can calculate a hyperplane for each line element in the design. A hyperplane can represent a carrier that extends beyond actual geometric boundaries of a line element. For line elements in two-dimensional space, the hyperplane can be represented as a vector with three floating point numbers corresponding to coefficients of a line equation in the form [a, b, c]. The hyperplane derivation process 530 can attach the derived hyperplane to the data representation for each line element.

The data grouping process 540 can receive output from the hyperplane derivation process 530 and can distribute the data into multiple groups. The data grouping process 540 can be implemented as a DEMUX (demultiplexer) operation that separates the data into individual groups labeled LHS\_g0, LHS\_g1, LHS\_g2, through LHS\_gN, representing different groupings of line elements. The data grouping process 540 can group all lines according to the attributes of the lines and the hyperplanes in which the lines are embedded. Lines sharing the same attributes and embedded in the same hyperplane can be grouped together within the hierarchical structure.

The packing process 550 can receive the grouped data from the data grouping process 540 and can consolidate the information to produce the final design data output. The packing process 550 can package coordinates, hyperplanes, and attributes for the design into a unified data structure. The data representation of a line element in the design can include three components packaged together: a first component including the attributes of the line comprising the name, layer, color as a three-integer vector, line type, and print width; a second component including the hyperplane coefficients represented as a vector [a, b, c]; and a third component including the endpoint coordinates, where a head endpoint can be represented as (x_{H}, y_{H}, z_{H}) and a tail endpoint can be represented as (x_{T}, y_{T}, z_{T}).

After processing all procedures in the design initializer 500, the data format of a design W can be translated from CAD objects to endpoint coordinates, which can be numerical values. The attributes of lines can be extracted and attached as part of the data representation. The system can calculate a hyperplane for each line and can attach the hyperplane to the data representation. The design data output from the design initializer 500 can then be sent to a maximal line modeler 600 for further processing to convert line elements into a maximal line representation with calibration.

In some cases, portions of the design initializer 500 can be delegated to the communication layer 300 interface. Processes related to attribute fetching and converting model objects to Shape Machine 200 objects can be delegated to the communication layer 300. By delegating these processes to the communication layer 300, translations of model objects to Shape Machine 200 objects can be platform-specific, enabling the Shape Machine 200 to be extended to different CAD platforms.

Referring to FIGS. 13A-13B, a maximal line modeler 600 can receive line data from a shape rule compiler 400 and a design initializer 500 and can translate the line data into a maximal line representation. The maximal line modeler 600 can be referred to herein as a maximal element modeler. The maximal line modeler 600 can include four channels: an LHS channel, an RHS channel, a design channel, and a rewriting channel. Each channel can process line data through three procedures to produce maximal line data as output.

With continued reference to FIG. 13A, the LHS channel can receive data of lines from a left-hand-side shape u and can output data of maximal lines to a shape embedding engine 700. The RHS channel can receive data of lines from a right-hand-side shape v and can output data of maximal lines to the shape embedding engine 700. The design channel can receive data of lines from a design W and can output data of maximal lines to the shape embedding engine 700. The rewriting channel can operate in a reverse direction compared to the other three channels, receiving data of maximal lines as input and outputting data of lines. The rewriting channel can be used to maximize lines after shape rule application and can output the data back to a CAD system. The rewriting channel can ensure that all lines are in maximal representation before being sent back to the CAD system.

Referring to FIG. 13B, each of the LHS, RHS, design, and rewriting channels can include three sequential processing modules. A line relationships checking process 610 can receive data of lines as input and can examine spatial relationships between lines while applying calibration to address precision errors. The line relationships checking process 610 can determine parallelism and collinearity between pairs of lines within a tolerance. A line grouping process 620 can receive output from the line relationships checking process 610 and can group lines based on the examined relationships. A boolean union with calibration process 630 can receive output from the line grouping process 620 and can perform Boolean union operations on the grouped lines while applying calibration, producing data of maximal lines as output.

With continued reference to FIGS. 13A-13B, the line relationships checking process 610 can examine each pair of lines to determine a relationship between the pair. For each pair of lines, the line relationships checking process 610 can examine features including distances between endpoints and angular differences between hyperplanes where the lines are embedded. The line relationships checking process 610 can label relationships between lines based on conditions including whether two lines are parallel, whether two lines are collinear, whether endpoints of one line occur between endpoints of another line, and whether two lines are equal within a tolerance.

The line relationships checking process 610 can apply tolerances for angle and distance to address precision errors caused by floating-point arithmetic. A distance tolerance can specify a maximum distance between endpoints for the endpoints to be considered coincident. An angle tolerance can specify a maximum angular difference between hyperplanes for the hyperplanes to be considered parallel or collinear. The tolerances can enable the system to recognize lines as parallel or collinear even when precision errors cause slight deviations from ideal geometric relationships.

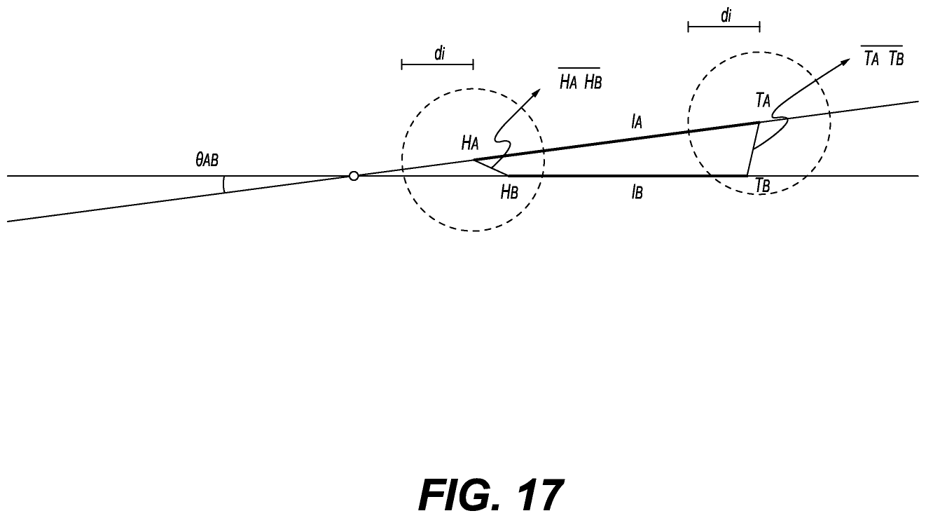

Referring to FIG. 17, two lines can be recognized as equal when a distance between head endpoints of the two lines is smaller than a distance tolerance and a distance between tail endpoints of the two lines is also smaller than the distance tolerance. The line relationships checking process 610 can identify such pairs of lines and can label the lines with each other's line index to indicate that the lines should be merged during subsequent processing.

With continued reference to FIGS. 13A-13B, the line grouping process 620 can group all lines that should be merged based on the labels assigned by the line relationships checking process 610. Lines can be grouped within attribute groups and hyperplane groups. Each line can be labeled with a hyperplane where the line is embedded and attributes of the line. The data format can be represented as a hierarchical structure where lines sharing the same attributes and embedded in the same hyperplane can be grouped together.

The boolean union with calibration process 630 can perform Boolean union operations on lines within each group to produce maximal lines. For lines in each group that are determined to be collinear and overlapping, the boolean union with calibration process 630 can remove the original lines and can create a new maximal line that spans the combined extent of the original lines.

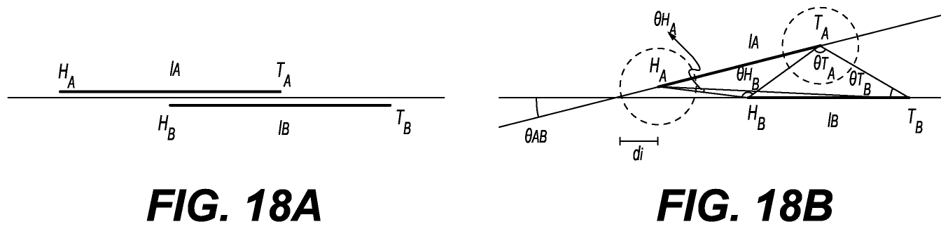

Referring to FIGS. 18A-18B, two collinear lines can be illustrated where one endpoint of a second line occurs between two endpoints of a first line. FIG. 18A can illustrate the two lines without precision error, where the two lines are truly collinear. FIG. 18B can illustrate an imperfect instance where the two lines are neither truly parallel nor truly collinear due to precision errors in the floating-point representation of the line coordinates.

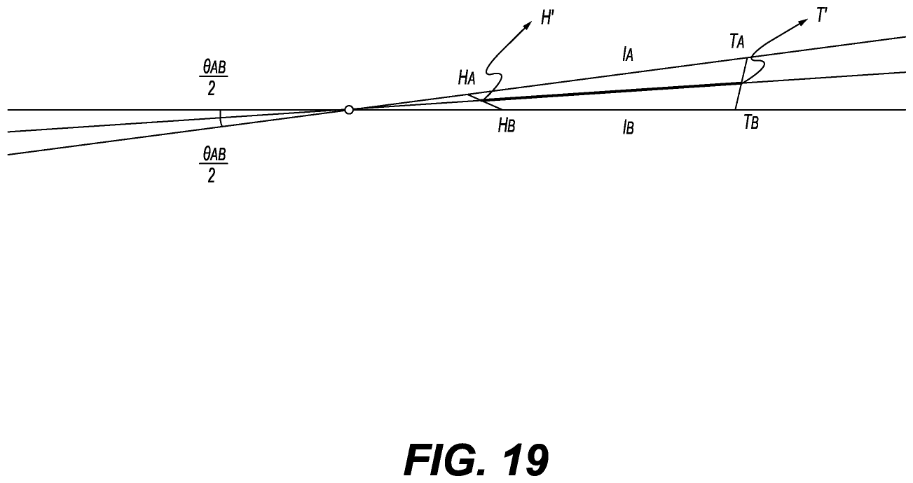

Referring to FIG. 19, the boolean union with calibration process 630 can create a calibrated maximal line when two lines are recognized as equal. Both original lines can be removed and a new line with new endpoints can be created and embedded in a new hyperplane. The new hyperplane can be computed as a bisector of the hyperplanes where the original lines were embedded. A calibrated head endpoint can be computed as an intersection of the new hyperplane and a line connecting the head endpoints of the original lines. A calibrated tail endpoint can be computed as an intersection of the new hyperplane and a line connecting the tail endpoints of the original lines.

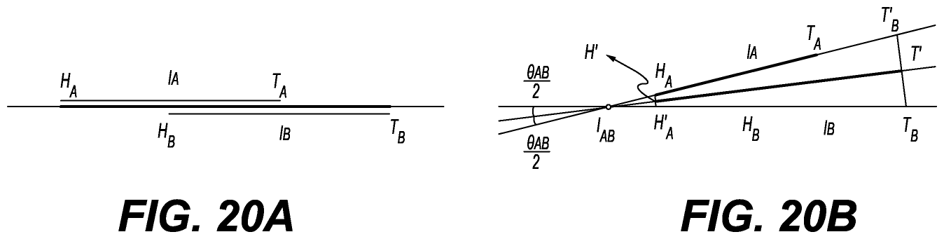

Referring to FIGS. 20A-20B, maximization of two collinear lines can be illustrated. FIG. 20A can illustrate maximization without precision error, where both original lines are removed and a new maximal line with endpoints from the original lines is created. FIG. 20B can illustrate maximization with precision errors, where both original lines are removed and a new maximal line with calibrated endpoints is created. The calibrated endpoints can be computed by projecting the original endpoints onto a calibrated hyperplane that is a bisector of the hyperplanes where the original lines were embedded.

With continued reference to FIGS. 13A-13B, the calibration mechanism can provide tolerances of angle and distance so that rectilinear shapes and non-rectilinear shapes can be supported without requiring shapes to snap onto a grid system. The calibration mechanism can be applied to shape Boolean operations including Boolean union and Boolean subtraction with the same logic that kept endpoints are projected to a new hyperplane.

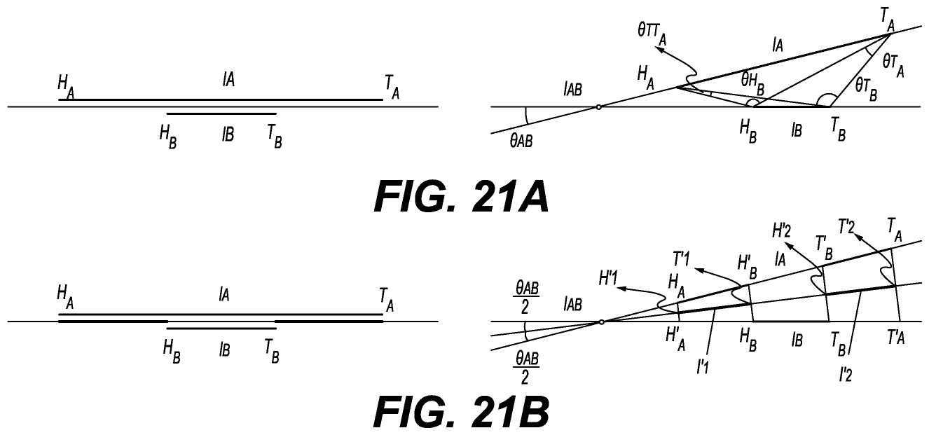

Referring to FIGS. 21A-21B, calibration in a Boolean difference operation can be illustrated. FIG. 21A can illustrate Boolean difference without precision error, where a first line and a second line are both removed and two new maximal lines are created. FIG. 21B can illustrate Boolean difference with precision errors, where the first line and the second line are both removed and two new maximal lines with calibrated endpoints are created. The calibrated endpoints can be computed by projecting the original endpoints onto a calibrated hyperplane.

With continued reference to FIGS. 13A-13B, after processing by the maximal line modeler 600, the data format of lines can be translated from a hierarchical structure with multiple max groups per hyperplane to a simplified structure where each hyperplane directly contains associated maximal line indices. The data representation of lines after the maximal line modeler 600 can include attributes, hyperplane coefficients, and endpoint coordinates for each maximal line.

The maximal line modeler 600 can translate input geometry into a unique geometric representation based on visual perception. The maximal line representation can allow users to inquire about geometry in any manner desired. The maximal line modeler 600 can be distinct from Boolean union functions common in CAD tools because the maximal line modeler 600 can be based on visual perception rather than object-oriented structure.

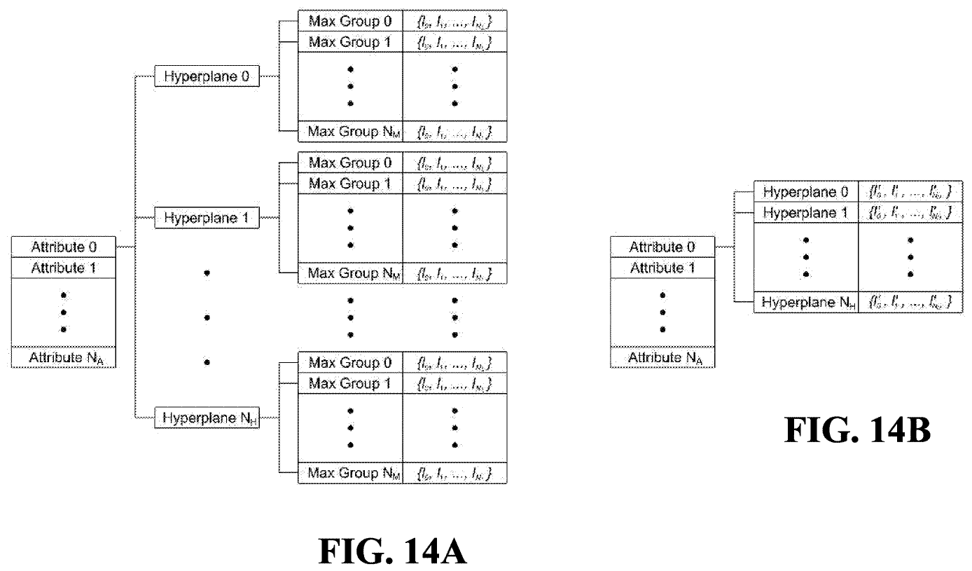

Referring to FIG. 14A, a data structure of lines before processing by a maximal line modeler 600 can include a hierarchical organization where multiple attributes can be associated with multiple hyperplanes, and each hyperplane can be associated with multiple max groups containing sets of line indices. The data structure can organize line elements according to attributes and hyperplanes in which the line elements are embedded prior to maximization processing.

With continued reference to FIG. 14A, the data structure can include Attribute 0 through Attribute NA on a left side, where NA represents a total number of attributes. Each attribute can connect to corresponding hyperplane entries labeled Hyperplane 0, Hyperplane 1, through Hyperplane NH, where NH represents a total number of hyperplanes. Each hyperplane entry can branch into multiple max group entries labeled Max Group 0, Max Group 1, through Max Group NM, where NM represents a total number of max groups associated with each hyperplane. Each max group can contain a set of line indices denoted as {l₀, l₁, . . . , l_{NL}}, where NL represents a number of line indices associated with each max group.

The max groups can represent collections of lines that share the same attributes and are embedded in the same hyperplane. Lines within each max group can be candidates for merging through Boolean union operations during the maximization process. The line relationships checking process 610 can examine pairs of lines within each max group to determine whether the lines should be merged based on spatial relationships including parallelism and collinearity within specified tolerances.

Referring to FIG. 14B, a data structure of lines after processing by the maximal line modeler 600 can present a simplified organization compared to the data structure shown in FIG. 14A. The post-processing structure can eliminate the intermediate max group level that was present in the pre-processing structure.

With continued reference to FIG. 14B, the data structure after maximization can include Attribute 0 through Attribute NA on a left side connecting directly to hyperplane entries labeled Hyperplane 0, Hyperplane 1, through Hyperplane NH. Each hyperplane entry can contain a set of line indices denoted as {l′₀, l′₁, . . . , l′_{NL}}, where the prime notation can indicate that the line indices represent maximal lines rather than the original input lines.

The transformation from the data structure of FIG. 14A to the data structure of FIG. 14B can be performed by the boolean union with calibration process 630. For lines in each max group shown in FIG. 14A, the boolean union with calibration process 630 can perform Boolean union operations to combine the grouped lines into maximal lines. Lines that are determined to be collinear and overlapping within a max group can be merged into a single maximal line that spans the combined extent of the original lines.

The data representation of lines after the maximal line modeler 600 can include three components packaged together for each maximal line. A first component can include attributes of the line comprising a name, a layer, a color as a three-integer vector, a line type, and a line width. A second component can include hyperplane coefficients represented as a vector [a, b, c]. A third component can include endpoint coordinates, where a head endpoint can be represented as (x_{H}, y_{H}, z_{H}) and a tail endpoint can be represented as (x_{T}, y_{T}, z_{T}).

The simplification of the data structure from FIG. 14A to FIG. 14B can demonstrate how the maximal line modeler 600 consolidates and reorganizes line data. By eliminating the intermediate max group level and producing a streamlined representation where each hyperplane directly contains associated maximal line indices for each attribute, the maximal line modeler 600 can create a unique, minimal representation of the geometry suitable for subsequent processing by the shape embedding engine 700.

Referring to FIG. 15, a shape embedding engine 700 can be a component of the Shape Machine 200. The shape embedding engine 700 can receive parameters of transformation and process shapes through multiple channels and modules to produce parameter ranges, parameters, LHS matches, and RHS matches as outputs.

The shape embedding engine 700 can include ten procedures: a registration point derivation and reduction process 710, a registration point weight calculation process 720, a registration point ranking process 730, a registration point sampling process 740, a derivation of transformation matrices process 750, a process for intermediate embedding process 760, an LHS candidates generating process 770, an embedding checking process 780, an RHS candidate generating process 790, and an equivalency reduction process 795.

With continued reference to FIG. 15, the shape embedding engine 700 can include an LHS channel and a design channel that operate in parallel. The LHS channel can receive LHS input and include the registration point derivation and reduction process 710 followed by the registration point weight calculation process 720. The design channel can receive design input and include a corresponding registration point derivation and reduction process 710 followed by a registration point weight calculation process 720.

The registration point derivation and reduction process 710 can derive intersections of maximal lines for both a left-hand-side shape u and a design W. Intersections between maximal lines with different attributes can be derived, and attributes of lines can be attached to the registration point. If multiple intersections coincide at the same point, the registration point derivation and reduction process 710 can reduce the multiple intersections into one registration point and attach the attributes of the removed registration points to the remaining registration point.

The registration point weight calculation process 720 can calculate a weight for each registration point for both the left-hand-side shape u and the design W. The weights of registration points can help the shape embedding engine 700 to rank and sample the registration points from the left-hand-side shape u and the design W so that a search space can be reduced.

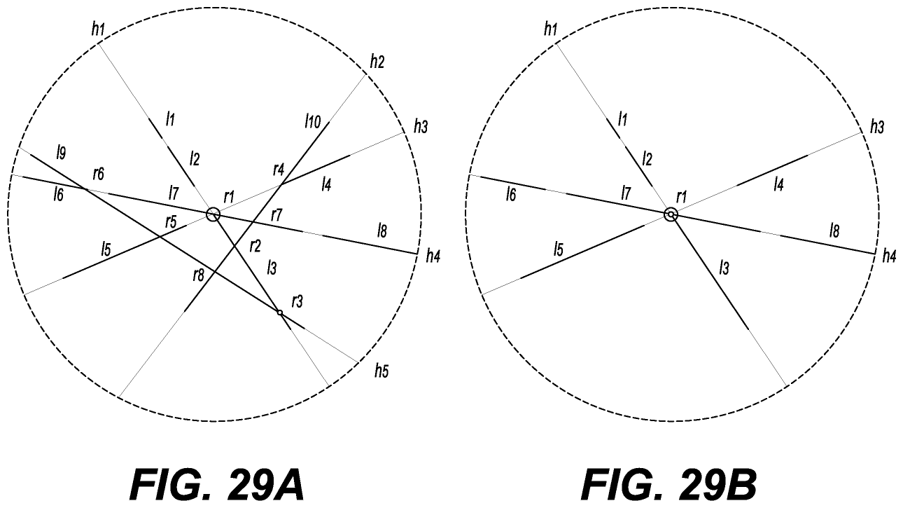

Referring to FIGS. 29A-29B, a weighting process of a registration point can be illustrated. FIG. 29A can illustrate a shape comprising ten maximal lines embedded in four hyperplanes. FIG. 29B can illustrate one of the registration points intersected by eight maximal lines embedded in three hyperplanes.

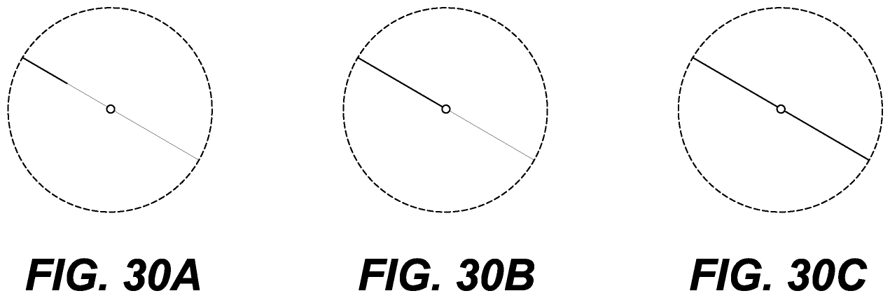

A method to weight a registration point can include counting a number of hyperplanes that intersect at the registration point. To obtain additional improvement in performance, information of maximal lines can be introduced. Referring to FIGS. 30A-30C, three configurations of a maximal line and a registration point can be illustrated. FIG. 30A can illustrate a first configuration c₁ where the registration point is not occurring on the maximal line. FIG. 30B can illustrate a second configuration c₂ where the registration point is occurring on an endpoint of the maximal line. FIG. 30C can illustrate a third configuration c₃ where the registration point is occurring on a body of the maximal line.

The three configurations c₁, c₂, and c₃ can be in part relations c₁<c₂<c₃. A registration point of the design W where a maximal line with the configuration c₃ is possible to be embedded in can be a possible registration point for a maximal line with configurations c₂ or c₁ to be embedded in.

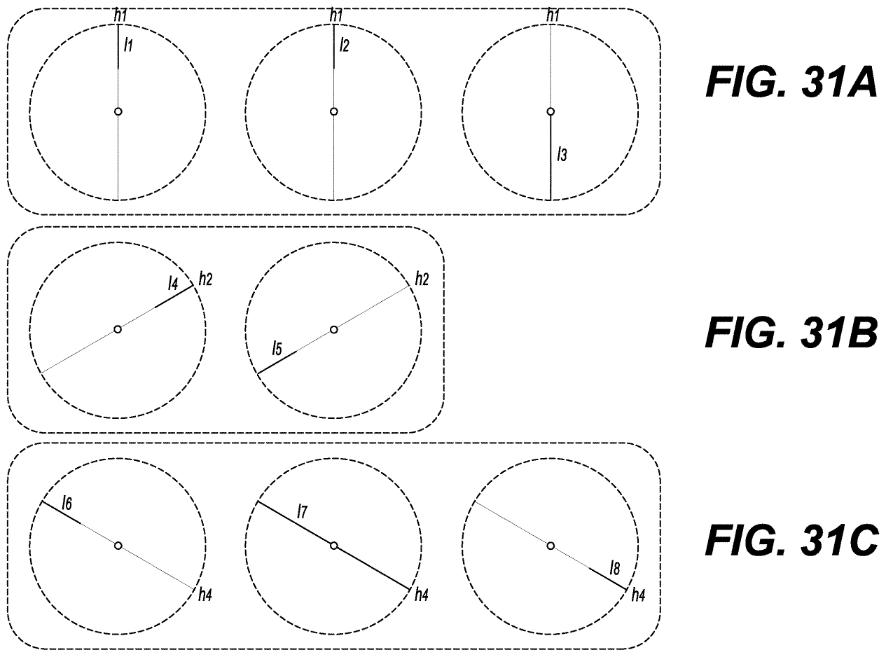

Referring to FIGS. 31A-31C, normalized maximal lines intersecting at a registration point can be illustrated. FIG. 31A can illustrate three normalized maximal lines embedded in a hyperplane h₁. FIG. 31B can illustrate two normalized maximal lines embedded in a hyperplane h₂. FIG. 31C can illustrate three normalized maximal lines embedded in a hyperplane h₄.

With continued reference to FIG. 15, the registration point ranking process 730 can receive outputs from the registration point weight calculation process 720 modules. The registration point ranking process 730 can rank registration points based on the calculated weights. Registration point matching can start by choosing the registration point in a query shape that can match to the least possible registration points in the design, resembling the registration point ranking process 730.

The significance of a registration point can be determined by multiple factors including: a number of radii at the registration point, a number of direct attributes associated to point and arc carriers that created the registration point, and occurrences of direct attributes in a design signature.

The registration point sampling process 740 can sample registration points from the left-hand-side shape and the design based on the ranking. Sampling the registration points of the left-hand-side shape u with a pre-process of weighting and ranking registration points that can be embedded in the least registration points of the design W can reduce the search space.

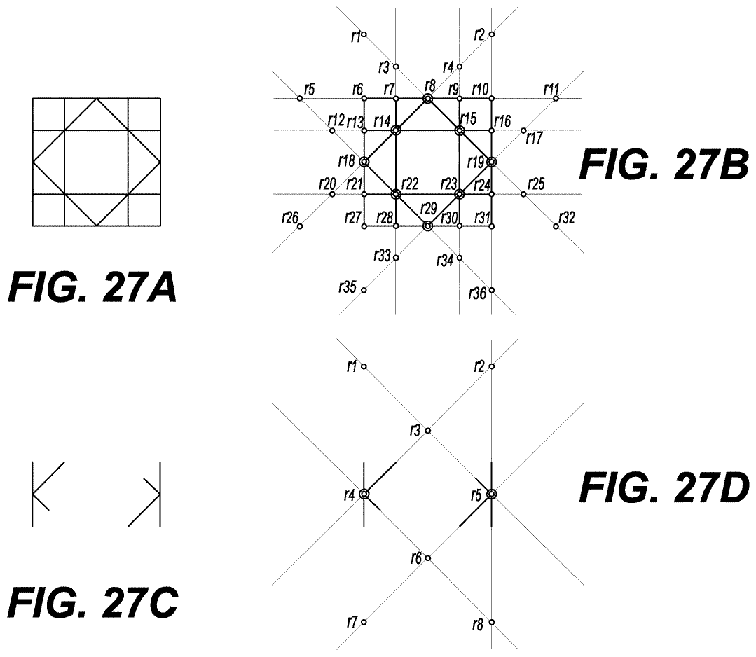

Referring to FIGS. 27A-27D, an example of registration point embedding can be illustrated. FIG. 27A can illustrate a design W comprising 12 maximal lines embedded in 12 hyperplanes. FIG. 27B can illustrate that among 36 registration points at which 12 hyperplanes intersect, eight of the registration points can contain two registration points of the left-hand-side shape u. FIG. 27C can illustrate a shape u comprising six maximal lines embedded in six hyperplanes. FIG. 27D can illustrate eight registration points at which six hyperplanes intersect, where two of the registration points can be embedded in eight of the registration points of the design W.

With continued reference to FIGS. 27A-27D, the search space can be reduced from C₂³⁶=630 to C₂⁸=28 for embedding under Euclidean transformations. If the embedding is processed under affine transformation, the search space can be reduced from C₃³⁶=7140 to C₁⁶=6.

With continued reference to FIG. 15, the derivation of transformation matrices process 750 can derive transformation matrices from the sampled registration points. The derivation of transformation matrices for a shape embedding under Euclidean transformations can include automated comparison of at least two registration points sampled in the left-hand-side shape u versus all pairs of registration points in the design W. The derivation of transformation matrices for a shape embedding under affine transformations can include automated comparison of at least three registration points sampled in the left-hand-side shape u versus all triplets of registration points in the design W. The derivation of transformation matrices for a shape embedding under linear transformations can include automated comparison of at least four registration points sampled in the left-hand-side shape u versus all quadruplets of registration points in the design W.

The parameters of transformation can be provided to a Det/Ind check module that determines whether the embedding is determinate or indeterminate. For determinate embeddings, the process can proceed to the derivation of transformation matrices process 750, which can output parameter ranges and parameters. For indeterminate embeddings, the flow can proceed to the registration point sampling process 740 for design, which can connect to the process for intermediate embedding process 760 that can also output parameters.

The process for intermediate embedding process 760 can handle indeterminate embedding conditions. A shape embedding can be indeterminate when the left-hand-side shape u has fewer registration points than required to derive the transformation matrices. The shape embedding engine 700 can determine the embedding case at the beginning of the process by checking the number of registration points of the left-hand-side shape u and the transformation parameters.

An isometry calculation can be indeterminate if: there are no registration points, or there is one registration point and there are no line carriers in the query. A similarity calculation can be indeterminate if there are no registration points, there is one registration point with no arcs centered at the point and there are no line carriers in the query, there is one registration point with at least one arc centered at the point and there are no line carriers in the query, or there is one registration point with spokes and no arcs are in the query. An affinity calculation can be indeterminate if there are no registration points, there is one registration point with no spokes, there is one registration point with only one spoke, there is one registration point with multiple spokes, there are multiple collinear registration points with no spokes or all spoke directions are only along the same line of collinearity, or there are multiple collinear registration points with spoke directions only along the same line of collinearity where any other spoke directions are all parallel.

If the embedding is indeterminate, a special process can be activated to calculate ranges of included parameters and send the ranges to the communication layer 300 to compile a message and echo the message back to users to ask for further parameters. After receiving the parameters, the shape embedding engine 700 can continue the embedding process with the parameters.

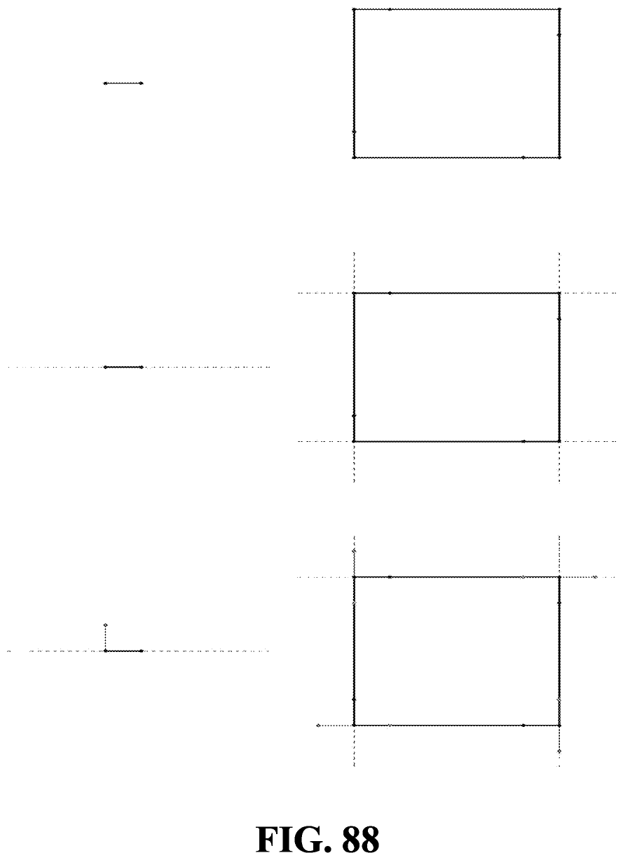

Referring to FIG. 88, stages of a shape embedding process with phantom registration points can be illustrated. If a query is small, meaning the query has fewer than three non-collinear registration points, phantom registration points can be created to be used in the transformation calculation. If the query has two registration points, a phantom registration point can be created to form a right angle with the two existing registration points. A corresponding phantom registration point can be created against all pairs of two design registration points that match the two query registration points. If the query has only one registration point, then for each spoke on the registration point, a phantom registration point can be created in the direction of that spoke at a distance of one unit from the actual registration point, and a second phantom registration point can be created to make a right angle with the actual registration point and the first phantom point.

Phantom registration points can also be created for each spoke for each design registration point that the query anchor can match to. Both legs of the right angles created can be the same length, and two right angles can be created on the design signature: one corresponding to a direct transformation and one corresponding to an indirect transformation. The first leg of the angles can be the same, but the second leg of the indirect angle can be flipped across the first matched design registration point.

With continued reference to FIG. 15, the LHS candidates generating process 770 can generate all candidates f(u) with the derived transformations f. The LHS candidates generating process 770 can receive input and feed into the embedding checking process 780.

The embedding checking process 780 can check all candidates to determine if the candidates can be embedded into the design W and exclude transformations that cannot make the left-hand-side shape u embedded in the design W. Once an anchor and two other query registration points have been matched, the registration points can create a basis for computing an embedding transformation. An affine transformation that maps the query registration points to their matches can be computed using a linear algebra package. If the transformation should be limited to an isometry or a similarity, the transformation that is computed can be further checked to make sure that the transformation actually is an isometry or a similarity.

If successful, the transformation can be applied to the entire query signature. If there are any query registration points that do not map close to a unique design registration point, the transformation can be discarded. If all registration points map close to a design registration point, a new transformation can be computed with least-squares to map all transformed query registration points to their close target. The new transformation can be nearly the identity and can be used to further reduce any floating-point error. The new transformation can then be composed with the original transformation to be used as the final computed transformation.

With the adjusted transformation, query registration points can be checked to see that the query registration points map to a design registration point that the query registration points can embed into. If one does not match, the transformation can be discarded. If all registration points match, the transformation can be applied to the query shape, and the transformed query shape can be checked to see if the transformed query shape can embed into the design. If not, the transformation can be discarded. All remaining transformations after this step can be valid embedding transformations.

A switch controlled by the derivation of transformation matrices process 750 and the process for intermediate embedding process 760 can direct the flow to the RHS candidate generating process 790. The RHS candidate generating process 790 can use the set of transformations f that can make the left-hand-side shape u embedded in the design W to generate all corresponding candidates of the right-hand-side shape f(v).

The equivalency reduction process 795 can eliminate all identical copies, both for the left-hand-side shapes and the right-hand-side shapes, to keep the results nonequivalent. The equivalency reduction process 795 can produce the final LHS matches and RHS matches outputs.

Referring to FIG. 16, a rule application unit 800 can be a component of the Shape Machine 200. The rule application unit 800 can receive matches from the shape embedding engine 700 and apply shape rules to a design by performing Boolean operations with calibration.

The rule application unit 800 can include four procedures: a single-application process 810, an all-application process 820, an each-application process 830, and an all-preview printing process 840. After the shape embedding engine 700 processes a shape rule and a design, all matches fₙ(u) and fₙ(v) can be sent to the communication layer 300 to generate previews and control parameters for users.

With continued reference to FIG. 16, the single-application process 810 can apply a single selected match to the design. The single-application process 810 can receive parameters, design data, LHS matches, and RHS matches as inputs. The parameters and design inputs can feed into a multiplexer, while the LHS matches and RHS matches can feed into another multiplexer. The outputs from the multiplexers can proceed through a Boolean difference with calibration module, followed by a Boolean union with calibration module, producing output that feeds into a final multiplexer for generating application results.

The all-application process 820 can apply all matches to the design in parallel. The all-application process 820 can receive the same input types as the single-application process 810 and route the inputs through Boolean union with calibration modules. The outputs can then pass through a Boolean difference with calibration module, followed by another Boolean union with calibration module, with the result feeding into the output multiplexer.

The each-application process 830 can process matches one by one and record all results. The each-application process 830 can receive inputs that pass through counter modules before proceeding to a Boolean difference with calibration module. The output can then flow through a Boolean union with calibration module and into a results recorder, which can capture individual application results.

The all-preview printing process 840 can receive inputs that feed directly into a previews recorder module, which can store preview information for visualization purposes.

With continued reference to FIG. 16, each procedure in the rule application unit 800 can be implemented with multiple Boolean union units and Boolean difference units in addition to a control system. Each Boolean operation unit can be implemented with a calibration mechanism to address precision errors caused by floating-point arithmetic.

The Boolean difference with calibration module can perform subtraction operations to remove a transformed instance of the left-hand-side shape f(u) from the design W. The Boolean union with calibration module can perform addition operations to add a corresponding transformed instance of the right-hand-side shape f(v) to the design. The formal expression for the shape computation operation can be written as: if f(u)≤W, then W=W−f(u)+f(v), where the symbol ≤ denotes the part relation indicating that the transformed shape f(u) is embedded in the design W.

The calibration mechanism applied to the Boolean operations can project endpoints onto a calibrated carrier computed as a bisector of carriers where elements are embedded. The calibration mechanism can provide tolerances of angle and distance so that rectilinear shapes and non-rectilinear shapes can be supported without requiring shapes to snap onto a grid system.

The outputs from the single-application process 810 and the all-application process 820 can converge at the output multiplexer, which can select between the processing pathways to generate the final application results output from the rule application unit 800. After rule application, the updated design can be maximized by the maximal line modeler 600 to produce a unique, minimal representation of the resulting geometry.

Referring to FIG. 17, a calibration mechanism can address precision errors that arise from floating-point arithmetic in CAD geometry. Calibration for maximal lines can be a mechanism to reduce accumulated error caused by floating-point arithmetic of CAD geometry. Checking parallelism and collinearity between two lines can be an included pre-process for line maximization. Checking for parallelism and collinearity in well-defined cases of lines, for example, rectilinear shapes or otherwise shapes whose endpoints snap upon a grid system, appears straightforward, but even then, the import of transformations brings problems in such comparisons, and the extension of such calculations and procedures for all lines, rational and irrational ones, brings even more precision errors and renders these computations idle. For instance, slight precision errors between two parallel lines can make the lines, in reality, non-parallel as the lines will infact intersect eventually in a point. The usage of floating-point numbers to represent real numbers does not solve the problem as floating-point representation is only an approximation and this issue is still inevitable. Most detrimentally, it is almost virtually impossible to discern with a naked eye such precision errors as the lines do appear parallel to one another. From a user's perspective, the system should recognize these two lines as a pair of parallel lines.

Setting up a tolerance can help reduce the effects caused by precision errors. FIG. 17 shows an example where two lines are recognized as equal because the distance between two endpoints H_{A} and H_{B} is smaller than the tolerance dₜ and the distance between the endpoints T_{A} and T_{B} is smaller than the tolerance dₜ as well. The two lines, l_{A} and l_{B}, can be almost parallel with an angle θ_{AB}, and at the same time, the endpoints of the two lines can be very close to each other. In this case, the system can recognize these two lines as equal because the distance between the endpoints H_{A} and H_{B} is smaller than the tolerance dₜ, and the distance between the endpoints T_{A} and T_{B} is smaller than the tolerance dₜ as well.

With continued reference to FIG. 17, the condition to examine if two lines are equal can be described as: H_{A}H_{B}≤dₜ and T_{A}T_{B}≤dₜ, or alternatively, T_{A}H_{B}≤dₜ and H_{A}T_{B}≤dₜ. This examination method can be generalized for all possible relations between two lines by examining the following features: the angle θ_{AB} between the two hyperplanes h_{A} and h_{B} where l_{A} and l_{B} are embedded; the distance between the endpoint H_{A} and the endpoint H_{B}; the distance between the endpoint T_{A} and the endpoint T_{B}; the distance between the endpoint T_{A} and the endpoint H_{B}; the distance between the endpoint H_{A} and the endpoint T_{B}; and angular relationships between vectors formed by the endpoints.

Referring to FIGS. 18A-18B, FIGS. 18A-18B show an example of two collinear lines without precision error and an example of imperfect collinear lines, where two lines are collinear and only one endpoint of l_{B} occurs between two endpoints of l_{A}. FIG. 18A illustrates l_{A} and l_{B} in this case of relation without any precision error. FIG. 18B illustrates an imperfect instance of this case of relation where l_{A} and l_{B} are neither truly parallel nor truly collinear.

Maximization of lines in the Shape Machine 200 can also be processed with the tolerance, and a new maximal line can be redrafted for every maximization process. For instance, the pair of lines in FIG. 17 can be recognized as two equal lines so that the maximization can be processed. Both l_{A} and l_{B} can be removed and a new line l′ with new endpoints H′ and T′ can be created and embedded in a new hyperplane h′. The new hyperplane h′ can be the bisector of the hyperplane h_{A} and h_{B}. H′ can be the intersection of h′ and the line segment connecting H_{A} and H_{B}. T′ can be the intersection of h′ and the line segment connecting T_{A} and T_{B}, as shown in FIG. 19.

With continued reference to FIGS. 18A-18B, the maximization can be processed according to different cases of relations. For the example in FIGS. 18A-18B, the ideal case can be to remove the endpoints T_{A} and H_{B}, then create a new maximal line with the endpoints H_{A} and T_{B}. In the case with precision errors, a bisector of h_{A} and h_{B} can be created as the new hyperplane, and the system can mark out two temporary points H′_{A} and T′_{B} on h_{B} and h_{A} respectively. The new maximal line can be created with the endpoints H′ and T′ where H′ can be the point of intersection of the new hyperplane h′ and the line connecting H_{A} and H′_{A}, and T′ can be the point of intersection of the new hyperplane h′ and the line connecting T_{B} and T′_{B}. FIGS. 20A-20B illustrate an example of the maximization for two lines with a line relationship where two lines are collinear and only one endpoint of l_{B} occurs between two endpoints of l_{A}. FIG. 20A illustrates an example of maximization without any precision error where l_{A} and l_{B} are both removed and a new maximal line with endpoints H_{A} and T_{B} is created. FIG. 20B illustrates an example of maximization with precision errors where l_{A} and l_{B} are both removed and a new maximal line with endpoints H′ and T′ is created.

In general, the endpoint which is supposed to be kept if there is no precision error can be calibrated by projecting the endpoint onto the new hyperplane which is the bisector of the hyperplanes where lines are embedded. This mechanism provides the tolerances of angle and distance so that not only rectilinear shapes are supported but also no need to snap shapes onto a grid system. Furthermore, this mechanism can also be applied to the shape Boolean operations including Boolean union and Boolean subtraction with the same logic that the kept endpoints are projected to the new hyperplane.

Referring to FIGS. 21A-21B, FIGS. 21A-21B show an example of the calibration in Boolean difference l_{A}−l_{B} where l_{B} is embedded in l_{A} and none of the endpoints of l_{B} coincides with any endpoint of l_{A}. FIG. 21A illustrates an example of Boolean difference without any precision error where l_{A} and l_{B} are both removed and two new maximal lines l′₁ with endpoints H_{A} and H_{B} and l′₂ with endpoints T_{B} and T_{A} are created. FIG. 21B illustrates an example of Boolean difference with precision errors where l_{A} and l_{B} are both removed and two new maximal lines l′₁ with new endpoints H′₁ and T′₁ and l′₂ with new endpoints H′₂ and T′₂ are created.

Referring to FIG. 19, a line maximization process with calibration can be performed by the maximal line modeler 600. The calibration mechanism can address precision errors that arise from floating-point arithmetic in CAD geometry. When two lines are recognized as equal within specified tolerances, the maximization process can remove both original lines and create a new maximal line embedded in a calibrated carrier.

With continued reference to FIG. 19, when two lines l_{A} and l_{B} are recognized as equal, both lines can be removed and a new line l′ with new endpoints H′ and T′ can be created and embedded in a new hyperplane h′. The new hyperplane h′ can be computed as the bisector of the hyperplane h_{A} and the hyperplane h_{B} where the original lines l_{A} and l_{B} are embedded. The endpoint H′ can be computed as the intersection of the new hyperplane h′ and a line segment connecting the endpoints H_{A} and H_{B}. The endpoint T′ can be computed as the intersection of the new hyperplane h′ and a line segment connecting the endpoints T_{A} and T_{B}.

Referring to FIGS. 20A-20B, an example of line maximization for two collinear lines can be illustrated. FIG. 20A can illustrate a maximization process without precision error where two lines l_{A} and l_{B} are collinear and only one endpoint of l_{B} occurs between two endpoints of l_{A}. In the case without precision error, both lines l_{A} and l_{B} can be removed and a new maximal line with endpoints H_{A} and T_{B} can be created.

With continued reference to FIGS. 20A-20B, FIG. 20B can illustrate a maximization process with precision errors. In the case with precision errors, a bisector of h_{A} and h_{B} can be created as the new hyperplane h′. The system can mark out two temporary points H′_{A} and T′_{B} on h_{B} and h_{A} respectively. The new maximal line can be created with endpoints H′ and T′, where H′ can be the point of intersection of the new hyperplane h′ and a line connecting H_{A} and H′_{A}, and T′ can be the point of intersection of the new hyperplane h′ and a line connecting T_{B} and T′_{B}.

The endpoint that would be kept if there were no precision error can be calibrated by projecting the endpoint onto the new hyperplane, which can be the bisector of the hyperplanes where the lines are embedded. This calibration mechanism can provide tolerances of angle and distance so that rectilinear shapes and non-rectilinear shapes can be supported without requiring shapes to snap onto a grid system.

Referring to FIGS. 21A-21B, the calibration mechanism can also be applied to shape Boolean operations including Boolean union and Boolean subtraction. FIGS. 21A-21B can illustrate an example of calibration in a Boolean difference operation l_{A}−l_{B} where l_{B} is embedded in l_{A} and none of the endpoints of l_{B} coincides with any endpoint of l_{A}.

FIG. 21A can illustrate a Boolean difference operation without precision error. In the case without precision error, both lines l_{A} and l_{B} can be removed and two new maximal lines l′₁ with endpoints H_{A} and H_{B} and l′₂ with endpoints T_{B} and T_{A} can be created.

FIG. 21B can illustrate a Boolean difference operation with precision errors. In the case with precision errors, both lines l_{A} and l_{B} can be removed and two new maximal lines l′₁ with new endpoints H′₁ and T′₁ and l′₂ with new endpoints H′₂ and T′₂ can be created. The new endpoints can be computed by projecting the original endpoints onto a calibrated carrier computed as the bisector of the carriers where the original lines are embedded.

The calibration mechanism can apply the same logic to Boolean operations as to maximization operations, where the kept endpoints can be projected to the new hyperplane. This approach can enable the shape Boolean operations in the rule application unit 800 to handle precision errors consistently with the maximization operations in the maximal line modeler 600.

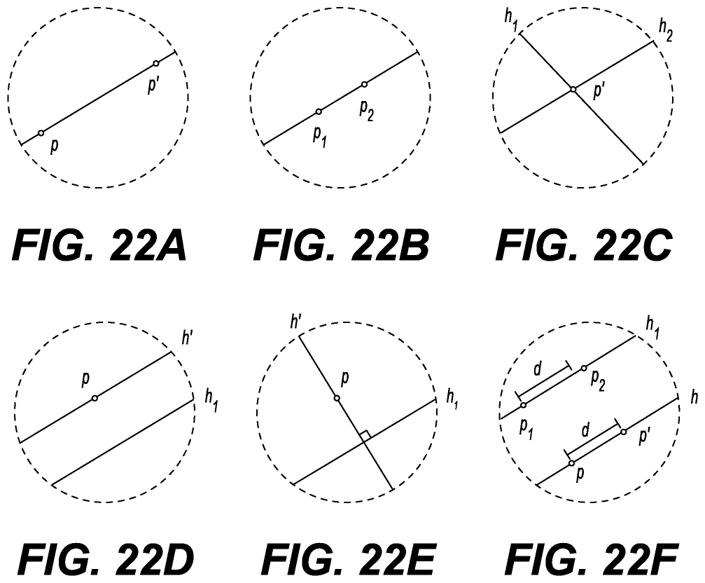

Referring to FIGS. 22A-22F, six geometric operations can be used to support shape embedding calculations and Euclidean constructions within the Shape Machine 200. These geometric operations can provide fundamental building blocks for deriving transformation matrices and constructing geometric relationships between shapes.

FIG. 22A illustrates a first geometric operation for constructing an arbitrary hyperplane through a given point. Given a point p, the first geometric operation can construct a hyperplane h′ that passes through the point p. The hyperplane h′ can extend in any direction from the point p, providing flexibility in establishing geometric relationships.

FIG. 22B illustrates a second geometric operation for constructing a hyperplane with two given points. Given two points p₁ and p₂, the second geometric operation can construct a hyperplane that passes through both points p₁ and p₂. The second geometric operation can be used to establish connections between registration points during shape embedding calculations.

With continued reference to FIGS. 22A-22F, FIG. 22C illustrates a third geometric operation for finding a point of intersection of two given nonparallel hyperplanes. Given two hyperplanes h₁ and h₂ that are not parallel to each other, the third geometric operation can compute the point p′ at which the two hyperplanes h₁ and h₂ intersect. The third geometric operation can be used to derive registration points from carrier intersections.

FIG. 22D illustrates a fourth geometric operation for constructing a hyperplane parallel to a given hyperplane through a given point that is outside the given hyperplane. Given a hyperplane h₁ and a point p that does not lie on the hyperplane h₁, the fourth geometric operation can construct a hyperplane h′ that is parallel to the hyperplane h₁ and passes through the point p.

FIG. 22E illustrates a fifth geometric operation for constructing a hyperplane perpendicular to a given hyperplane through a given point. Given a hyperplane h₁ and a point p, the fifth geometric operation can construct a hyperplane h′ that is perpendicular to the hyperplane h₁ and passes through the point p. The perpendicular relationship can be indicated by a right angle symbol at the intersection of the hyperplanes h₁ and h′.

FIG. 22F illustrates a sixth geometric operation for constructing a point on a hyperplane at a specified distance from another point. Given two points p₁ and p₂, a hyperplane h₁, and a point p on the hyperplane h₁, the sixth geometric operation can construct a point p′ on the hyperplane h₁ such that the distance from the point p′ to the point p equals the distance from the point p₁ to the point p₂. The sixth geometric operation can enable distance transfer operations during geometric constructions.

With continued reference to FIGS. 22A-22F, the six geometric operations can be combined to perform pictorial derivation of transformation matrices for shape embedding under linear transformations. The pictorial approach can decompose high-degree calculations into multiple low-degree calculations to reduce accumulated precision errors caused by floating-point arithmetic in CAD geometry. The derivation of a transformed point p′ under a linear transformation can involve constructing a projective congruent spatial relation between two pairs of registration points using the six geometric operations.

The six geometric operations can support Euclidean constructions within the shape grammar framework. Traditional straightedge and compass constructions can be reworked using the six geometric operations to enable geometric calculations that would otherwise require parametric shape grammar implementations. The intersection operator can use the third geometric operation to find intersection points between line descriptors and arc descriptors, enabling the construction of regular polygons, inscribed circles, and other geometric figures.

The shape embedding engine 700 can use the six geometric operations during the derivation of transformation matrices process 750. When deriving a linear transformation that includes combinations of translation, rotation, reflection, scaling, stretching, shearing, and perspectivity, the geometrical construction can include four registration points to determine the transformation. The pictorial approach can map four registration points r₁, r₂, r₃, and r₄ to four targeted registration points r′₁, r′₂, r′₃, and r′₄ using the six geometric operations in a sequence of construction steps.

The six geometric operations can provide an alternative to algebraic approaches for transformation derivation. The pictorial approach can focus on precision even when the resolution of CAD systems is low, while algebraic approaches can focus on speed when the resolution of the CAD system is high enough to cover accumulated errors. The shape embedding engine 700 can switch between pictorial and algebraic modes based on the type of transformation being derived and the precision requirements of the shape embedding calculation.

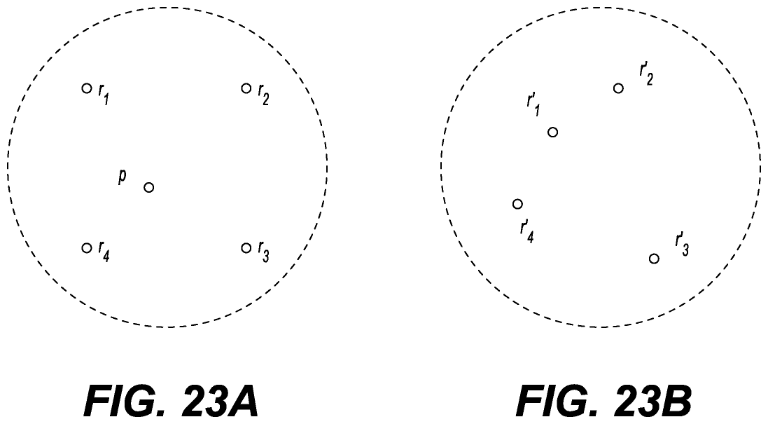

Referring to FIGS. 23A-23B, a pictorial derivation of a linear transformation can be performed through the construction of a projective congruent spatial relation between two pairs of points. FIG. 23A can illustrate a point p with four registration points r₁, r₂, r₃, and r₄ serving as references. FIG. 23B can illustrate four targeted registration points r′₁, r′₂, r′₃, and r′₄ that correspond to the registration points in FIG. 23A. The pictorial approach can derive a transformed point p′ under a linear transformation by mapping the four registration points to the four targeted registration points using geometric construction operations.

With continued reference to FIGS. 23A-23B, the pictorial approach can address problems with calculations that arise during the derivation of transformation matrices, particularly for affine and perspectival transformations. The transformation that can embed a shape u in a shape W can be derived by a series of geometric procedures involving a minimum of numerical calculations. The pictorial approach can geometrically reconstruct a congruent, similar, affine congruent, or projective congruent shape u on the shape W with the selected registration points and their hyperplanes as the references for the mapping.

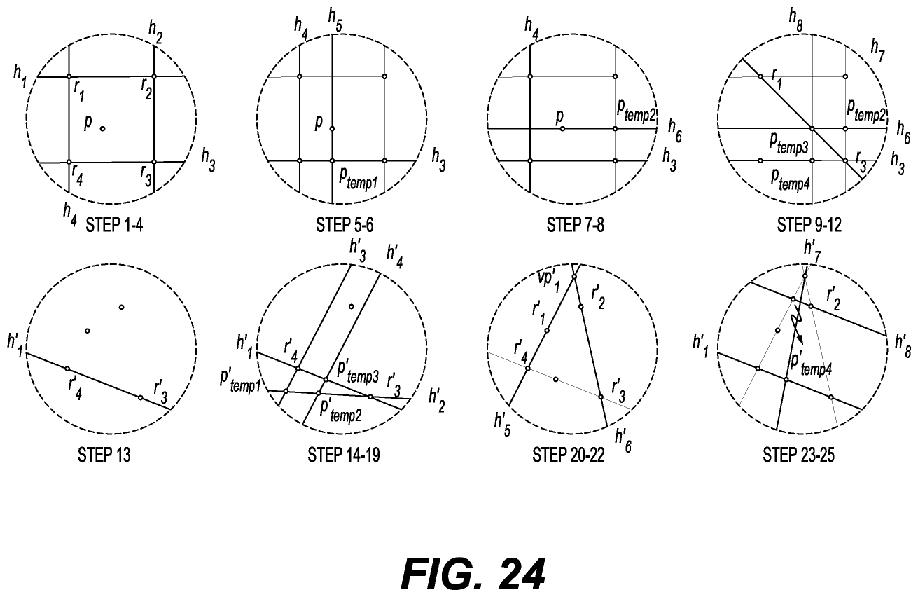

Referring to FIG. 24, steps 1 through 25 of the pictorial approach to derive the transformation for shape embedding under a linear transformation can be illustrated. The pictorial approach can use six geometric operations to construct the transformation. A first geometric operation can construct an arbitrary hyperplane through a given point. A second geometric operation can construct a hyperplane with two given points. A third geometric operation can find a point of intersection of two given non-parallel hyperplanes. A fourth geometric operation can construct a hyperplane parallel to a given hyperplane through a given point that does not lie on the given hyperplane. A fifth geometric operation can construct a hyperplane perpendicular to a given hyperplane through a given point. A sixth geometric operation can construct a point on a given hyperplane at a specified distance from another point.

With continued reference to FIG. 24, the construction can involve all six geometric operations to map the four registration points r₁, r₂, r₃, and r₄ to the four targeted registration points r′₁, r′₂, r′₃, and r′₄. The four registration points can be ordered in eight valid cyclic orderings. The order of the registration points can be a cyclic version of (r₁, r₂, r₃, r₄) or (r₄, r₃, r₂, r₁), and orderings that are not cyclic versions of these sequences can be invalid.

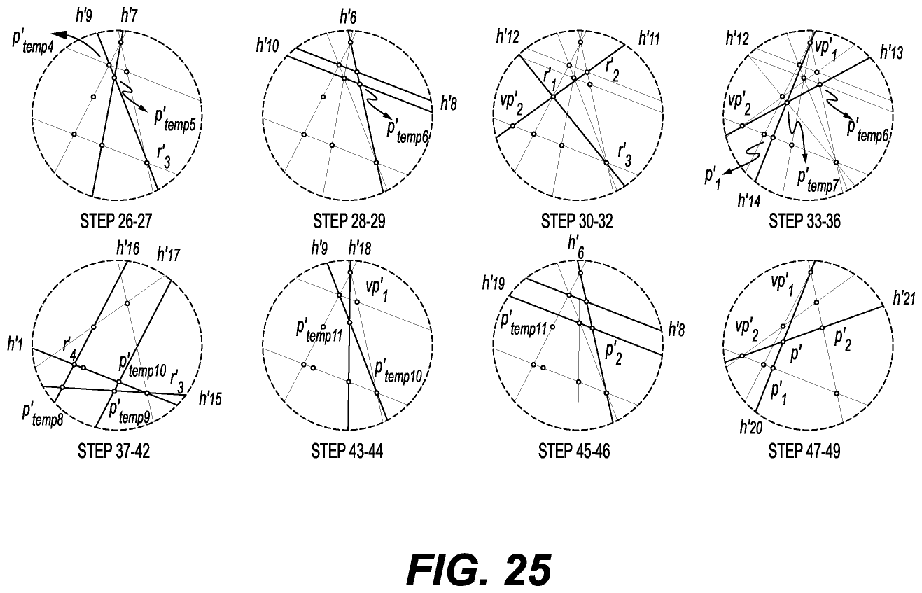

Referring to FIG. 25, steps 26 through 49 of the pictorial approach to derive the transformation for shape embedding under a linear transformation can be illustrated. The pictorial approach can include multiple iterative steps that construct hyperplanes and intersection points to establish the projective congruent spatial relation between the source registration points and the targeted registration points. The construction can proceed through a sequence of geometric operations that progressively build the transformation mapping.

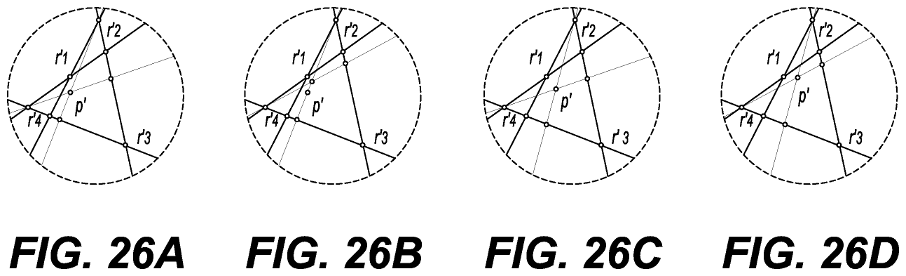

Referring to FIGS. 26A-26D, four results of the pictorial approach for the derivation of linear transformation can be illustrated. The pictorial approach can produce different transformation results depending on the ordering of the registration points and the targeted registration points. Each result can represent a valid linear transformation that maps the source shape to a corresponding position and orientation in the design.

The pictorial approach can decompose high-degree calculations into multiple low-degree calculations to reduce accumulated precision errors caused by floating-point arithmetic in CAD geometry. The derivation of transformation matrices for shape embedding under linear transformations can involve high-degree polynomial calculations that accumulate precision errors when performed using standard algebraic methods. The pictorial approach can avoid accumulated errors by performing geometric constructions that involve only low-degree calculations at each step.

The shape embedding engine 700 can use the pictorial approach as an alternative to algebraic approaches for transformation derivation. The pictorial approach can focus on precision even when the resolution of CAD systems is low, while algebraic approaches can focus on speed when the resolution of the CAD system is high enough to cover accumulated errors. The shape embedding engine 700 can switch between pictorial and algebraic modes based on the type of transformation being derived and the precision requirements of the shape embedding calculation.

The derivation of transformation matrices for shape embedding under Euclidean transformations can include the automated comparison of at least two registration points sampled in the left-hand-side shape u versus all pairs of registration points in the design W. The derivation of transformation matrices for shape embedding under affine transformations can include the automated comparison of at least three registration points sampled in the left-hand-side shape u versus all triplets of registration points in the design W. The derivation of transformation matrices for shape embedding under linear transformations can include the automated comparison of at least four registration points sampled in the left-hand-side shape u versus all quadruplets of registration points in the design W.

The pictorial approach can be applicable for the derivations of isometries, similarities, affinities, and perspectivities. The shape embedding engine 700 can use the algebraic approach for the derivation of isometric, similar, and affine transformations when the accumulated errors are within a manageable range with the calibration mechanism. The shape embedding engine 700 can switch to the pictorial mode for the derivation of linear transformations when the accumulated errors are outside the manageable range even with the calibration mechanism.

Referring to FIGS. 27A-27D, registration point embedding and hyperplane arrangements can be used to reduce a search space for shape embedding operations. The shape embedding engine 700 can use registration point embedding to determine which registration points of a left-hand-side shape u can be embedded in which registration points of a design W.

FIG. 27A can illustrate a design W comprising twelve maximal lines embedded in twelve hyperplanes. The design W can include a configuration of two nested squares, with one square rotated approximately forty-five degrees relative to the other to form a diamond shape within a square. The twelve maximal lines can form the edges of the outer square and the inner rotated square.

FIG. 27B can illustrate thirty-six registration points at which the twelve hyperplanes of the design W intersect. Among the thirty-six registration points, eight registration points can be highlighted by circles to indicate that the eight registration points are able to contain two registration points from the left-hand-side shape u. The registration points can occur at locations where two or more hyperplanes intersect, including at corners of the squares and at locations where edges of the outer square intersect with edges of the inner rotated square.

With continued reference to FIGS. 27A-27D, FIG. 27C can illustrate a shape u comprising six maximal lines embedded in six hyperplanes. The shape u can include a configuration resembling two arrows pointing inward toward each other. The six maximal lines can form the edges of the arrow-like configuration.

FIG. 27D can illustrate eight registration points at which the six hyperplanes of the shape u intersect. Among the eight registration points, two registration points can be highlighted by circles to indicate that the two registration points can only be embedded in the eight registration points highlighted in FIG. 27B. The two highlighted registration points of the shape u can have geometric features that constrain which registration points of the design W can serve as valid embedding targets.

The shape embedding engine 700 can observe that not every registration point of the shape u can be embedded in any registration point of the design W after applying a transformation. By analyzing the geometric features of registration points, the shape embedding engine 700 can determine that only eight out of thirty-six registration points of the design W are able to contain the two registration points of the shape u. This observation can enable the shape embedding engine 700 to reduce the search space for shape embedding operations.

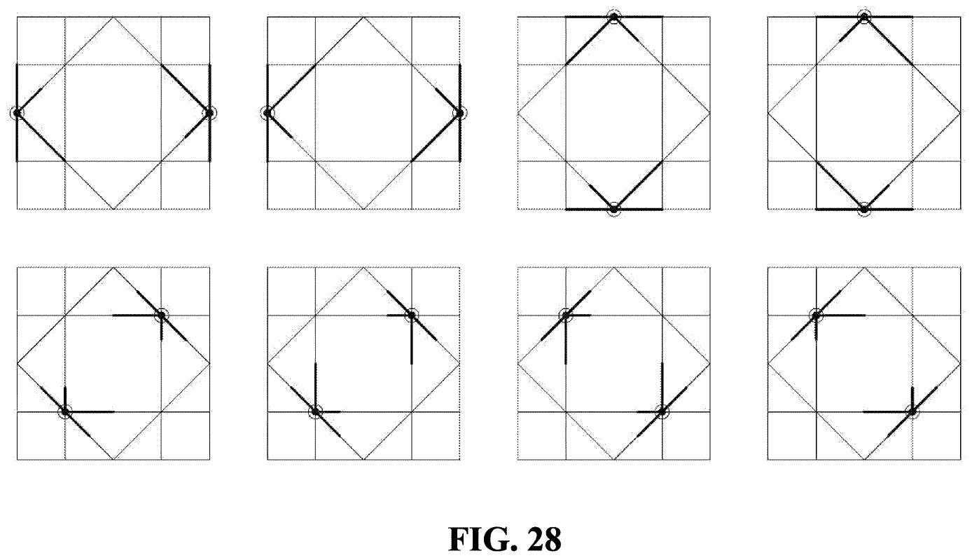

Referring to FIG. 28, shape embedding results under similar transformation can be illustrated. FIG. 28 can depict eight variations of shape embedding results, where each variation shows a square with diagonal lines extending from each corner to form an X pattern, and a rotated inner square positioned at the center. Small circles can appear at various positions on each diagram, indicating registration points where the sampled registration points of the shape u can be embedded into the selected registration points of the design W.

With continued reference to FIG. 28, the eight diagrams can be arranged in two rows of four, with the top row showing four configurations and the bottom row showing four additional configurations. The two sampled registration points of the shape u can only be embedded in the eight selected registration points of the design W. Each of the eight results can represent a different valid embedding transformation that maps the registration points of the shape u to corresponding registration points of the design W under similar transformation.

The shape embedding engine 700 can use weighting and ranking of registration points to reduce the search space before sampling registration points. In the example of FIGS. 27A-27D, the search space can be reduced from C₂³⁶=630 to C₂⁸=28 when processing embedding under similar transformation. If the embedding is processed under affine transformation, the search space can be reduced from C₃³⁶=7140 to C₁⁶=6, where two registration points can be determined and the system selects one from the remaining six registration points.

The registration point weight calculation process 720 can calculate a weight for each registration point based on geometric features of maximal elements intersecting at the registration point. Each registration point can appear as an intersection point of two or more hyperplanes where an equal or greater number of maximal lines are embedded. The weight can encode information about the number of hyperplanes intersecting at the registration point and the configurations of maximal lines relative to the registration point.

The registration point ranking process 730 can rank the registration points based on the calculated weights. The shape embedding engine 700 can sample registration points from the left-hand-side shape u that can be embedded in the least number of registration points of the design W. By selecting registration points with more restrictive weights, the shape embedding engine 700 can reduce the number of candidate transformation matrices that need to be computed and verified.

The shape embedding engine 700 can match registration points of the left-hand-side shape u to registration points of the design W by checking whether the weight of a registration point of the shape u can be embedded in the weight of a registration point of the design W. A registration point of the design W in which a registration point of the shape u can be embedded can have an equal or greater number of hyperplanes. The embedding checking process 780 can verify that the geometric features at the registration point of the design W are sufficient to contain the geometric features at the registration point of the shape u.

Referring to FIGS. 29A-29B, a registration point weight calculation process 720 can calculate a weight for each registration point based on geometric features of maximal elements intersecting at the registration point. FIG. 29A can illustrate a shape comprising ten maximal lines embedded in four hyperplanes. FIG. 29B can illustrate one of the registration points intersected by eight maximal lines embedded in three hyperplanes.

With continued reference to FIGS. 29A-29B, the shape can comprise ten maximal lines embedded in four hyperplanes that intersect at eight registration points. Taking one of the registration points r₇ as an example, eight maximal lines embedded in three hyperplanes can intersect at the registration point r₇. Each registration point can appear as an intersection point of two or more hyperplanes where an equal or greater number of maximal lines are embedded.

A simple method to weight a registration point can involve counting the number of hyperplanes that intersect at the registration point. However, the number of hyperplanes alone can be insufficient to provide practical performance improvements. To obtain more improvement, more information about the maximal lines can be introduced into the weight calculation.

Referring to FIGS. 30A-30C, three configurations of a maximal line and a registration point can be defined. FIG. 30A can illustrate a first configuration c₁ where the registration point does not occur on the maximal line. In the first configuration c₁, the registration point can be located at a position where the carrier of the maximal line passes through, but the maximal line itself does not extend to that position.

FIG. 30B can illustrate a second configuration c₂ where the registration point occurs on an endpoint of the maximal line. In the second configuration c₂, the registration point can coincide with one of the two endpoints that define the boundary of the maximal line along the carrier.

FIG. 30C can illustrate a third configuration c₃ where the registration point occurs on the body of the maximal line. In the third configuration c₃, the registration point can be located between the two endpoints of the maximal line, such that the maximal line passes through the registration point.

With continued reference to FIGS. 30A-30C, the three configurations c₁, c₂, and c₃ can be in part relations such that c₁<c₂<c₃. Any registration point of a design W where a maximal line with the configuration c₃ can be embedded can also be a possible registration point for a maximal line with configurations c₂ or c₁ to be embedded. In other words, if a registration point of a left-hand-side shape u with the configuration c₃ can be embedded in a registration point of the design W, there can be a possibility to embed a registration point that has configuration c₂ or c₁ in the registration point of the design W.

Referring to FIGS. 31A-31C, the configuration of each maximal line intersecting at a registration point can be normalized. FIG. 31A can illustrate three normalized maximal lines embedded in a hyperplane h₁. FIG. 31B can illustrate two normalized maximal lines embedded in a hyperplane h₂. FIG. 31C can illustrate three normalized maximal lines embedded in a hyperplane h₄. The normalized maximal lines can represent the configurations of the maximal lines relative to the registration point, organized according to the hyperplanes in which the maximal lines are embedded.

To obtain a simplest form of the weight of a registration point, the normalized maximal lines can be merged according to the part relations among the normalized maximal lines. For instance, normalized lines l₁ and l₂ can be merged because the normalized lines have equivalent chance to be embedded. Similarly, lines l₆ and l₈ can be merged into l₇ because both l₆ and l₈ are parts of l₇.

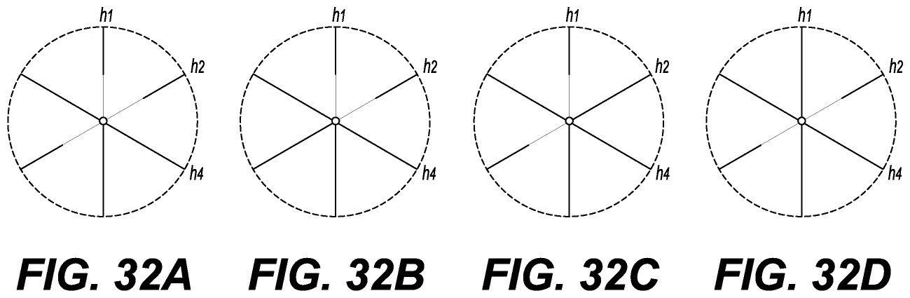

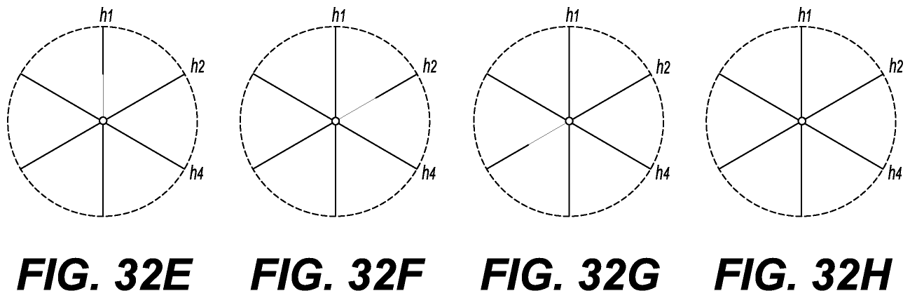

Referring to FIGS. 32A-32H, the simplest form of the normalized maximal lines intersecting at a registration point and supersets of the normalized weight can be illustrated. FIG. 32A can illustrate the simplest form of the normalized maximal lines intersecting at the registration point. FIGS. 32B-32H can illustrate seven supersets of the normalized weight of the registration point. The supersets can represent alternative configurations that can contain the simplest form of the weight.

With continued reference to FIGS. 32A-32H, each diagram can show a registration point at the center with normalized maximal lines extending outward in different configurations. The lines extending from the center point can be labeled with hyperplane identifiers h₁, h₂, h₃, and h₄. The different configurations can represent different possible arrangements of hyperplanes passing through a common intersection point.

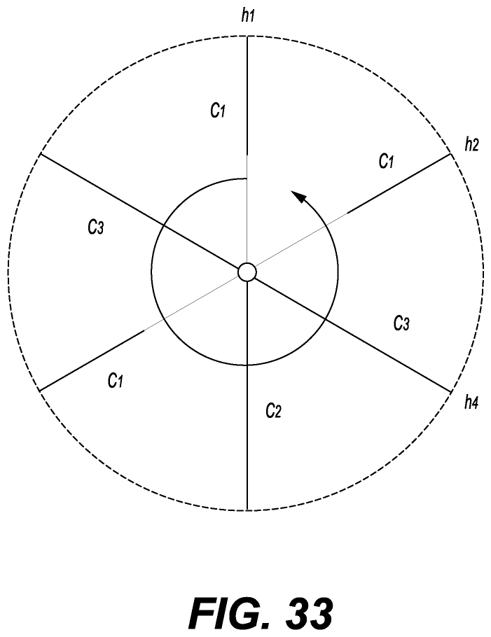

Referring to FIG. 33, a data representation of the weight of a registration point can be obtained by following a convention to describe the weight. The convention can involve standing on a registration point and looking outward in a direction along any hyperplane and recording the configurations of the maximal lines one by one in a counter-clockwise rotation. The simplest form of weight of a registration point can be described as a sequence of configurations such as c₁-c₃-c₁-c₂-c₃-c₁.

With continued reference to FIG. 33, the weight can be rewritten in a folded form to describe the weight more precisely. In the folded form, configurations embedded in the same hyperplane can be grouped together. The folded form can indicate which configurations belong to the same hyperplane and can facilitate comparison between weights of different registration points.

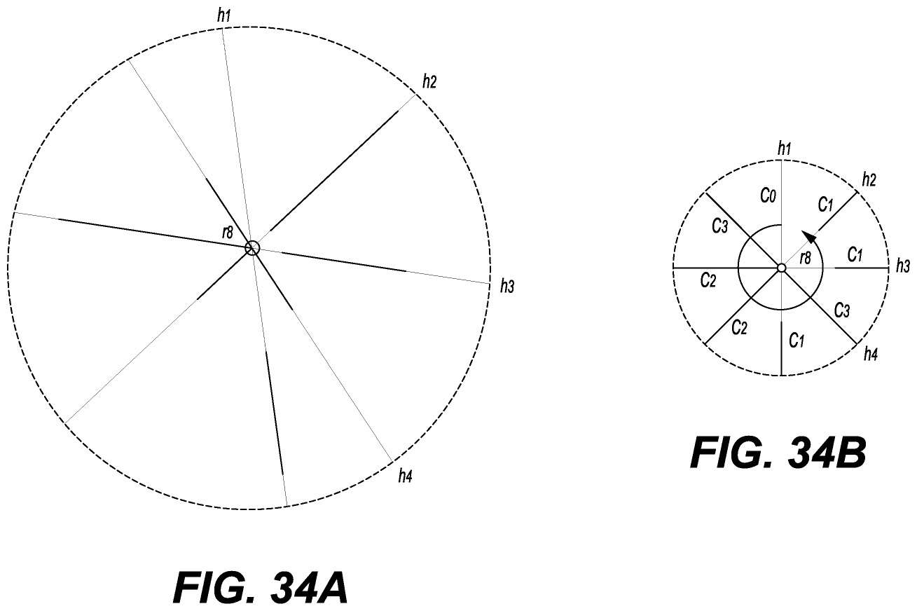

Referring to FIGS. 34A-34B, a registration point r_{B} at which four hyperplanes intersect can be illustrated. FIG. 34A can illustrate a registration point at which six maximal lines embedded in four hyperplanes intersect. FIG. 34B can illustrate the normalized form of registration point r_{B}. The weight of registration point r_{B} can be a superset of the weight of the registration point shown in FIGS. 32A-32B.

A registration point of the design W in which a registration point of the left-hand-side shape u can be embedded can have more hyperplanes than the registration point of the left-hand-side shape u. The shape embedding engine 700 can check if a registration point of the left-hand-side shape u can be embedded into a registration point of the design W by checking the weights in a cyclic manner.

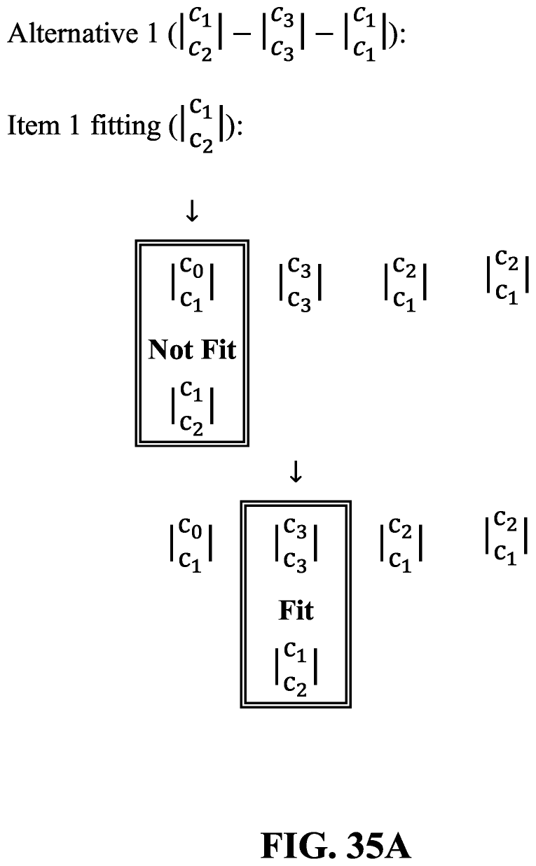

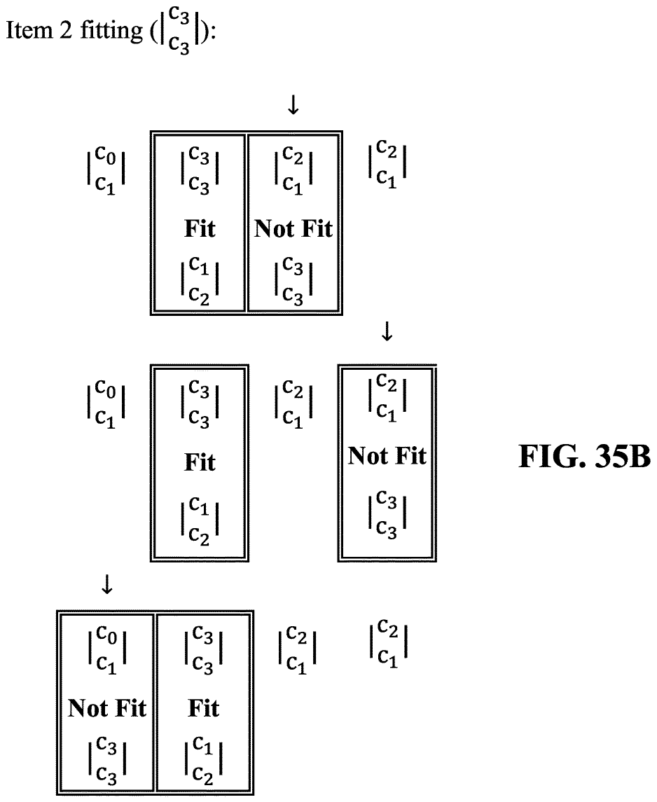

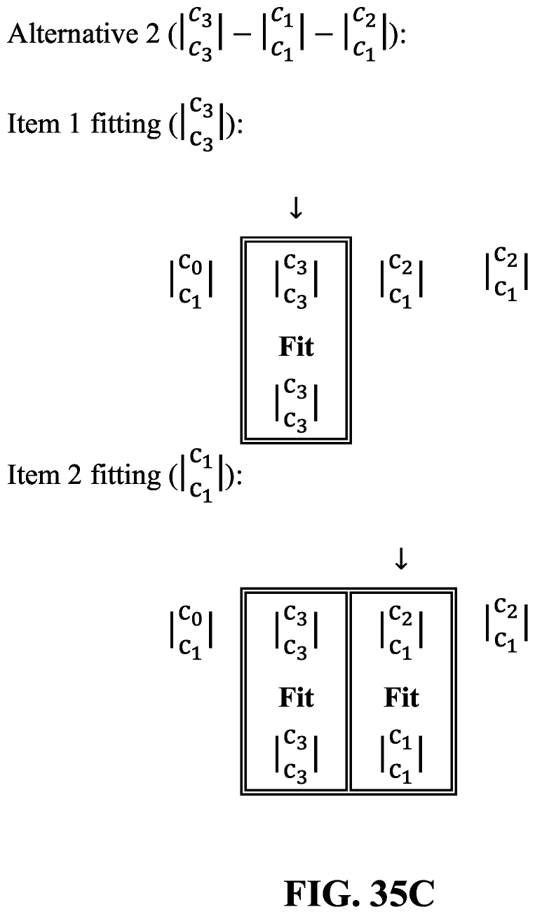

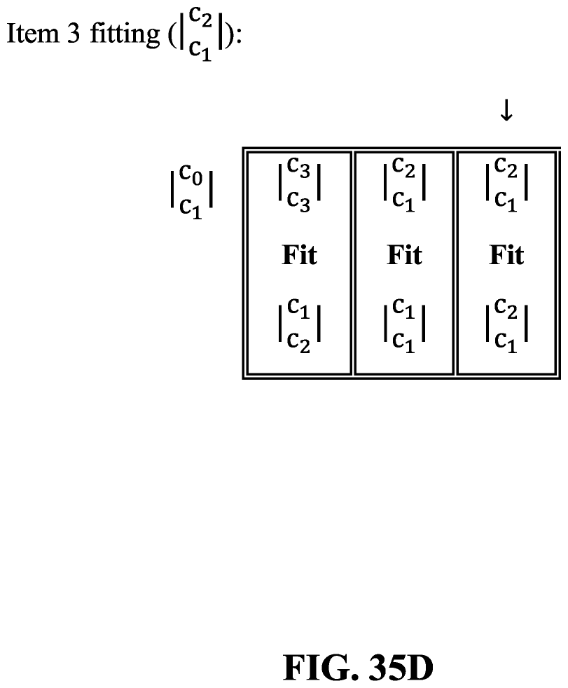

Referring to FIGS. 35A-35D, a fitting process for embedding registration points can be illustrated. The shape embedding engine 700 can check if a first item of a weight w_{A} is a subset of an item of a weight w_{B} with the smallest index. After fitting the first item into w_{B}, the shape embedding engine 700 can start to fit a second item into w_{B}. The second item can only be fit into items after the position where the first item was fit because of the cyclic order.

With continued reference to FIGS. 35A-35D, if there is no item of w_{B} after the fitted position that is a superset of the next item of w_{A}, the alternative of w_{A} can fail to be fit into w_{B}. The shape embedding engine 700 can then process the next alternative until all items of w_{A} can be fit into w_{B}. If all items of w_{A} can fit into w_{B} in order, the registration point r_{B} can be labeled as a candidate for embedding.

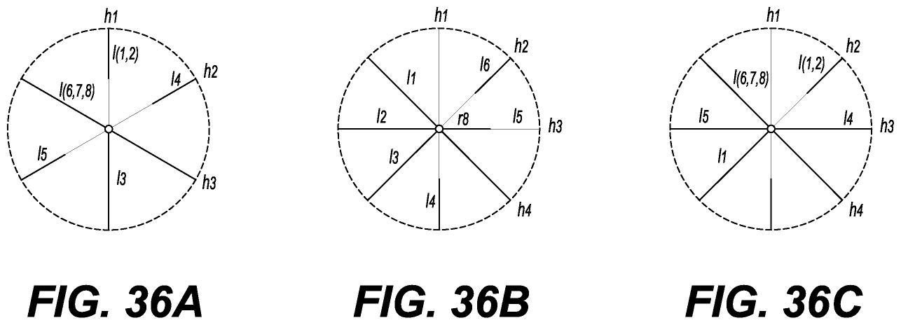

Referring to FIGS. 36A-36C, a visualization of registration point embedding can be illustrated. FIG. 36A can illustrate a normalized registration point at which five normalized maximal lines embedded in three hyperplanes intersect. FIG. 36B can illustrate a normalized registration point at which six normalized maximal lines embedded in four hyperplanes intersect. FIG. 36C can illustrate the result of embedding. The length of the lines and the angles between hyperplanes can be discarded in the weight representation because the diagrams can explain how the shape embedding engine 700 generates the weight for each registration point.

The registration point ranking process 730 can rank the registration points based on the calculated weights. The shape embedding engine 700 can sample registration points from the left-hand-side shape u that can be embedded in the least number of registration points of the design W. By selecting registration points with more restrictive weights, the shape embedding engine 700 can reduce the number of candidate transformation matrices that need to be computed and verified during the embedding checking process 780.

Referring to FIGS. 31A-31C, the configuration of each maximal line intersecting at a registration point can be normalized to facilitate weight calculation and comparison during shape embedding operations. The normalization process can organize the maximal lines according to the hyperplanes in which the maximal lines are embedded, enabling the shape embedding engine 700 to compare registration points across different shapes.

FIG. 31A can illustrate three normalized maximal lines embedded in a hyperplane h₁. Each normalized maximal line can be represented as a line segment extending from a central registration point outward along the direction of the hyperplane h₁. The three normalized maximal lines l₁, l₂, and l₃ can each have a configuration that indicates the relationship between the maximal line and the registration point.

FIG. 31B can illustrate two normalized maximal lines embedded in a hyperplane h₂. The two normalized maximal lines l₄ and l₅ can extend from the registration point along the direction of the hyperplane h₂. The hyperplane h₂ can be oriented at a different angle than the hyperplane h₁ shown in FIG. 31A.

FIG. 31C can illustrate three normalized maximal lines embedded in a hyperplane h₄. The three normalized maximal lines 16, 17, and 18 can extend from the registration point along the direction of the hyperplane h₄. The hyperplane h₄ can be oriented at yet another angle relative to the hyperplanes h₁ and h₂.

With continued reference to FIGS. 31A-31C, the normalized maximal lines can represent the configurations of the maximal lines relative to the registration point, organized according to the hyperplanes in which the maximal lines are embedded. The normalization process can enable the shape embedding engine 700 to compare the geometric features at registration points without regard to the absolute positions or orientations of the maximal lines in the design.

To obtain a simplest form of the weight of a registration point, the normalized maximal lines can be merged according to part relations among the normalized maximal lines. For instance, normalized lines l₁ and l₂ can be merged because the normalized lines have equivalent chance to be embedded. Similarly, lines l₆ and l₈ can be merged into l₇ because both l₆ and l₈ are parts of l₇.

Referring to FIGS. 32A-32H, the simplest form of the normalized maximal lines intersecting at a registration point and supersets of the normalized weight can be illustrated. FIG. 32A can illustrate the simplest form of the normalized maximal lines intersecting at the registration point after the merging process. FIGS. 32B-32H can illustrate seven supersets of the normalized weight of the registration point.

With continued reference to FIGS. 32A-32H, each diagram can show a registration point at the center with normalized maximal lines extending outward in different configurations. The lines extending from the center point can be labeled with hyperplane identifiers h₁, h₂, h₃, and h₄. The different configurations can represent different possible arrangements of hyperplanes passing through a common intersection point.

The supersets can represent alternative configurations that can contain the simplest form of the weight. A registration point of a design W in which a registration point of a left-hand-side shape u can be embedded can have an equal or greater number of hyperplanes than the registration point of the left-hand-side shape u. The shape embedding engine 700 can use the supersets to determine which registration points of the design W are valid embedding targets for registration points of the left-hand-side shape u.

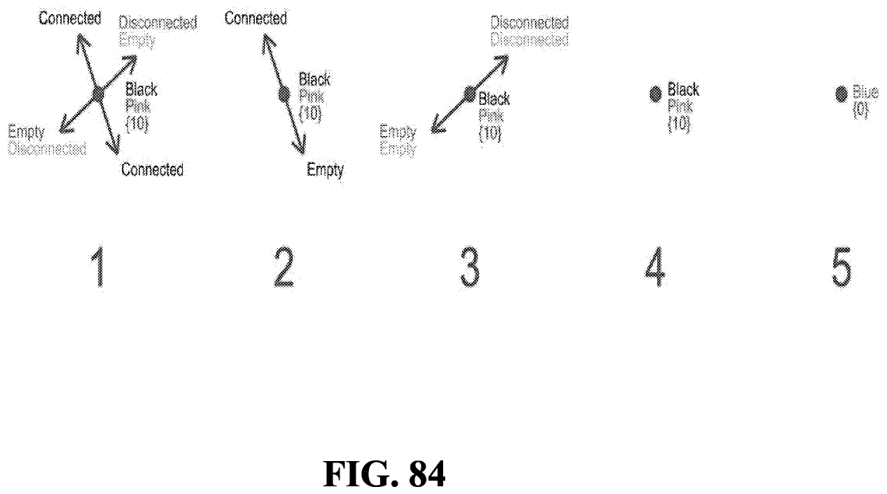

Referring to FIG. 84, registration point signatures can be computed from spoke directions and attribute mappings. The registration point signatures can correspond to registration points of a shape, where spokes can be shown as arrows extending from each registration point. The spoke types corresponding to each attribute can be shown in corresponding attribute colors.

The shape embedding engine 700 can compute registration point signatures through a process that includes creating spokes for each line carrier passing through an intersection. Two spokes can be created for each line carrier passing through the intersection. A spoke can encode information about the half of the line carrier on one side of the registration point. Each carrier can create two spokes because each spoke represents one half of the carrier extending in opposite directions from the registration point.

A spoke can include a vector direction of the half-carrier and a map from each element attribute present on the carrier to a spoke type. The spoke type can indicate whether a line with a particular attribute on the half-carrier meets the registration point, whether all lines with that attribute on the half-carrier do not meet the registration point, or whether no lines with that attribute exist on the half-carrier. In the case where no lines with a particular attribute exist on one half-carrier, the other half-carrier can contain a line with that attribute.

Registration points created by arc carriers can include information about the radii of the arc carriers. Registration points created by point carriers can be provided with a radius of zero. Registration points created by point and arc carriers can also contain a set of all attributes found on the carriers. The attributes can be referred to herein as direct attributes.

With continued reference to FIG. 84, the registration point signatures can include direct attributes depicted as color labels such as “Black,” “Pink,” and “Blue,” corresponding to the attributes of the geometry associated with the carriers passing through the corresponding registration points. Radii sets can be depicted in notation adjacent to each registration point signature.

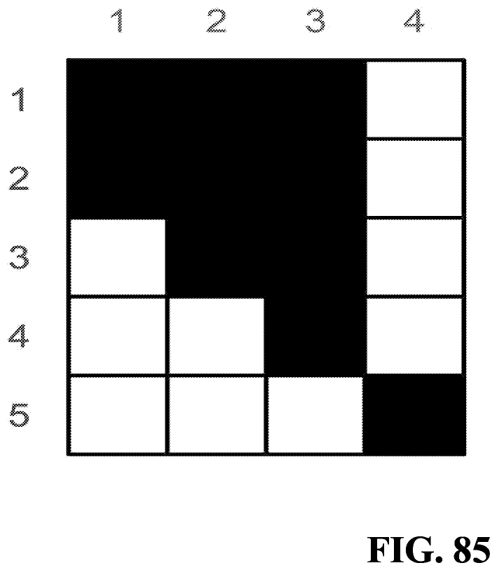

Referring to FIG. 85, a hypergraph incidence matrix can be created for a shape signature. The hypergraph incidence matrix can contain a row for each registration point and a column for each carrier. A value of one in row i and column j can indicate that registration point i was created by carrier j. The hypergraph incidence matrix can represent the topological relationships between registration points and carriers in the shape signature.

The shape embedding engine 700 can use the hypergraph incidence matrix during the registration point matching process. Registration points can be considered neighbors if there is a column where both registration points' corresponding cells are shaded, indicating that both registration points were created by the same carrier. The neighbor relationships can be used during breadth-first-search exploration of the hypergraph when matching registration points of a query shape to registration points of a design.

The significance of a registration point can be determined by multiple factors including the number of radii at the registration point, the number of direct attributes associated with point and arc carriers that created the registration point, the number of spokes on the registration point, and the commonality of attributes in the design signature. The shape embedding engine 700 can select the most significant query registration point as an anchor for matching to registration points in the design.

When determining if a design registration point is a valid match for a query registration point, the radii, direct attributes, number of spokes, and spoke attributes can be compared. The design registration point cannot be smaller than the query registration point. If the computed transformation is to be an isometry, each radius in the query registration point can also be present in the design registration point.

Referring to FIG. 33, a data representation of a weight of a registration point can be obtained by following a convention to describe the weight. The convention can involve standing on a registration point and looking outward in a direction along any hyperplane and recording the configurations of the maximal lines one by one in a counter-clockwise rotation. The weight of a registration point can encode information about the hyperplanes intersecting at the registration point and the configurations of maximal lines relative to the registration point.

With continued reference to FIG. 33, the simplest form of weight of a registration point can be described as a sequence of configurations. For example, a weight can be expressed as c₁-c₃-c₁-c₂-c₃-c₁, where each configuration c₁, c₂, or c₃ represents the relationship between a maximal line and the registration point along a particular direction. The sequence can capture the cyclic arrangement of configurations as observed when rotating counter-clockwise around the registration point.

The weight can be rewritten in a folded form to describe the weight more precisely. In the folded form, configurations embedded in the same hyperplane can be grouped together. For example, a folded form of the weight can be expressed as column vectors separated by dashes, where each column vector contains the configurations associated with a single hyperplane. The folded form can indicate which configurations belong to the same hyperplane and can facilitate comparison between weights of different registration points.

Referring to FIGS. 34A-34B, a registration point r_{B} at which four hyperplanes intersect can be illustrated. FIG. 34A can illustrate a registration point at which six maximal lines embedded in four hyperplanes intersect. FIG. 34B can illustrate the normalized form of registration point r_{B}. The weight of registration point r_{B} can be a superset of the weight of a registration point having fewer hyperplanes.

With continued reference to FIGS. 34A-34B, a registration point of a design W in which a registration point of a left-hand-side shape u can be embedded can have more hyperplanes than the registration point of the left-hand-side shape u. The weight representation can include a configuration c₀ in addition to configurations c₁, c₂, and c₃. The configuration c₀ can represent a case where no maximal line with a particular attribute exists on a half-carrier extending from the registration point.

The folded form of the weight of registration point r_{B} can be expressed as a sequence of column vectors, where each column vector corresponds to one of the four hyperplanes intersecting at the registration point. The first column vector can contain configurations c₀ and c₁, representing the configurations of maximal lines embedded in a first hyperplane. The second column vector can contain configurations c₃ and c₃, representing the configurations of maximal lines embedded in a second hyperplane. The third and fourth column vectors can each contain configurations c₂ and c₁, representing the configurations of maximal lines embedded in the third and fourth hyperplanes respectively.

The weight representation can have multiple alternative forms depending on which hyperplane serves as the starting point for the counter-clockwise rotation. Each alternative form can represent the same weight but with a different cyclic ordering of the column vectors. The shape embedding engine 700 can use any of the alternative forms when checking whether a registration point of the left-hand-side shape u can be embedded in a registration point of the design W.

The data representation of the weight can enable the shape embedding engine 700 to compare registration points across different shapes without regard to the absolute positions or orientations of the maximal lines in the design. The folded form can preserve information about which configurations belong to the same hyperplane, which can be used during the cyclic fitting process to determine valid embedding candidates. The weight representation can reduce the search space for shape embedding operations by enabling the shape embedding engine 700 to identify registration points of the design W that have sufficient geometric features to contain the geometric features at registration points of the left-hand-side shape u.

Referring to FIGS. 35A-35D, a fitting process for embedding registration points can be illustrated. The shape embedding engine 700 can check whether a registration point r_{A} of a left-hand-side shape u can be embedded into a registration point r_{B} of a design W by checking the weights of the registration points in a cyclic manner. The fitting process can determine whether the weight w_{A} of registration point r_{A} can be fit into the weight w_{B} of registration point r_{B}.

FIG. 35A can illustrate an initial step of the fitting process. The shape embedding engine 700 can check whether a first item of the weight w_{A} is a subset of an item of the weight w_{B} with the smallest index. The first item of w_{A} can comprise a column vector containing configurations such as c₁ and c₂, where each configuration represents the relationship between a maximal line and the registration point along a particular direction. The shape embedding engine 700 can search through the items of w_{B} to find the item with the smallest index that is a superset of the first item of w_{A}.

With continued reference to FIGS. 35A-35D, after fitting the first item of w_{A} into w_{B}, the shape embedding engine 700 can start to fit a second item of w_{A} into w_{B}. The second item can only be fit into items of w_{B} that occur after the position where the first item was fit because of the cyclic order of the weight representation. The cyclic order can preserve the angular arrangement of configurations as observed when rotating counter-clockwise around the registration point.

FIG. 35B can illustrate a cyclic fitting process for embedding registration point weights. The shape embedding engine 700 can process the items of w_{A} sequentially, attempting to fit each item into a corresponding item of w_{B} while maintaining the cyclic order. If there is no item of w_{B} after the fitted position that is a superset of the next item of w_{A}, the current alternative of w_{A} can fail to be fit into w_{B}.

FIG. 35C can illustrate a continuation of the cyclic fitting process. When an alternative of w_{A} fails to be fit into w_{B}, the shape embedding engine 700 can process the next alternative. The weight w_{A} can have multiple alternative forms depending on which hyperplane serves as the starting point for the counter-clockwise rotation. Each alternative form can represent the same weight but with a different cyclic ordering of the column vectors.

FIG. 35D can illustrate fitting an item into a data structure during shape computation. The shape embedding engine 700 can continue processing alternatives until all items of w_{A} can be fit into w_{B} in order. If all items of w_{A} can fit into w_{B} in order, the registration point r_{B} can be labeled as a candidate for embedding. The candidate registration points can be used in subsequent steps of the shape embedding process to compute transformation matrices.

With continued reference to FIGS. 35A-35D, the fitting process can account for the fact that a registration point of the design W in which a registration point of the left-hand-side shape u can be embedded can have more hyperplanes than the registration point of the left-hand-side shape u. The weight of a registration point in the design W can be a superset of the weight of a registration point in the left-hand-side shape u. The shape embedding engine 700 can use the subset and superset relationships between weight items to determine which registration points of the design W are valid embedding targets for registration points of the left-hand-side shape u.

The fitting process can reduce the search space for shape embedding operations by eliminating registration points of the design W that do not have sufficient geometric features to contain the geometric features at registration points of the left-hand-side shape u. By checking the weights in a cyclic manner, the shape embedding engine 700 can efficiently determine whether a registration point embedding is possible without computing full transformation matrices for every possible registration point pairing.

Referring to FIGS. 36A-36C, a visualization of registration point embedding can be illustrated using circular diagrams with line segments and hyperplane indicators. The circular diagrams can represent the geometric relationships used in shape signature calculations, where the weight of each registration point can be depicted in a normalized form that discards absolute geometric features such as line lengths and angles between hyperplanes.

FIG. 36A can illustrate a first circular diagram depicting a normalized registration point r_{A} at which five normalized maximal lines embedded in three hyperplanes intersect. The circular diagram can include a dashed circle boundary with solid line segments extending from a central registration point outward in various directions. The line segments can be labeled with hyperplane identifiers h₁, h₂, h₃, h₄, and h₅ positioned at locations around the perimeter of the circular boundary. The line segments can represent the normalized maximal lines that intersect at the registration point, organized according to the hyperplanes in which the maximal lines are embedded.

With continued reference to FIGS. 36A-36C, FIG. 36B can illustrate a second circular diagram depicting a normalized registration point r_{B} at which six normalized maximal lines embedded in four hyperplanes intersect. The second circular diagram can include a similar dashed circle boundary with solid line segments extending from a central registration point. The line segments can be labeled with hyperplane identifiers h₁, h₂, h₃, h₄, h₅, and h₆. A radius indicator r₃ can be positioned at the center of the circular diagram. Several of the radial line segments can be highlighted to indicate specific geometric relationships relevant to the embedding calculation.

FIG. 36C can illustrate a third circular diagram depicting the result of embedding the registration point r_{A} into the registration point r_{B}. The third circular diagram can show how the normalized maximal lines from the first registration point can be fit into the normalized maximal lines of the second registration point. The line segments can be labeled with hyperplane identifiers h₁, h₂, h₃, h₄, and h₅, and multiple radial line segments can be highlighted to indicate the correspondence between the two registration points.

The circular diagrams in FIGS. 36A-36C can represent the weight of each registration point in a normalized form. The length of the lines and the angles between hyperplanes can be discarded in the weight representation because the diagrams can explain how the shape embedding engine 700 generates the weight for each registration point. The geometric features such as absolute positions and orientations can be discarded during the normalization process, leaving only the topological relationships between the maximal lines and the hyperplanes in which the maximal lines are embedded.

The shape embedding engine 700 can use the circular diagram representation to determine whether a registration point of a left-hand-side shape u can be embedded into a registration point of a design W. The registration point r_{B} of the design W can have more hyperplanes than the registration point r_{A} of the left-hand-side shape u. The shape embedding engine 700 can check whether the weight w_{A} of registration point r_{A} can be fit into the weight w_{B} of registration point r_{B} using a cyclic fitting process.

With continued reference to FIGS. 36A-36C, the cyclic fitting process can involve checking whether each item of the weight w_{A} is a subset of a corresponding item of the weight w_{B}. The items can be fit in a cyclic order, where each subsequent item of w_{A} can only be fit into items of w_{B} that occur after the position where the previous item was fit. When all items of w_{A} can be fit into w_{B} in order, the registration point r_{B} can be labeled as a candidate for embedding.

The circular diagram representation can enable the shape embedding engine 700 to compare registration points across different shapes without regard to the absolute positions or orientations of the maximal lines in the design. The normalized form can preserve information about which configurations belong to the same hyperplane, which can be used during the cyclic fitting process to determine valid embedding candidates. The weight representation can reduce the search space for shape embedding operations by enabling the shape embedding engine 700 to identify registration points of the design W that have sufficient geometric features to contain the geometric features at registration points of the left-hand-side shape u.

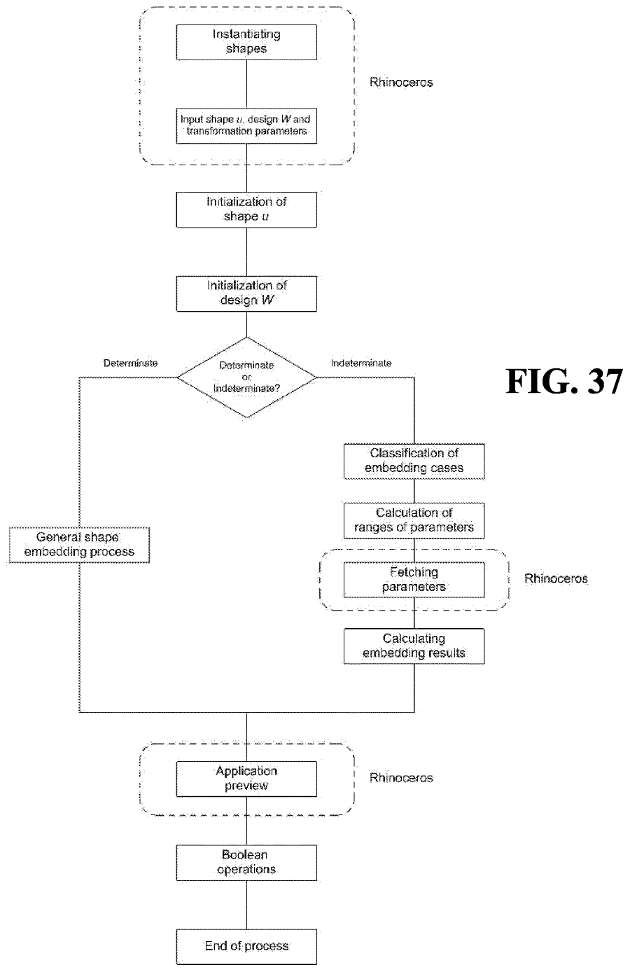

Referring to FIG. 37, a flowchart for a method for shape embedding and shape replacement in a computer-aided design system can be illustrated. FIG. 37 can depict the calculation of shape embedding performed by the Shape Machine 200. Dash-lined blocks in FIG. 37 can represent operations that are processed in a CAD system, such as McNeel Rhinoceros or another computer-aided design application.

The method can begin with a shape instantiation phase. During shape instantiation, the Shape Machine 200 can receive a shape rule comprising a left-hand-side shape u and a right-hand-side shape v from the computer-aided design application via the communication layer 300. The Shape Machine 200 can also receive a design W comprising a plurality of geometric elements from the computer-aided design application.

With continued reference to FIG. 37, an initialization phase can follow the shape instantiation phase. During initialization, the shape rule compiler 400 can unpack the shape rule and extract parameters, attributes, and endpoint coordinates from the left-hand-side shape u and the right-hand-side shape v. The design initializer 500 can similarly process the design W to extract attributes and endpoint coordinates. The maximal line modeler 600 can convert the geometric elements of the shapes u, v, and the design W into maximal element representations by grouping elements on equivalent carriers and computing an average carrier for each group.

The method can proceed to a determinate/indeterminate evaluation phase. The shape embedding engine 700 can determine whether the embedding is determinate or indeterminate by checking the number of registration points of the left-hand-side shape u and the transformation parameters. An embedding can be determinate when the left-hand-side shape u can be embedded into the design W in a finite number of ways. An embedding can be indeterminate when the left-hand-side shape u does not contain sufficient registration points to fully specify the transformation parameters for a specified transformation type.

When the embedding is determinate, the method can proceed along a first pathway. The shape embedding engine 700 can derive registration points from intersections of carriers associated with the maximal element representations. The registration point derivation and reduction process 710 can compute intersections of maximal lines for both the left-hand-side shape u and the design W. The registration point weight calculation process 720 can calculate a weight for each registration point based on geometric features of maximal elements intersecting at the registration point. The registration point ranking process 730 can rank the registration points based on the calculated weights to reduce a search space for shape embedding. The registration point sampling process 740 can sample registration points from the left-hand-side shape u and the design W based on the ranking. The derivation of transformation matrices process 750 can derive transformation matrices from the sampled registration points.

When the embedding is indeterminate, the method can proceed along a second pathway. The process for intermediate embedding process 760 can be activated to calculate ranges of included parameters. The shape embedding engine 700 can send the parameter ranges to the communication layer 300 to compile a message and echo the message back to users to request further parameters. After receiving the parameters from the user, the shape embedding engine 700 can continue the embedding process with the received parameters.

As further shown in FIG. 37, a parameter calculation phase can follow the determinate/indeterminate evaluation phase. The LHS candidates generating process 770 can generate all candidates f(u) using the derived transformations f. The embedding checking process 780 can check all candidates to determine whether the candidates can be embedded into the design W. The embedding checking process 780 can exclude transformations that cannot make the left-hand-side shape u embedded in the design W. The RHS candidate generating process 790 can use the set of valid transformations to generate all corresponding candidates of the right-hand-side shape f(v). The equivalency reduction process 795 can eliminate identical copies for both the left-hand-side shapes and the right-hand-side shapes to keep the results nonequivalent.

An application preview phase can follow the parameter calculation phase. After the shape embedding engine 700 completes processing, all matches fₙ(u) and fₙ(v) can be sent to the communication layer 300 to generate a preview and control parameters for users. The preview of rule application can be generated in real-time and shown on the design. Users can input different parameters to control the system, such as selecting a specific match to apply, applying all matches in parallel, processing matches one by one with results recorded, printing all previews, or exiting without any change.

The method can conclude with a Boolean operations phase. The rule application unit 800 can receive the selected parameters and activate a corresponding procedure to complete the process. The single-application process 810 can apply a selected match to the design. The all-application process 820 can apply all matches in parallel. The each-application process 830 can process matches one by one and record all results. Each procedure can be implemented with Boolean union units and Boolean difference units in addition to a control system. Each Boolean operation unit can be implemented with a calibration mechanism to address precision errors. The Boolean difference operation can remove a transformed instance of the left-hand-side shape f(u) from the design W. The Boolean union operation can add a corresponding transformed instance of the right-hand-side shape f(v) to the design W. The updated design can be maximized and sent back to the computer-aided design application via the communication layer 300.

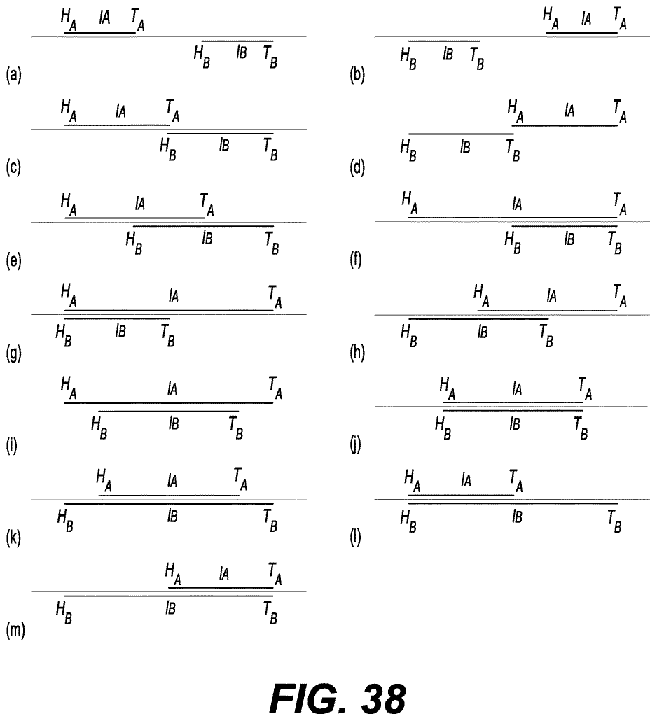

Referring to FIG. 38, the maximal line modeler 600 can examine spatial relations between two collinear lines to determine whether the lines can be fused into a single maximal line. FIG. 38 can illustrate thirteen cases of spatial relations between two collinear lines, denoted as line l_{A} and line l_{B}. The thirteen cases can be categorized based on the intersection characteristics between the two lines.

FIGS. 38A and 38B can illustrate two cases where the two lines do not intersect. In these cases, the lines can be collinear but separated by a gap, and no Boolean union operation can be performed to combine the lines into a single maximal line.

FIGS. 38C and 38D can illustrate two cases where the two lines intersect at endpoints. In these configurations, the endpoint of one line can coincide with an endpoint of the other line, enabling the lines to be joined at the shared endpoint.

FIGS. 38E and 38H can illustrate two cases where the intersection of the two lines is a part of both lines. In these configurations, the lines can overlap partially, with the overlapping region being contained within both line l_{A} and line l_{B}.

FIGS. 38F and 38G can illustrate two cases where the intersection of the two lines is line l_{B} with the alignment of one endpoint. In these configurations, line l_{B} can be fully contained within line l_{A}, with one endpoint of line l_{B} coinciding with an endpoint of line l_{A}.

FIG. 38I can illustrate the case where the intersection of the two lines is line l_{B} and no endpoint is aligned. In this configuration, line l_{B} can be fully embedded within line l_{A} without any endpoint coincidence.

FIG. 38J can illustrate the case where the two lines are equal. In this configuration, line l_{A} and line l_{B} can have the same endpoints and can be recognized as identical lines within a calibration tolerance.

FIG. 38K can illustrate the case where the intersection of the two lines is line l_{A} and no endpoint is aligned. In this configuration, line l_{A} can be fully embedded within line l_{B} without any endpoint coincidence.

FIGS. 38L and 38M can illustrate two cases where the intersection of the two lines is line l_{A} with the alignment of one endpoint. In these configurations, line l_{A} can be fully contained within line 6B, with one endpoint of line l_{A} coinciding with an endpoint of line l_{B}.

With continued reference to FIG. 38, the maximal line modeler 600 can examine nine features for each pair of lines to determine the spatial relation between the pair. Among the cases where lines are parallel or collinear, a Boolean union operation can be processed on cases where the lines overlap or share endpoints to obtain the maximal line representation. The spatial relation analysis can enable the line relationships checking process 610 to identify which pairs of lines can be combined during the line grouping process 620 and the boolean union with calibration process 630.

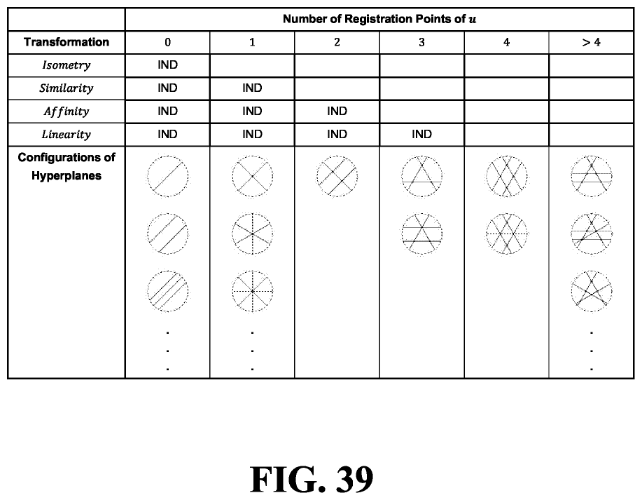

Referring to FIG. 39, a table can illustrate the relationship between transformation types, registration point counts, and hyperplane configurations for shape embedding operations. FIG. 39 can depict fourteen cases of shape embedding for shapes consisting of lines, organized according to the type of geometric transformation and the number of registration points available in the left-hand-side shape.

The transformation types can include isometry, similarity, affinity, and linearity. Isometry transformations can preserve distances and angles, and can include translation, rotation, and reflection operations. Similarity transformations can preserve angles but allow uniform scaling. Affinity transformations can preserve parallelism and can include stretching and shearing operations. Linearity transformations can include perspectivity operations.

With continued reference to FIG. 39, the number of registration points required to derive a transformation matrix can vary based on the transformation type. For isometry transformations, two registration points can be sufficient to derive the transformation matrix. For similarity transformations, two registration points can also be sufficient. For affinity transformations, three non-collinear registration points can be required. For linearity transformations including perspectivity, four registration points in general position can be required.

FIG. 39 can indicate cases labeled as IND, representing indeterminate embedding conditions. An indeterminate embedding condition can occur when the left-hand-side shape does not contain sufficient registration points to fully specify the transformation parameters for a specified transformation type. The shape embedding engine 700 can detect indeterminate embedding conditions based on the number of registration points in the left-hand-side shape and the type of geometric transformation specified.

For isometry transformations, an indeterminate condition can occur when there are no registration points in the left-hand-side shape, or when there is one registration point with no line carriers in the query shape. For similarity transformations, indeterminate conditions can occur when there are no registration points, when there is one registration point with no arcs centered at the point and no line carriers, when there is one registration point with at least one arc centered at the point and no line carriers, or when there is one registration point with spokes and no arcs in the query shape.

For affinity transformations, indeterminate conditions can occur when there are no registration points, when there is one registration point with no line carriers, when there is one registration point with only one spoke and its mirror, when there is one registration point with multiple spokes, when there are multiple collinear registration points with no spokes or all spoke directions along the same line of collinearity, or when there are multiple collinear registration points with spoke directions along the same line of collinearity and other spoke directions that are all parallel.

As further shown in FIG. 39, the table can indicate which transformation properties become indeterminate for each case. Translation can be indeterminate when there are no registration points for isometry, similarity, and affinity transformations. Rotation can be indeterminate when there is one registration point with insufficient directional information. Scale can be indeterminate for similarity and affinity transformations when the registration point configuration does not provide sufficient information to determine the scaling factor. Shear can be indeterminate for affinity transformations when the registration point configuration does not provide sufficient information to determine the shearing parameters. Stretch can be indeterminate for affinity transformations across multiple cases where the registration point configuration does not provide sufficient information to determine the stretching parameters.

When an embedding transformation is indeterminate, the shape embedding engine 700 can create phantom registration points to establish a reference frame for computing the transformation. The reference frame created on the query shape can be a right angle with legs of the same length. The phantom registration points created on the design can be transformed according to the indeterminate parameters specified by user input or calculated parameter ranges. The process for intermediate embedding process 760 can calculate ranges of included parameters and send the parameter ranges to the communication layer 300 to request further parameters from users.

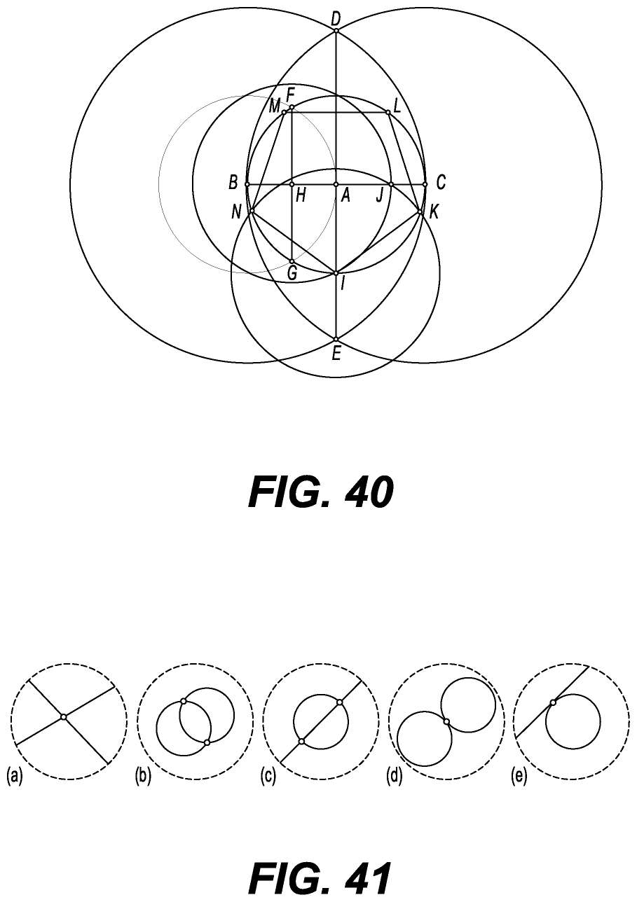

Referring to FIG. 40, the Shape Machine 200 can support Euclidean constructions with straightedge and compass within the shape grammar framework. FIG. 40 can illustrate Ptolemy's construction of a regular pentagon inscribed in a given circle. The construction can comprise multiple steps that demonstrate how geometric constructions can be implemented using shape rules and intersection operators.

The construction of a regular pentagon inscribed in a circle can comprise the following steps. A first step can construct a perpendicular bisector DE of the diameter BC of the circle A and mark the point I at the intersection of DE and the circle A. A second step can construct a perpendicular bisector FG of the radius AB of the circle and parallel to DE at H. A third step can construct a circle with center H and radius HI and mark the intersection J of the circle H with the diameter BC of the circle A. A fourth step can construct a circle with center I and radius IJ and mark the intersection K with the circle A. A fifth step can construct all five sides to complete the pentagon.

With continued reference to FIG. 40, the automation of Euclidean constructions within the shape grammar formalism can present challenges because conventions underlying geometrical constructions, such as marking the intersections of two circles with points, cannot be performed in a straightforward way using shape embedding operations alone. The shape grammar formalism can treat shapes as consisting of basic elements including points, lines, planes, and solids, where lines do not consist of an infinite set of points, endpoints of lines are not parts of lines, and intersections of two lines do not make a point. The Shape Machine 200 can address these challenges by introducing intersection operators that derive intersection points from the descriptors of shape elements.

Referring to FIG. 41, five types of intersection points can exist between element descriptors for shapes made up of line segments and arcs in two-dimensional space. A first type can comprise the intersection point of two line descriptors. A second type can comprise two intersection points of arc descriptors. A third type can comprise two intersection points of an arc descriptor and a line descriptor. A fourth type can comprise a tangent point of two arc descriptors. A fifth type can comprise a tangent point of a line descriptor and an arc descriptor.

The five types of intersection points can be identified with an int operator and converted to a shape made of points at each intersection location by a makePt operator. The operators can be deployed in schema rules of the form x→makePt(int(dsc(prt(x)),dsc(prt(x)))) and x→x+makePt(int(dsc(prt(x)),dsc(prt(x)))). The dsc operator can map a shape to a set of implicit equations of each of the shape's descriptors. The int operator can map two such sets to a set of coordinates. The makePt operator can map these coordinates back to maximal points.

The intersection rule schema can be implemented in four steps. A first step can isolate two subshapes of a design, such as all the maximal lines in a design and all the maximal arcs in a design. A second step can determine the set of element descriptors in both subshapes, deriving all equation coefficients from the endpoints of lines and the center, radius, and endpoints of arcs retrieved from the database of CAD systems. A third step can equate all pairs of descriptor equations, one from the first set of descriptors and one from the second, and solve each equated pair to determine all intersections from descriptors of the first subshape with descriptors of the second. A fourth step can convert the computed intersection locations to a shape comprising maximal points at each intersection location.

The Shape Machine 200 can support labeled shapes and labeled descriptors in the intersection schema. The symbolic representation of the operator can be written to exemplify the color properties of the basic elements of the shape in the calculation. A line operator can be typed in a first color to indicate that only lines labeled in the first color are selected. An arc operator can be typed in a second color to indicate that only arcs labeled in the second color are selected. A makePt operator can be typed in a third color to indicate that the points instantiated can be labeled in the third color. This functionality can reduce the complexity of the process by isolating specific shapes and avoiding instantiation of redundant shapes.

The implementation of Ptolemy's construction of the regular pentagon in the Shape Machine 200 can comprise 27 rules, including 19 shape rules and 8 int operator rules. The construction can proceed through the following steps. A first step can construct a perpendicular bisector of a diameter of the given circle by constructing two circles, one with point B as the center and passing through point C, and a second with point C as the center and passing through point B, then constructing the perpendicular bisector line DE by connecting the points D and E at the intersection points of the two circles.

Some shapes can play a scaffolding role in the generation of the shape, meaning that the shapes are instantiated to help construct new shapes and then the shapes are removed. The scaffolding shapes can include auxiliary arcs used for marking intersection points. The Shape Machine 200 can apply shape rules to instantiate scaffolding shapes and subsequently remove the scaffolding shapes after the scaffolding shapes have served their construction purpose.

A second step of the pentagon construction can construct a perpendicular bisector of a radius of the given circle and parallel to the perpendicular bisector constructed in the first step. A third step can construct a circle with center H passing through I and mark the intersection J with the diameter BC of the given circle, where the distance IJ represents the length of the side of the regular pentagon. A fourth step can construct a circle with center I passing through J and mark the intersection K with circle A, where the distance IK equals IJ and represents one side of the regular pentagon. A fifth step can construct all five sides of the regular pentagon by iteratively constructing circles and connecting vertices.

The Shape Machine 200 can use the intersection schema to enable straightedge and compass constructions that would otherwise be difficult or impossible to achieve without a parametric shape grammar interpreter. The intersection points of the descriptors of basic elements of shapes, which can be used as registration points to enable the search for a possible embedding of a shape u into a shape W under some Euclidean, affine, or linear transformation f, can also be used constructively to enable shape calculations.

The line operator can take a shape x as input and output the subshape line(x) composed of all of the maximal lines of the shape. The arc operator can output the subshape arc(x) composed of all of the maximal arcs of the shape. These operators can allow the extraction of the locations of three possible types of intersections of the descriptors of line elements and arc elements. The three types can comprise intersections of line descriptors with line descriptors, intersections of arc descriptors with arc descriptors, and intersections of line descriptors with arc descriptors.

The Shape Machine 200 can generate schema rules including x→int(line(x),line(x)), x→int(arc(x),arc(x)), and x→int(line(x),arc(x)). The Shape Machine 200 can also generate schema rules including x→x+int(line(x),line(x)), x→x+int(arc(x),arc(x)), and x→x+int(line(x),arc(x)). These schema rules can provide a framework for implementing Euclidean constructions within the shape grammar formalism.

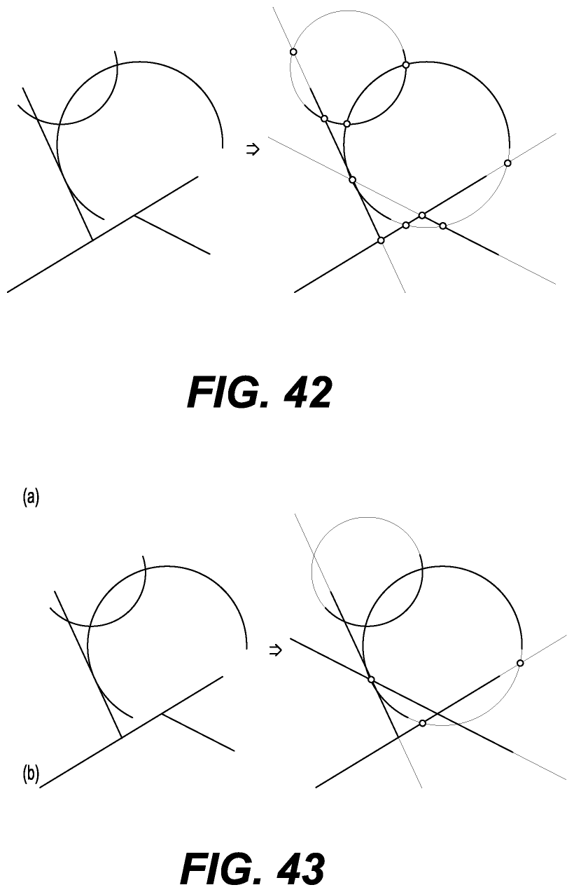

Referring to FIGS. 42-43, the Shape Machine 200 can apply an intersection rule schema to shapes consisting of lines and arcs to produce intersection points. The intersection rule schema can be expressed as x→x+int(prt(x),prt(x)), where the prt operator can return parts of a shape x, the dsc operator can derive descriptors of basic elements, the int operator can compute intersections of descriptor equations, and the makePt operator can convert computed intersection locations to maximal points.

FIG. 42 can illustrate an application of the rule schema on a shape consisting of three lines and two arcs to produce the shape plus ten intersection points. The line and arc descriptors can be denoted by thin line weight and can be given for reference. In the example shown in FIG. 42, the prt operator can return the entirety of the shape x. The int operator can give points coincident to the intersections of pairs of line descriptors, pairs of arc descriptors, and pairs of line descriptors and arc descriptors.

With continued reference to FIGS. 42-43, the intersection rule schema can be implemented in the Shape Machine 200 as a type of rule distinct from shape embedding rules and control flow rules. The intersection rule schema can be denoted by an explicit symbolic representation to distinguish the intersection rule schema from shape embedding rules and control flow rules. The intersection rule schema can work with labeled shapes and labeled descriptors, and can instantiate intersection points with various properties as requested.

FIG. 43 can illustrate an application of the rule schema on a shape consisting of three lines and two arcs labeled in different colors to produce the shape plus three intersection points. FIG. 43(a) can show a makePt operator rule with labeled descriptors. FIG. 43(b) can show the result of rule application on a shape with labeled line segments and arcs. The symbolic representation of the operator can be written to exemplify the color properties of the basic elements of the shape in the calculation.

As further shown in FIG. 43, a line operator can be typed in a first color to indicate that only lines labeled in the first color are selected. An arc operator can be typed in a second color to indicate that only arcs labeled in the second color are selected. A makePt operator can be typed in a third color to indicate that the points instantiated can be labeled in the third color. The script can specify that the operator rule is applied only on arcs and line segments with specified labels and the new shapes can be labeled with a specified color. This functionality can reduce the complexity of the process by isolating specific shapes and can avoid instantiating redundant shapes.

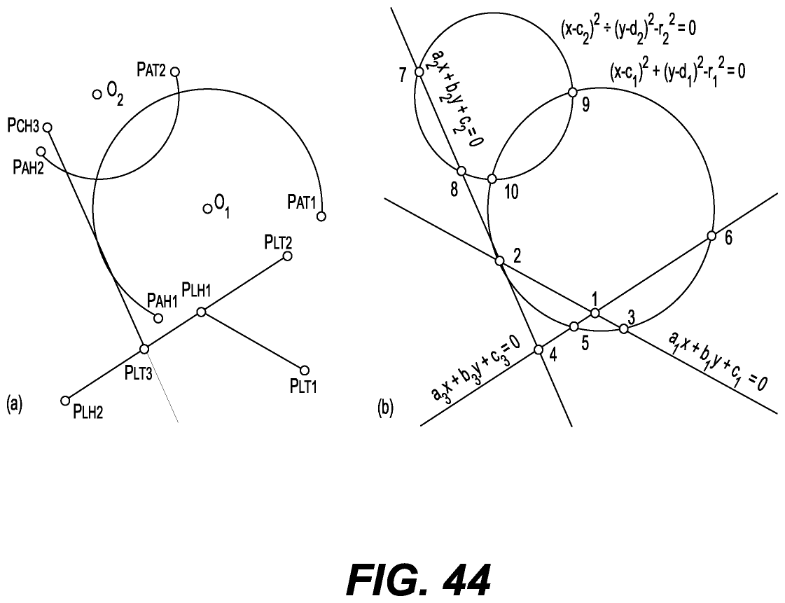

Referring to FIG. 44, the derivation of intersection point locations can involve computing coordinates from descriptor equations. FIG. 44 can illustrate an example of deriving the location coordinates of intersection points in the Shape Machine 200. The descriptors of line segments can be derived by reversely calculating the coefficients with the coordinates of the two endpoints of each line segment.

With continued reference to FIG. 44, a line descriptor can be expressed in the form a₁x+b₁y+c₁=0, where the coefficients a₁, b₁, and c₁ can be derived from the coordinates of the head endpoint and the tail endpoint of the line segment. For a line segment with head endpoint P_{LH} and tail endpoint P_{LT}, the coefficients of the line descriptor equation can be computed from the endpoint coordinates retrieved from the database of CAD systems.

The descriptors of arcs can be expressed in the form (x−c₁)²+(y−d₁)²−r₁²=0, where c₁ and d₁ can represent the x-coordinate and y-coordinate of the center point, and r₁ can represent the radius of the arc. The coefficients of the arc descriptor can be derived by reversely calculating the coefficients with the coordinates of the two endpoints and the center point of the arc. For an arc with center point O, head endpoint P_{AH}, and tail endpoint P_{AT}, the center coordinates and radius can be computed from the geometric data retrieved from the CAD system.

As further shown in FIG. 44, the solutions of each equated pair of descriptor equations can provide the locations of the intersection points. To find the intersection of two line descriptors, the system of two linear equations can be solved simultaneously to obtain the x-coordinate and y-coordinate of the intersection point. To find the intersections of a line descriptor and an arc descriptor, the linear equation can be substituted into the quadratic equation to obtain up to two intersection points. To find the intersections of two arc descriptors, the two quadratic equations can be solved simultaneously to obtain up to two intersection points.

Some solutions of the equated descriptor equations can be identical when the intersections occur at the same location. The Shape Machine 200 can reduce identical coordinates into one coordinate pair to retain the maximality of points. The computed intersection locations can be converted to a shape comprising maximal points at each intersection location by the makePt operator.

The intersection rule schema can be implemented in four steps. A first step can isolate two subshapes of a design, such as all the maximal lines in a design and all the maximal arcs in a design. The first step can be representative of the prt operator. A second step can determine the set of element descriptors in both subshapes, deriving all equation coefficients from the endpoints of lines and the center, radius, and endpoints of arcs retrieved from the database of CAD systems. The second step can be representative of the dsc operator.

A third step can equate all pairs of descriptor equations, one from the first set of descriptors and one from the second, and can solve each equated pair to determine all intersections from descriptors of the first subshape with descriptors of the second. The third step can be representative of the int operator. A fourth step can convert the computed intersection locations to a shape comprising maximal points at each intersection location. The fourth step can be representative of the makePt operator.

The implementation of the intersection operator in the Shape Machine 200 can support interactive instantiation and editing within the interface of the application. By changing the label of the symbolic expression of the operator, the corresponding parts of the shape that are labeled with the same color or layer can be selected. This capability can enable selective computation of intersection points between specific subsets of shape elements based on their attributes.

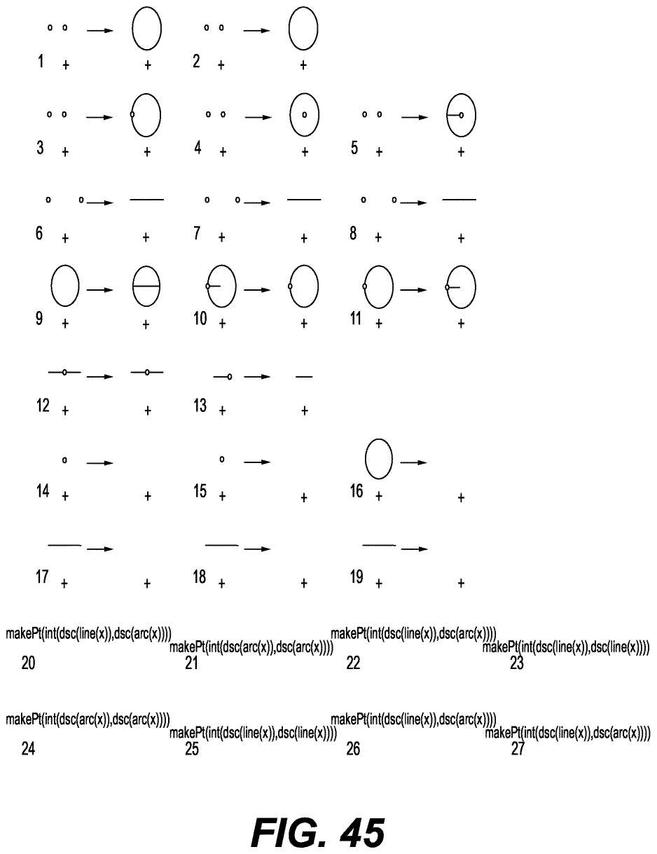

Referring to FIG. 45, the Shape Machine 200 can implement Euclidean constructions using a combination of shape rules and symbolic rules. FIG. 45 can illustrate 27 rules including 19 shape rules and 8 symbolic rules for the implementation of an inscribed regular pentagon in the Shape Machine 200. The shape rules can define geometric transformations that add, remove, or modify geometric elements such as points, lines, arcs, and circles. The symbolic rules can use operators to compute intersection points from the descriptors of shape elements.

The shape rules shown in FIG. 45 can include rules numbered 1 through 19. Rules 1 and 2 can show two points being transformed into an ellipse. Rules 3, 4, and 5 can show two points being transformed into circles with points positioned at different locations. Rules 6, 7, and 8 can show two points being transformed into horizontal lines. Rules 9, 10, and 11 can show circles being transformed into circles with horizontal lines through the circles. Rules 12 and 13 can show line segments with points being transformed into line segments without points. Rules 14 and 15 can show single points being transformed into empty shapes. Rule 16 can show a circle being transformed into an empty shape. Rules 17, 18, and 19 can show horizontal lines being transformed into empty shapes.

With continued reference to FIG. 45, the symbolic rules can include rules numbered 20 through 27. The symbolic rules can use a makePt operator, an int operator, a dsc operator, a line operator, and an arc operator. The makePt operator can convert computed intersection locations to a shape comprising maximal points at each intersection location. The int operator can compute intersections of descriptor equations. The dsc operator can derive descriptors of basic elements, where a line descriptor can be expressed in the form a₁x+b₁y+c₁=0 and an arc descriptor can be expressed in the form (x−c₁)²+(y−d₁)²−r₁²=0. The line operator can take a shape x as input and output the subshape line(x) composed of all of the maximal lines of the shape. The arc operator can output the subshape arc(x) composed of all of the maximal arcs of the shape.

The symbolic rules can be expressed in the form x→makePt(int(dsc(prt(x)),dsc(prt(x)))) and x→x+makePt(int(dsc(prt(x)),dsc(prt(x)))). Rules 20, 22, 26, and 27 can use the expression makePt(int(dsc(line(x)),dsc(arc(x)))) for finding intersections between line descriptors and arc descriptors. Rules 21 and 24 can use the expression makePt(int(dsc(arc(x)),dsc(arc(x)))) for finding intersections between arc descriptors. Rules 23 and 25 can use the expression makePt(int(dsc(line(x)),dsc(line(x)))) for finding intersections between line descriptors.

As further shown in FIG. 45, the symbolic representation of the operators can be written to exemplify the color properties of the basic elements of the shape in the calculation. A line operator can be typed in a first color to indicate that only lines labeled in the first color are selected. An arc operator can be typed in a second color to indicate that only arcs labeled in the second color are selected. A makePt operator can be typed in a third color to indicate that the points instantiated can be labeled in the third color. This functionality can reduce the complexity of the process by isolating specific shapes and can avoid instantiating redundant shapes.

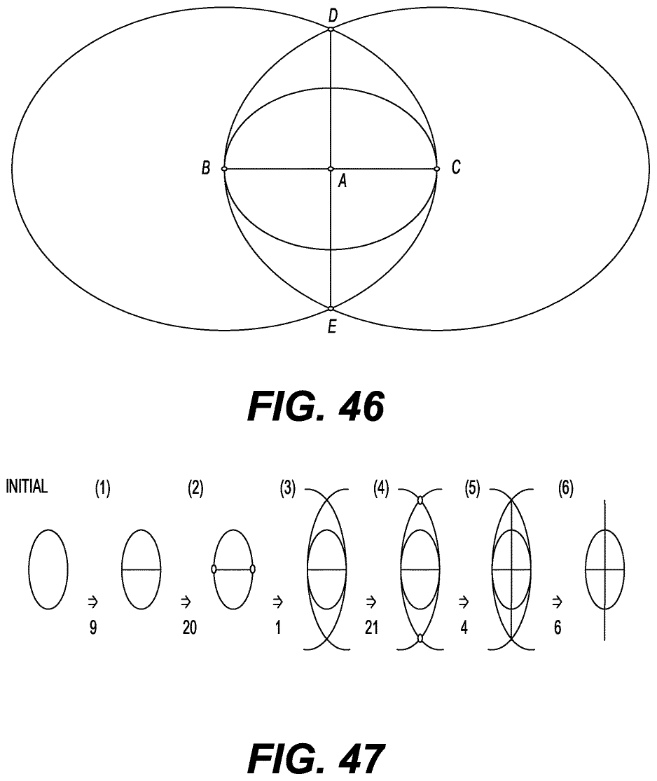

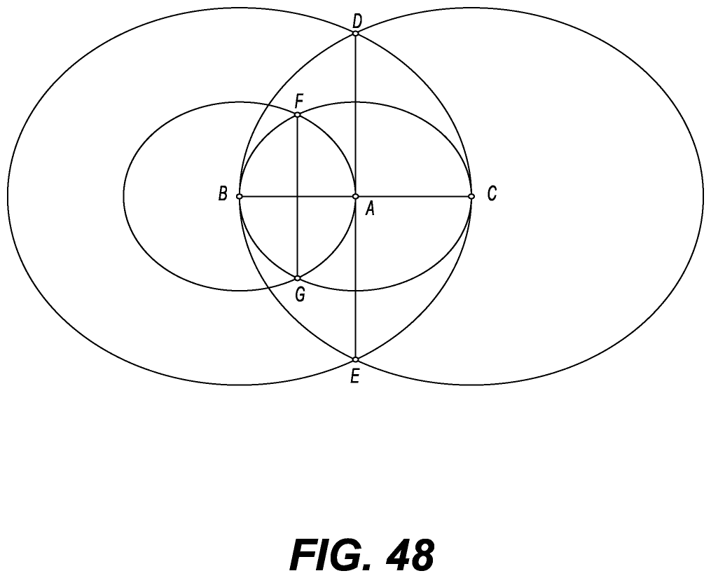

Referring to FIGS. 46-47, the Shape Machine 200 can implement the construction of a perpendicular bisector DE of a diameter BC as part of Ptolemy's construction of a regular pentagon inscribed in a given circle. FIG. 46 can illustrate the complete set of constructions included for the first step of the pentagon construction. The first step can start with the construction of two circles, one with a point B as the center and passing through a point C, and a second with the point C as the center and passing through the point B. The perpendicular bisector line DE can then be constructed by connecting the points D and E at the intersection points of the two circles.

FIG. 47 can illustrate the construction of the perpendicular bisector in the Shape Machine 200 implemented in six steps. The implementation of this step in the Shape Machine 200 can include five shape rules and two symbolic rules. The production can proceed as follows. A first application can instantiate a black line as the diameter of the initial circle. A second application can make two black points at the intersections of the descriptors of all black lines and black circles. A third application can instantiate two blue circles, each constructed with a blue point as the center and passing through another blue point, while removing the two black points. A fourth application can make two black points at the intersections of the descriptors of all blue circles. A fifth application can instantiate a blue line by connecting two black points while removing the two black points, where the blue line can be the perpendicular bisector. A sixth application can remove all blue circles.

With continued reference to FIGS. 46-47, some shapes can play a scaffolding role in the generation of the shape, meaning that the shapes can be instantiated to help construct new shapes and then the shapes can be removed. For example, the third application can instantiate a blue circle and remove two black points, and the fifth application can instantiate a blue line and remove two black points. Similarly, the sixth application can remove the auxiliary arcs used for the marking of the intersection points. The scaffolding shapes can include auxiliary arcs used for marking intersection points, and the Shape Machine 200 can apply shape rules to instantiate scaffolding shapes and subsequently remove the scaffolding shapes after the scaffolding shapes have served the construction purpose.

Referring to FIG. 48, the Shape Machine 200 can implement the construction of a perpendicular bisector FG of a radius AB, where the perpendicular bisector FG can be parallel to a previously constructed perpendicular bisector DE. FIG. 48 can illustrate the complete set of constructions included for the second step of Ptolemy's construction of a regular pentagon inscribed in a given circle.

The second step of the pentagon construction can start with the construction of two circles. A first circle can be constructed with a point B as the center and passing through a point A. A second circle can be constructed with the point A as the center and passing through the point B. The perpendicular line FG can then be constructed at the intersection points F and G of the two circles, where the perpendicular line FG can be parallel to the previously constructed perpendicular bisector DE.

With continued reference to FIG. 48, the construction can include multiple labeled points. A point A can be located at the center of the initial circle. Points B and C can be positioned on the circle at locations along a horizontal diameter. Points D and E can be positioned on a vertical line passing through the center A, with point D at the top of the circle and point E at the bottom. Points F and G can be positioned on a vertical line that passes through a point H between points A and B on the horizontal diameter, where the line FG can be the perpendicular bisector of the radius AB. The point H can represent the midpoint of the radius AB. The point I can be located at the intersection of the perpendicular bisector DE and the circle.

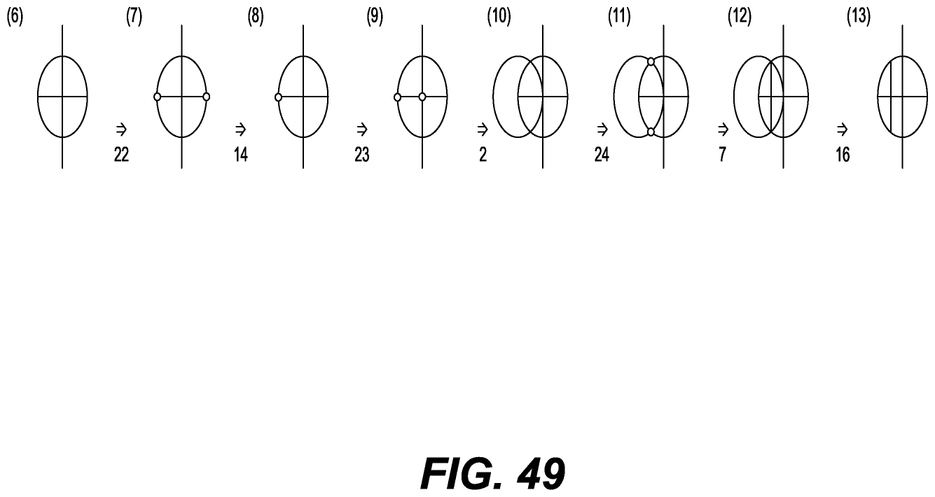

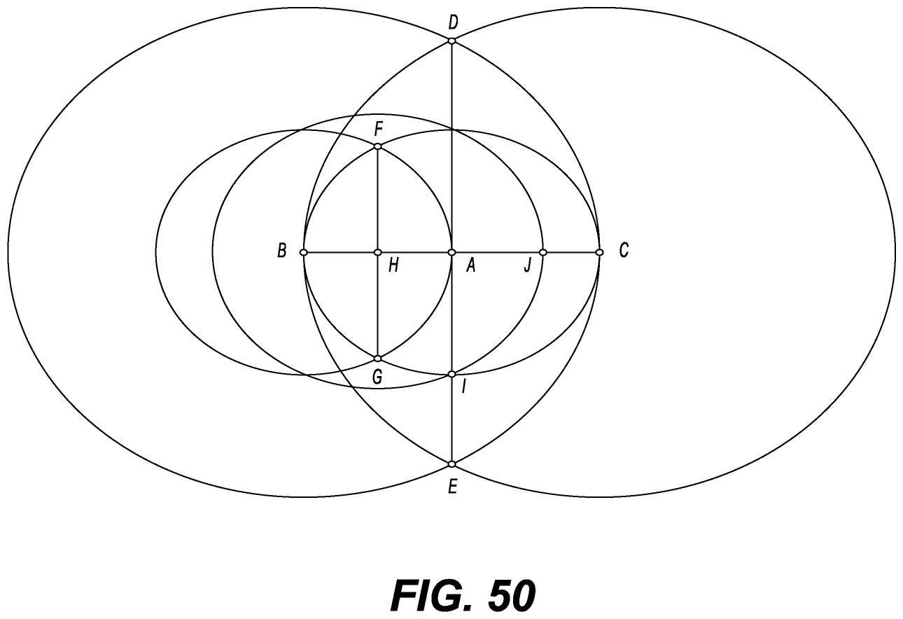

Referring to FIG. 49, the Shape Machine 200 can implement the construction of the perpendicular bisector parallel to the previously constructed perpendicular bisector in seven steps. FIG. 49 can illustrate a sequence of geometric constructions with elliptical shapes, where each diagram can show an oval shape containing internal geometric elements consisting of lines and points. The implementation of the second step in the Shape Machine 200 can include four shape rules and three symbolic rules.

The sequence shown in FIG. 49 can proceed through the following rule applications. A seventh application can make two blue points at the intersections of the descriptors of all black lines and all black circles. An eighth application can remove one blue point. A ninth application can make a black point at the intersections of the descriptors of all black lines and all blue lines, where the black point can also be the center of the initial circle.

With continued reference to FIG. 49, a tenth application can instantiate a blue circle with the blue point as the center and passing through the black point, while removing the blue point and the black point. An eleventh application can make two black points at the intersections of the descriptors of all blue circles and all black circles. A twelfth application can instantiate a yellow line by connecting two black points, while removing the two black points, where the yellow line can be the perpendicular bisector that is parallel to the perpendicular bisector constructed in the previous step. A thirteenth application can remove all blue circles.

As further shown in FIG. 49, the rule applications can be applied to remove temporary shapes. The application corresponding to step eight can remove a blue point that can be randomly selected, where any of the two blue points can be removed without causing issues. The difference can be that the pentagon can be constructed in a counterclockwise direction if the right blue point is removed, and the pentagon can be constructed in a clockwise direction if the left blue point is removed.

The diagrams in FIG. 49 can be arranged in a sequence with arrows indicating the progression from one step to the next. Each diagram can show an elliptical or oval shape containing internal geometric elements. The internal geometry of each ellipse can consist of intersecting lines forming triangular or angular patterns, with small circular nodes or points marking vertices and intersections. The configurations can vary across the diagrams, showing different arrangements of the internal line segments and connection points within the bounding elliptical curves.

The numerical values shown beneath each step in FIG. 49 can correspond to specific rule applications in the shape grammar implementation. The sequence can demonstrate how the Shape Machine 200 applies shape rules and symbolic rules in a systematic manner to construct geometric elements through the identification of intersection points between descriptors of lines and circles. The symbolic rules can use the int operator to compute intersections of descriptor equations and the makePt operator to convert computed intersection locations to maximal points.

Referring to FIG. 50, the Shape Machine 200 can implement Ptolemy's method for inscribing a regular pentagon within a given circle using straightedge and compass procedures. FIG. 50 can illustrate the geometric relationships used to determine the side length of a regular pentagon inscribed within a circle. The construction can include a circle with center point A and a horizontal diameter BC passing through the center. A perpendicular bisector DE can pass through the center A, intersecting the circle at points D and E. A point I can be located at the intersection of the perpendicular bisector DE and the circle. A point H can represent the midpoint of the radius AB. A circle centered at point H can pass through point I and can intersect the horizontal diameter BC at point J. The distance IJ can represent the length of the side of the regular pentagon to be constructed.

With continued reference to FIG. 50, the construction of a regular pentagon inscribed in a circle can comprise four steps. A first step can construct a perpendicular bisector DE of the diameter BC of the circle A and can mark the point I at the intersection of DE and the circle A. A second step can construct a perpendicular bisector FG of the radius AB of the circle and parallel to DE at H. A third step can construct a circle with center H and radius HI and can mark the intersection J of the circle H with the diameter BC of the circle A. A fourth step can construct a circle with center I and radius IJ and can mark the intersection K with the circle A. A fifth step can construct all five sides to complete the pentagon.

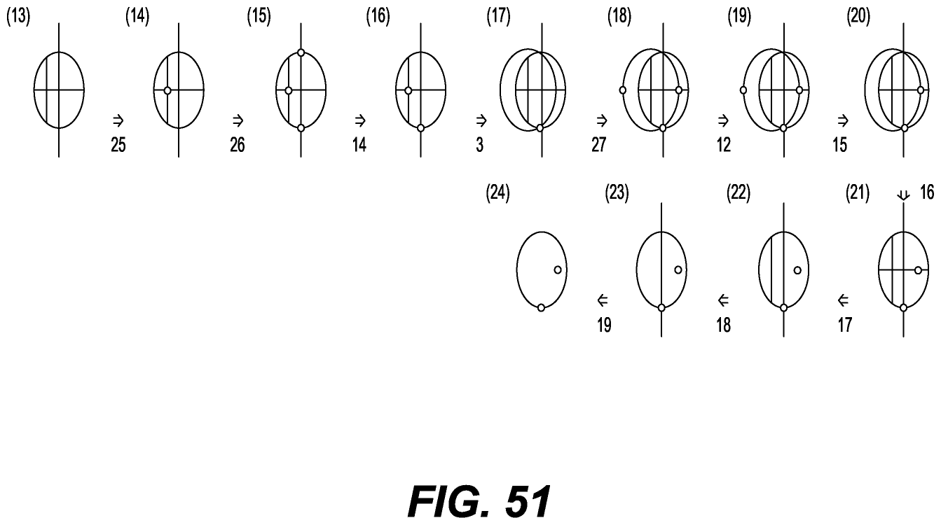

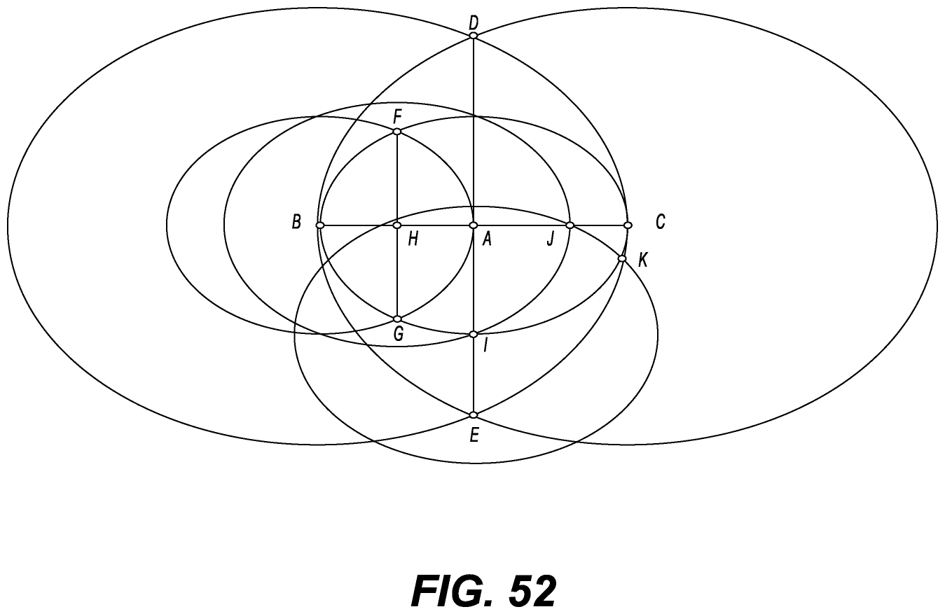

Referring to FIG. 51, the Shape Machine 200 can implement the construction process for establishing geometric relationships in the pentagon construction. FIG. 51 can illustrate a construction process implemented in multiple steps, where each step can show the progressive development of geometric elements. The construction can proceed through the following rule applications. A first application can instantiate a black line as the diameter of the initial circle. A second application can make two black points at the intersections of the descriptors of all black lines and black circles. A third application can instantiate two blue circles, where each blue circle can be constructed with a blue point as the center and passing through another blue point, while removing the two black points. A fourth application can make two black points at the intersections of the descriptors of all blue circles. A fifth application can instantiate a blue line by connecting two black points while removing the two black points, where the blue line can be the perpendicular bisector. A sixth application can remove all blue circles.

With continued reference to FIG. 51, the construction can continue with additional rule applications for the second step. A seventh application can make two blue points at the intersections of the descriptors of all black lines and all black circles. An eighth application can remove one blue point. A ninth application can make a black point at the intersections of the descriptors of all black lines and all blue lines, where the black point can also be the center of the initial circle. A tenth application can instantiate a blue circle with the blue point as the center and passing through the black point, while removing the blue point and the black point. An eleventh application can make two black points at the intersections of the descriptors of all blue circles and all black circles. A twelfth application can instantiate a yellow line by connecting two black points while removing the two black points, where the yellow line can be the perpendicular bisector that is parallel to the perpendicular bisector constructed in the previous step. A thirteenth application can remove all blue circles.

Referring to FIG. 52, the Shape Machine 200 can implement the derivation of a point K on the initial circle A, where the distance IK can be equal to IJ. FIG. 52 can illustrate the geometric construction for determining the first vertex of the regular pentagon. The construction can include a circle centered at point I and passing through point J, where the circle can intersect the initial circle A at point K. The distance IK can represent the length of one side of the regular pentagon. The construction can proceed through the following rule applications. A fourteenth application can make a black point at the intersections of the descriptors of all black lines and all yellow lines. A fifteenth application can make two blue points at the intersections of the descriptors of all blue lines and black circles. A sixteenth application can remove one blue point. A seventeenth application can instantiate a blue circle with a black point as the center point passing through a blue point, while removing the black point.

With continued reference to FIG. 52, the construction can continue with additional rule applications. An eighteenth application can make two black points at the intersections of the descriptors of all black lines and blue circles. A nineteenth application can replace a black point, which is on a black line, with a yellow point. A twentieth application can remove all black points. A twenty-first application can remove all blue circles. A twenty-second application can remove all black lines. A twenty-third application can remove all yellow lines. A twenty-fourth application can remove all blue lines. A twenty-fifth application can instantiate a blue circle with a blue point as the center point and passing through a yellow point, while removing the yellow point. A twenty-sixth application can make two black points at the intersections of the descriptors of all black circles and all blue circles. A twenty-seventh application can remove one black point. A twenty-eighth application can remove all blue circles.

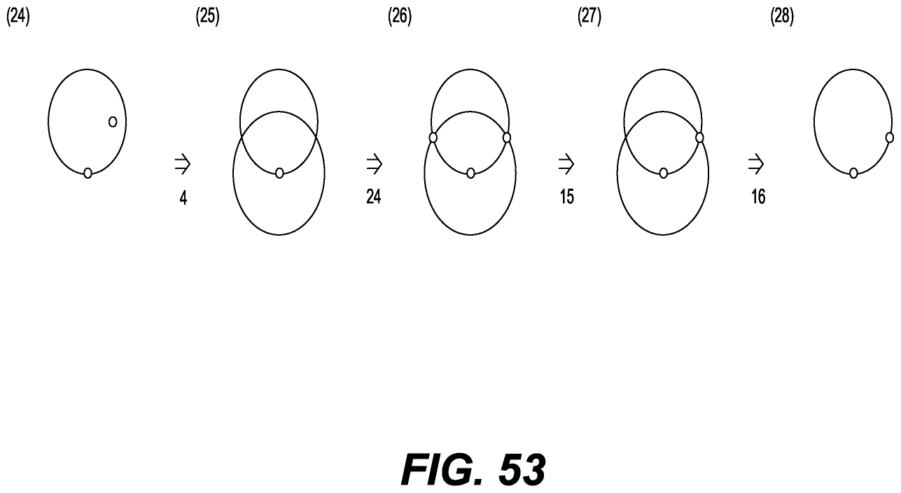

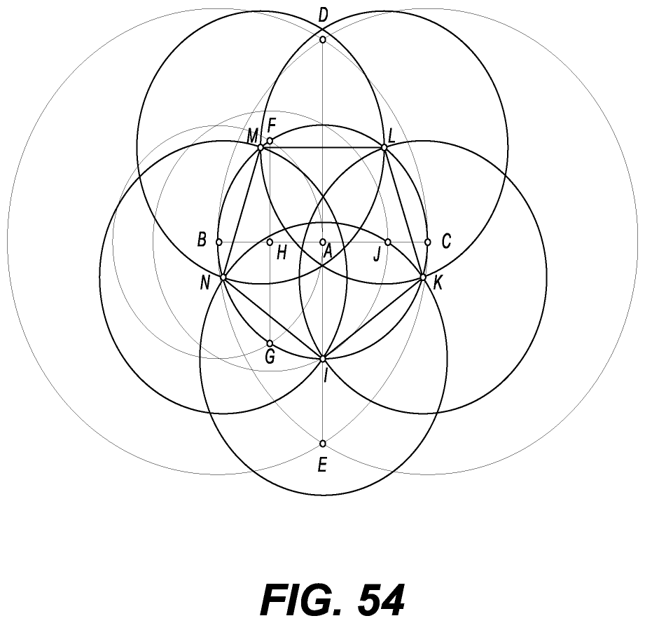

Referring to FIG. 53, the Shape Machine 200 can implement shape transformation steps for determining a point on the circle that establishes the first side of the regular pentagon. FIG. 53 can illustrate a sequence of five shape transformation steps showing the progressive construction process. The sequence can demonstrate the geometric construction methodology for locating a specific point on the initial circle, where the distance between the located point and another reference point can equal the length of one side of the regular pentagon being constructed.

Referring to FIG. 54, the Shape Machine 200 can implement Ptolemy's method for inscribing a regular pentagon with auxiliary circles. FIG. 54 can illustrate the complete set of constructions superimposed in a single diagram, showing the auxiliary circles and lines used in the classical Euclidean construction method. The construction can include multiple labeled points including D at the top of the outer circle, E at the bottom, B on the left side of the diameter, C on the right side, M and L in the upper region, N and K on the sides, H and J near the center, G in the lower central region, I at a lower intersection point, and F below the center. The auxiliary circles can intersect with each other and with the main circle at specific points that can define the pentagon's vertices and the intermediate construction steps.

With continued reference to FIG. 54, the fourth step of the construction can construct all five sides of the regular pentagon. A twenty-ninth application can instantiate a blue line by connecting the center of the initial circle and a blue point on the circle. A thirtieth application can instantiate a blue circle with the black point as the center and passing through a black point, and can instantiate a black line by connecting the black point and the blue point, while removing the blue point and replacing the black point with a blue point. A thirty-first application can make two black points at the intersections of the descriptors of all black circles and blue circles. A thirty-second application can remove a black point which is an endpoint of a black line. A thirty-third application can remove all blue circles. Applications thirty-four through forty-one can repeat applications thirty through thirty-three two times.

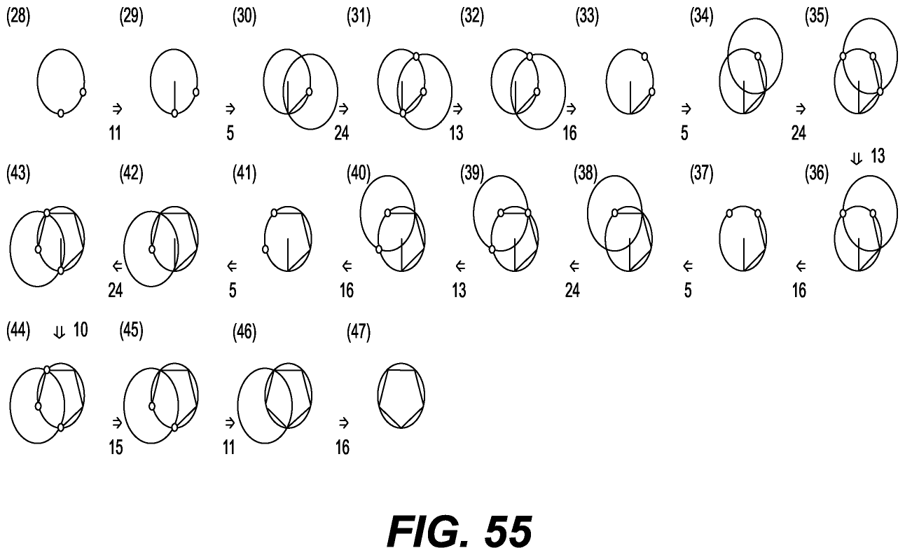

Referring to FIG. 55, the Shape Machine 200 can implement construction steps for building the sides of the regular pentagon. FIG. 55 can illustrate a sequence of geometric constructions showing the progressive steps for building the sides of the pentagon inscribed in the circle. The sequence can be arranged in a grid format with numbered steps from twenty-eight through forty-seven, illustrating the construction process using circles and lines. A forty-second application can instantiate a blue circle with the black point as the center and passing through a black point, and can instantiate a black line by connecting the black point and the blue point, while removing the blue point and replacing the black point with a blue point. A forty-third application can make two black points at the intersections of the descriptors of all black circles and blue circles. A forty-fourth application can replace a black point which is an endpoint of a black line with a blue point. A forty-fifth application can remove all black points. A forty-sixth application can instantiate a black line by connecting two blue points, where the pentagon can be completed. A forty-seventh application can remove all blue circles.

As further shown in FIG. 55, the implementation of Ptolemy's construction of the regular pentagon in the Shape Machine 200 can comprise 27 rules, including 19 shape rules and 8 intersection operator rules. The shape rules can define geometric transformations that add, remove, or modify geometric elements such as points, lines, arcs, and circles. The intersection operator rules can use operators to compute intersection points from the descriptors of shape elements. The symbolic rules can be expressed in the form x→makePt(int(dsc(prt(x)),dsc(prt(x)))) and x→x+makePt(int(dsc(prt(x)),dsc(prt(x)))). The makePt operator can convert computed intersection locations to a shape comprising maximal points at each intersection location. The int operator can compute intersections of descriptor equations. The dsc operator can derive descriptors of basic elements.

With continued reference to FIGS. 50-55, some shapes can play a scaffolding role in the generation of the shape, meaning that the shapes can be instantiated to help construct new shapes and then the shapes can be removed. For example, the third application can instantiate a blue circle and remove two black points, and the fifth application can instantiate a blue line and remove two black points. Similarly, the sixth application can remove the auxiliary arcs used for the marking of the intersection points. The scaffolding shapes can include auxiliary arcs used for marking intersection points, and the Shape Machine 200 can apply shape rules to instantiate scaffolding shapes and subsequently remove the scaffolding shapes after the scaffolding shapes have served the construction purpose.

The reworking of any step-like Euclidean construction within the embed-fuse cycle of the shape grammar formalism can include the usage of labeled shapes to limit the shape embedding calculations on the specific shapes used for each step of the procedure, and intersection points derived from the intersections of line and circle descriptors that classify the labeled shapes used for each step of the procedure. The symbolic representation of the operators can be written to exemplify the color properties of the basic elements of the shape in the calculation. A line operator can be typed in a first color to indicate that only lines labeled in the first color are selected. An arc operator can be typed in a second color to indicate that only arcs labeled in the second color are selected. A makePt operator can be typed in a third color to indicate that the points instantiated can be labeled in the third color. This functionality can reduce the complexity of the process by isolating specific shapes and can avoid instantiating redundant shapes.

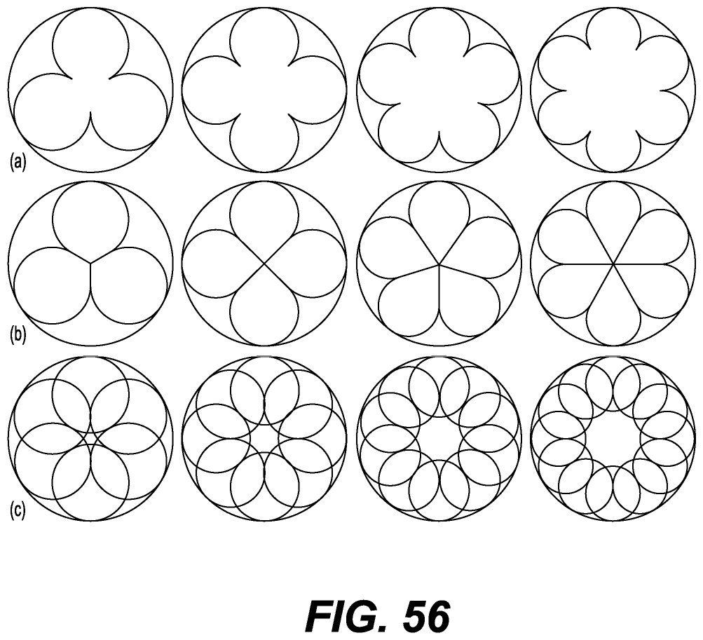

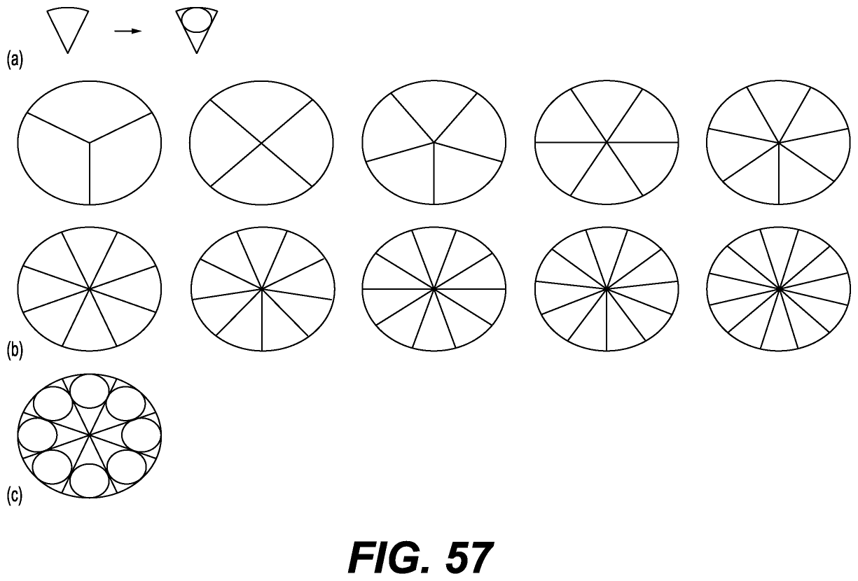

Referring to FIG. 56, the Shape Machine 200 can implement the construction of Gothic rosette patterns using shape rules and intersection operator rules. FIG. 56 can illustrate three families of Gothic rosette patterns, where each family can have ten examples with different numbers of circle divisions. Circular rosette windows in Gothic architecture can showcase intricate constructions of overlapping and nested arcs and circles making foils or rings filling the circular area of the rosette window. The design of interlaced foils, such as trefoils, quatrefoils, and other n-foil configurations, can be bounded by rounded or pointed arcs and can partition the window into disjoint regions. A parametric specification of Gothic rosette designs can be based on the number n of the foils in a unit circle.

With continued reference to FIG. 56, the first family of Gothic rosette patterns can comprise circular patterns featuring petal-like or flower-shaped designs with curved lobes pointing inward toward the center, where each successive pattern from left to right can contain an increasing number of lobes ranging from three to twelve. The second family can display circular patterns with similar curved elements arranged in a different configuration, where the curved segments can create overlapping or interlocking shapes with diagonal lines crossing through the center, progressing from three-fold to twelve-fold symmetry. The third family can present circular patterns composed of multiple overlapping circles arranged around a central point, creating rosette formations that can increase in complexity from left to right, with the number of constituent circles increasing from three to twelve or more across the row.

Referring to FIG. 57, the Shape Machine 200 can implement the progressive division of a circle into equal sectors as a foundation for Gothic rosette pattern construction. FIG. 57 can illustrate the division of a circle into progressively increasing numbers of equal sectors, starting from three sectors and increasing to twelve or more sectors. Each division can create radial lines extending from the center point to the circumference of the circle. The radial divisions can serve as scaffolds upon which inscribed circles and foil patterns can be constructed.

With continued reference to FIG. 57, a shape rule designed to instantiate an inscribed circle within a sector of the rosette can apply only on a circle that is divided into a specific number of identical parts because the left-hand-side shape of the shape rule can be precisely constructed within a sector of a particular angular measure. The shape rule can be not applicable for other rosette divisions because there can be no linear transformation that can embed the left-hand-side shape into other divisions of the rosette window with different angular measures. The Shape Machine 200 can address this limitation by using intersection points and labeled shapes to enable shape embedding calculations on specific shapes used for each step of the construction procedure.

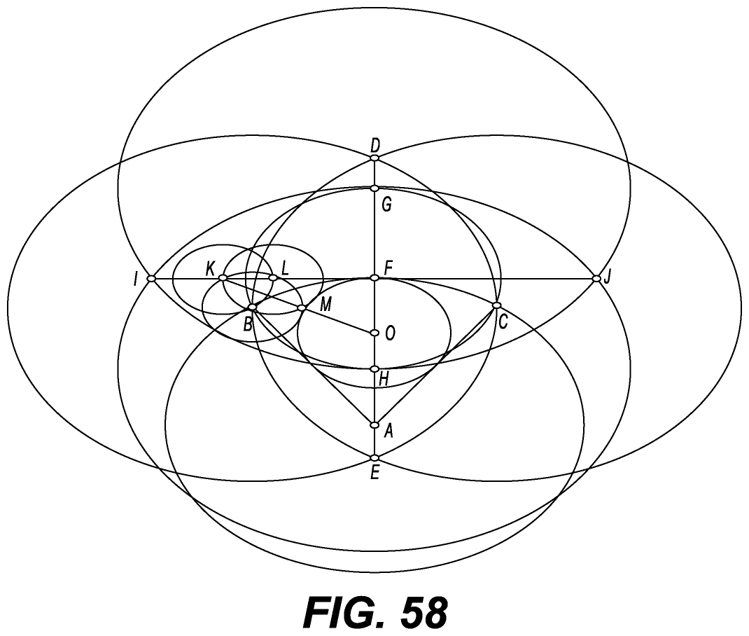

Referring to FIG. 58, the Shape Machine 200 can implement the inscription of a circle within a circular sector of a Gothic rosette design. FIG. 58 can illustrate the complete construction of an inscribed circle within a sector BAC, superimposed in a single diagram. The inscription of a circle within a sector BAC can include four steps. A first step can construct a bisector of the angle BAC, where the bisector can be a line DE that makes angle BAF equal to angle CAF. A second step can construct a line IJ that is perpendicular to the bisector DE and tangent to the initial circle. A third step can construct three circles with center points K, L, and B and identical radii of the length BK. A fourth step can construct the center point O of the inscribed circle and can construct the inscribed circle with the center point O passing through point F.

With continued reference to FIG. 58, the implementation of the four steps for inscribing a circle within a circular sector in the Shape Machine 200 can include 37 rules including 27 shape rules and 10 intersection operator rules. The construction of the bisector DE of the angle BAC can consist of two sub-steps. A first sub-step can construct two circles, one with point B as the center and passing through point C, and a second with point C as the center and passing through point B. A second sub-step can draw the bisector by connecting points D and E, which can be the intersection points of the two circles. The implementation of the bisector construction step in the Shape Machine 200 can include five shape rules and two intersection operator rules.

As further shown in FIG. 58, the construction of the line IJ perpendicular to the bisector DE and tangent to the initial circle can consist of five sub-steps. A first sub-step can construct a circle with point F as the center passing through point B. A second sub-step can find points G and H that are intersection points of the bisector and the circle constructed previously. A third sub-step can construct two circles, one with point G as the center passing through point H, and a second with point H as the center passing through point G. A fourth sub-step can find points I and J that are intersection points of the two circles constructed. A fifth sub-step can construct line IJ by connecting points I and J. The implementation of the perpendicular line construction in the Shape Machine 200 can include nine shape rules and three intersection operator rules.

The construction of the three circles to determine the center of the inscribed circle can consist of three sub-steps. A first sub-step can construct a circle K with point K as the center and passing through point B, where point K can be the intersection point of line AB and the perpendicular line IJ constructed in the previous step. A second sub-step can construct a circle L with center point L and passing through point K, where point L can be the intersection point of circle K and line IJ. A third sub-step can construct a circle B with center point B and passing through point K. The implementation of the three circles construction in the Shape Machine 200 can include 12 shape rules and three intersection operator rules.

The construction of the inscribed circle can consist of two sub-steps. A first sub-step can construct line KM and extend the line to intersect with line DE, where M can be the intersection point of circle L and circle B constructed in the previous step. A second sub-step can construct the inscribed circle with center point O passing through point F, where point O can be the intersection point of lines KM and DE. The implementation of the inscribed circle construction in the Shape Machine 200 can include nine shape rules and one intersection operator rule.

Some shapes can play a scaffolding role in the generation of the construction, meaning that the shapes can be instantiated to help construct new shapes and then the shapes can be removed. For example, rule applications can instantiate auxiliary circles and remove temporary points, and subsequent rule applications can remove the auxiliary circles used for marking intersection points. The Shape Machine 200 can apply shape rules to instantiate scaffolding shapes and subsequently remove the scaffolding shapes after the scaffolding shapes have served the construction purpose.

The application of the four steps above in one iteration can inscribe one circle in a circular sector. To inscribe three circles for an initial rosette that is divided into three circular sectors, the grammar can be applied in three iterations. Different numbers of initial divisions can include corresponding numbers of iterations of the shape grammar respectively. The Shape Machine 200 can generate ten variations of scaffolds for ten different divisions of the initial circle, ranging from three-fold to twelve-fold divisions.

A second phase of the construction for Gothic rosette patterns can detail the scaffold by removing or adding lines and arcs. The scaffold can be developed into various patterns by adding and subtracting lines and arcs. A challenge in the detailing phase can be to remove arcs for different scaffolds, because there can be no linear transformation to map an arc to another arc if the radians of the arcs are not identical. The Shape Machine 200 can address this challenge by using multiple steps of constructions with intersection operator rules.

The ornamentation of the circular sector of the Gothic rosette and the detailing of the circular sector can consist of four steps. A first step can differentiate the exterior circle and the inscribed circles with different colors or attributes. A second step can identify the arcs that are parts of the inscribed circles that are between two tangent points and closer to the center of the initial circle, and can subtract the identified arcs from the inscribed circles. A third step can identify the line segments that are between inscribed circles and the exterior circle, and can subtract the identified line segments. A fourth step can remove all temporary colors or attributes.

The subtraction of arcs from the inscribed circles for different radians can be implemented in two parts. A first part can subtract an arc ABC that is half of the circle. A second part can add an arc DAB that is half of the circle. The implementation of the foiling detailing for each circular sector of the Gothic rosette in the Shape Machine 200 can include nine shape rules and three intersection operator rules.

To detail all the inscribed circles for all circular sectors of the rosette window, the rule applications can be processed for multiple iterations. For different scaffolds, different iterations can be included. The Shape Machine 200 can generate variations of n-foil Gothic rosette windows, ranging from trefoil patterns to twelve-foil patterns. A third variation can be produced by applying the grammar to the initial shape and applying the grammar again to the initial shape rotated by half of the sector angle. Further detailing of the grammar to include the generation of nested foils, circles, and offset bands to denote material width can proceed along the procedures specified.

The integration of intersection points in the application of shape rules instantiated within schema rules can provide a framework to specify classes of parametric design variations, including classes of n-foil Gothic rosette windows, by productions of shape rules rather than parametric shape rules. The framework for shape calculation with basic elements and descriptors of the basic elements can bridge the embed-fuse capability of shape grammars and the parametric modeling capability of CAD systems.

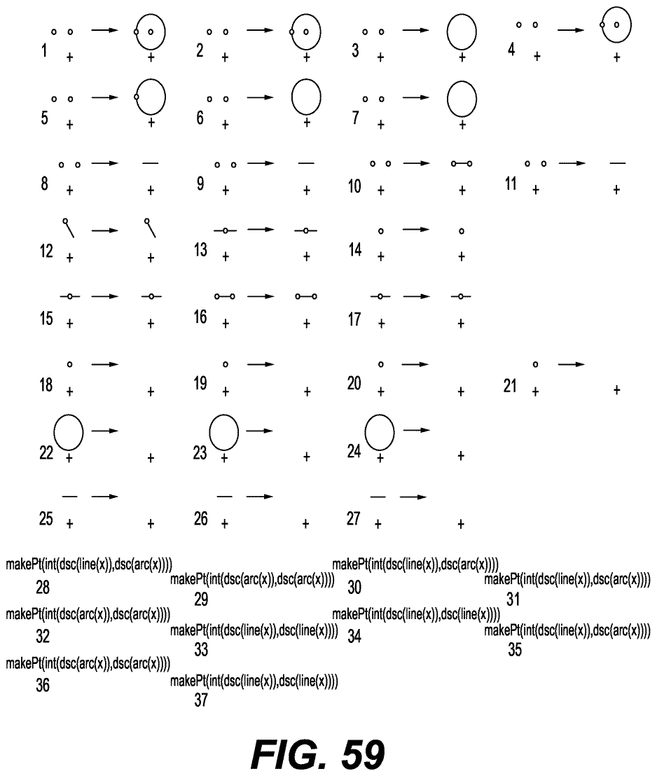

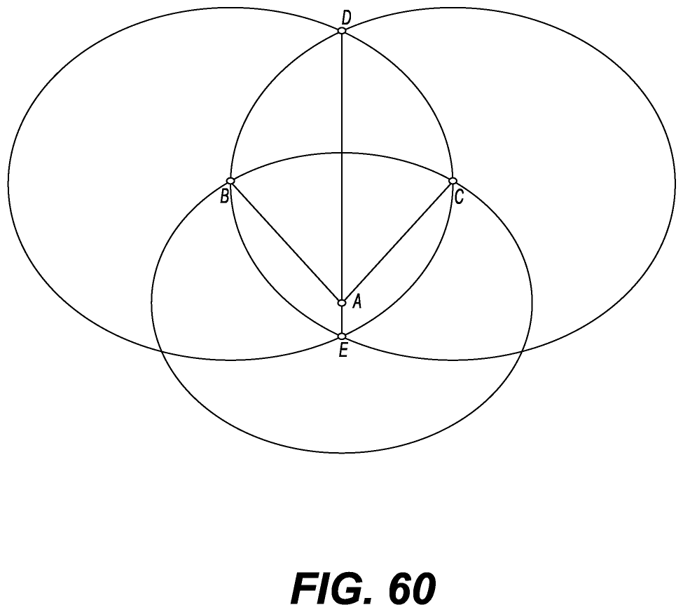

Referring to FIG. 59, the Shape Machine 200 can implement the construction of an inscribed circle within a circular sector of a Gothic rosette design using a combination of shape rules and intersection operator rules. FIG. 59 can illustrate 37 rules including 27 shape rules and 10 intersection operator rules for the implementation of an inscribed circle in a circle sector in the Shape Machine 200. The shapes in the shape rules can be labeled with colors to warrant a predefined sequence of shape rules. The shape rules can define geometric transformations that add, remove, or modify geometric elements such as points, lines, arcs, and circles. The intersection operator rules can use operators including a makePt operator, an int operator, a dsc operator, a line operator, and an arc operator to compute intersection points from the descriptors of shape elements.

With continued reference to FIG. 59, the intersection operator rules can include rules that use the expression makePt(int(dsc(line(x)),dsc(arc(x)))) for finding intersections between line descriptors and arc descriptors, rules that use the expression makePt(int(dsc(arc(x)),dsc(arc(x)))) for finding intersections between arc descriptors, and rules that use the expression makePt(int(dsc(line(x)),dsc(line(x)))) for finding intersections between line descriptors. The symbolic representation of the operators can be written to exemplify the color properties of the basic elements of the shape in the calculation. A line operator can be typed in a first color to indicate that only lines labeled in the first color are selected. An arc operator can be typed in a second color to indicate that only arcs labeled in the second color are selected. A makePt operator can be typed in a third color to indicate that the points instantiated can be labeled in the third color.

The inscription of a circle within a sector BAC can include four steps. A first step can construct a bisector of the angle BAC, where the bisector can be a line DE that makes angle BAF equal to angle CAF. A second step can construct a line IJ that is perpendicular to the bisector DE and tangent to an initial circle. A third step can construct three circles with center points K, L, and B and identical radii of the length BK. A fourth step can construct a center point O of the inscribed circle and can construct the inscribed circle with the center point O passing through a point F.

Referring to FIG. 60, the first step of the inscribed circle construction can construct a bisector DE of an angle BAC. FIG. 60 can illustrate the construction of the bisector of the angle BAC. The construction of the bisector DE can consist of two sub-steps. A first sub-step can construct two circles, one with a point B as the center and passing through a point C, and a second with the point C as the center and passing through the point B. A second sub-step can draw the bisector by connecting points D and E, which can be intersection points of the two circles.

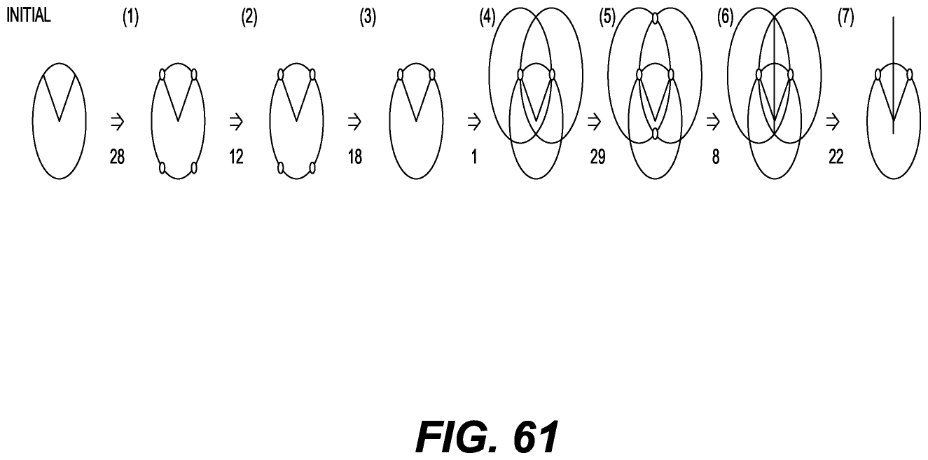

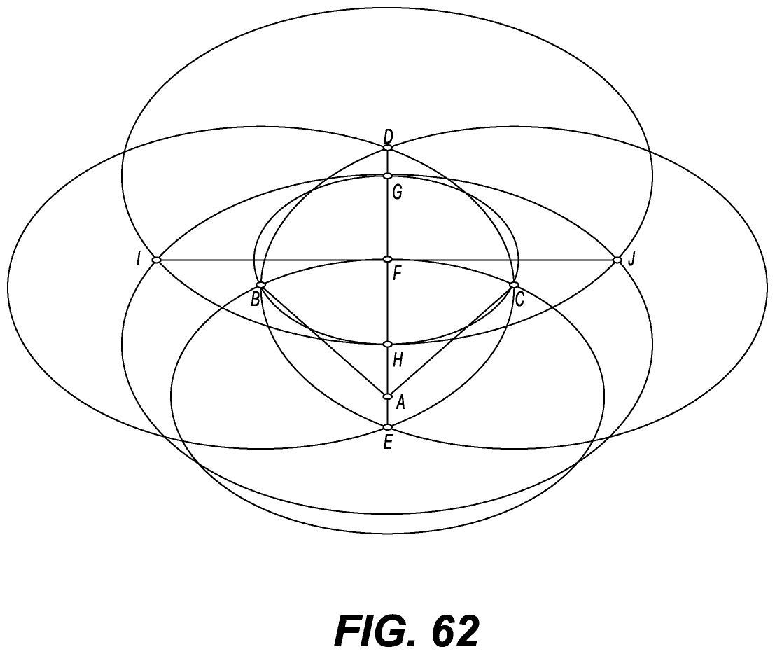

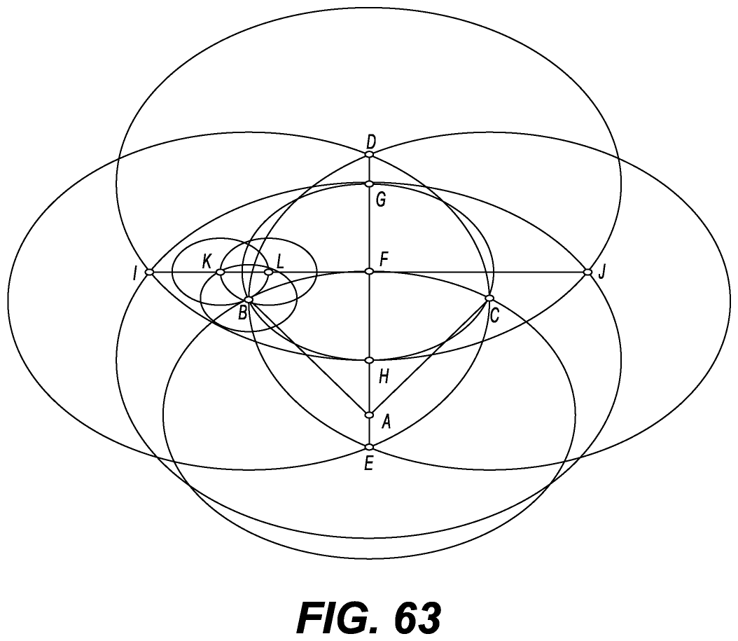

Referring to FIG. 61, the Shape Machine 200 can implement the bisector construction in seven steps. FIG. 61 can illustrate the construction of the bisector implemented in seven steps. The implementation of the first step in the Shape Machine 200 can include five shape rules and two intersection operator rules. A seventh rule application can make four yellow points at the intersections of the descriptors of all black lines and all black circles. An eighth rule application can replace two yellow intersection points, that are endpoints of black lines, with green points. A ninth rule application can remove all yellow points. A tenth rule application can instantiate two blue circles with one green point as the center and passing through the other green point. An eleventh rule application can make two red points at the intersections of the descriptors of all blue circles. A twelfth rule application can instantiate a blue line by connecting two red points and can remove the two red points. A thirteenth rule application can remove all blue circles.

With continued reference to FIG. 61, some points, lines, and circles can be removed at the end of the step to avoid complexity. The two green points in rule application seven can be retained because the two green points can be used in a next step.

Referring to FIG. 62, the second step of the inscribed circle construction can construct a line IJ perpendicular to the bisector DE and tangent to the initial circle. FIG. 62 can illustrate the construction of the line IJ perpendicular to the bisector DE and tangent to the initial circle. The construction of the line IJ can consist of five sub-steps. A first sub-step can construct a circle with a point F as the center passing through a point B. A second sub-step can find points G and H that are intersection points of the bisector and the circle constructed in the first sub-step. A third sub-step can construct two circles, one with the point G as the center passing through the point H, and a second with the point H as the center passing through the point G. A fourth sub-step can find two points I and J that are intersection points of the two circles constructed in the third sub-step. A fifth sub-step can construct the line IJ by connecting the points I and J.

With continued reference to FIG. 62, the implementation of the second step in the Shape Machine 200 can include nine shape rules and three intersection operator rules. An eighth rule application can make two yellow points at the intersections of the descriptors of all blue lines and all black circles. A ninth rule application can replace the yellow point, which is on a blue line, with a red point. A tenth rule application can remove all yellow points. An eleventh rule application can replace all red points with yellow points. A twelfth rule application can instantiate a blue circle with a yellow point as the center and passing through a green point. A thirteenth rule application can make two red points at the intersections of the descriptors of all blue lines and all blue circles. A fourteenth rule application can instantiate two red circles with one red point as the center and passing through the other red point. A fifteenth rule application can make two red points at the intersections of the descriptors of all red circles. A sixteenth rule application can instantiate a red line by connecting two red points and can remove the two red points. A seventeenth rule application can remove all blue circles. An eighteenth rule application can remove all red circles. A nineteenth rule application can remove all yellow points.

As further shown in FIG. 62, rule applications ten, seventeen, eighteen, and nineteen can remove shapes that play a scaffolding role in the generation of the construction. Rule applications eight, nine, and ten can disambiguate the point selected and can help guide the construction. Automation of Euclidean geometric constructions can include the implementation of random selections of shape embeddings, and additional shape rules can be included to warrant a correct selection.

Referring to FIG. 63, the Shape Machine 200 can implement the construction of three circles with center points K, L, and B. FIG. 63 can illustrate the construction of the three circles that can determine the center of the inscribed circle in a circular sector of the initial rosette.

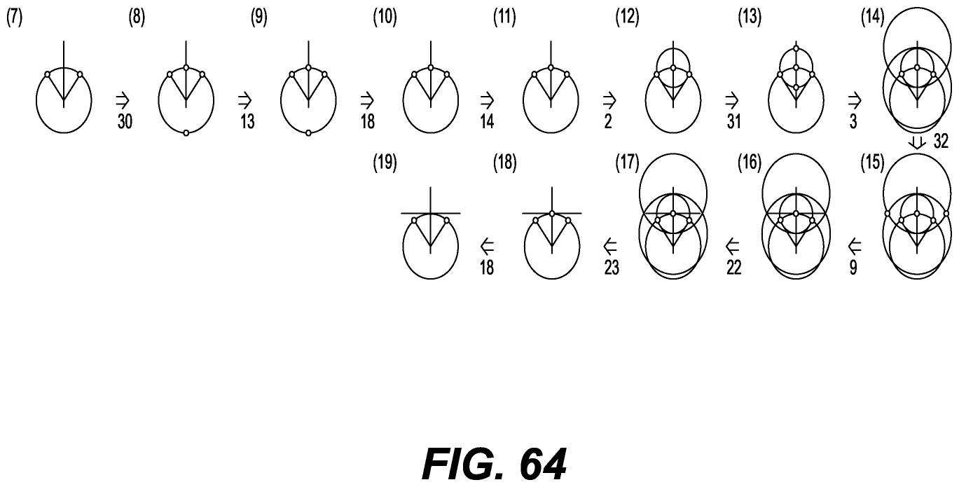

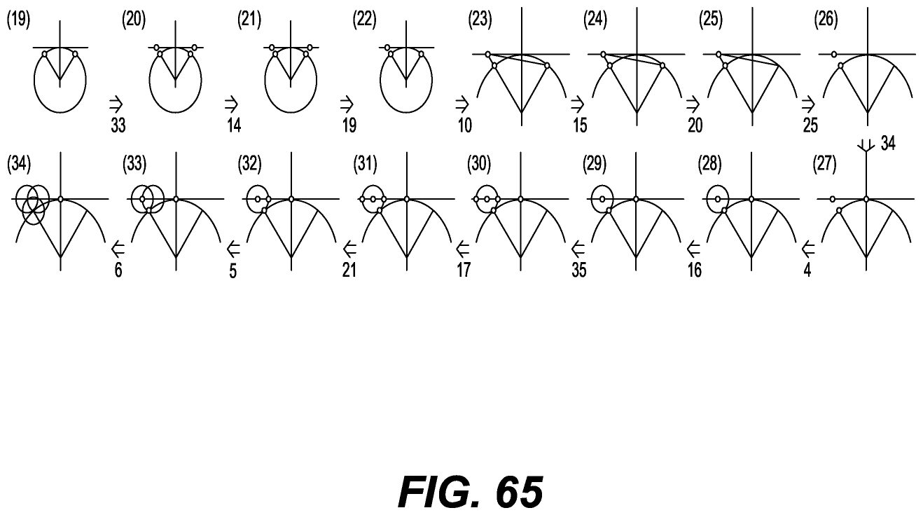

Referring to FIGS. 64-65, the third step of the inscribed circle construction can construct three circles to determine the center of the inscribed circle. FIG. 64 can illustrate the construction of the three circles implemented in multiple steps. FIG. 65 can illustrate the construction of the three circles to determine the center of the inscribed circle in a circular sector. The construction of the three circles can consist of three sub-steps. A first sub-step can construct a circle K with a point K as the center and passing through a point B, where the point K can be the intersection point of a line AB and the perpendicular line IJ constructed in the second step. A second sub-step can construct a circle L with a center point L and passing through the point K, where the point L can be the intersection point of the circle K and the line IJ. A third sub-step can construct a circle B with a center point B and passing through the point K. The implementation of the third step in the Shape Machine 200 can include twelve shape rules and three intersection operator rules.

With continued reference to FIGS. 64-65, a twentieth rule application can make two red points at the intersections of the descriptors of all black lines and all red lines. A twenty-first rule application can replace one red point with a yellow point. A twenty-second rule application can remove all red points. A twenty-third rule application can instantiate two yellow lines by connecting a yellow point and a green point. A twenty-fourth rule application can replace the green point, which is an endpoint of a yellow line and also an endpoint of a black line, with a red point. A twenty-fifth rule application can remove all green points. A twenty-sixth rule application can remove all yellow lines. A twenty-seventh rule application can make a blue point at the intersections of the descriptors of all red lines and all blue lines. A twenty-eighth rule application can instantiate a blue circle with a yellow point as the center point and passing through a red point. A twenty-ninth rule application can replace a red line segment, which has boundaries as a blue point and a yellow point, with a yellow line segment. A thirtieth rule application can make two black points at the intersections of the descriptors of all red lines and all blue circles. A thirty-first rule application can replace a black point, which is on a yellow line, with a green point. A thirty-second rule application can remove all black points. A thirty-third rule application can instantiate a red circle with a green point as the center point and passing through a yellow point, and can remove the green point. A thirty-fourth rule application can instantiate a yellow circle with a red point as the center point and passing through a yellow point, and can remove the red point and the yellow point.

As further shown in FIGS. 64-65, when the twenty-first rule application is applied, there can be two matches since there are two red points, and only one red point can be replaced with a yellow point where the selection can be random. Rule applications twenty-three through twenty-six can be applied to identify the green point which is on the same side of the yellow point. Rule applications twenty-nine through thirty-two can be applied to identify the black point which is closer to the bisector. Rule applications twenty-two, twenty-five, twenty-six, and thirty-two can remove temporary and redundant shapes.

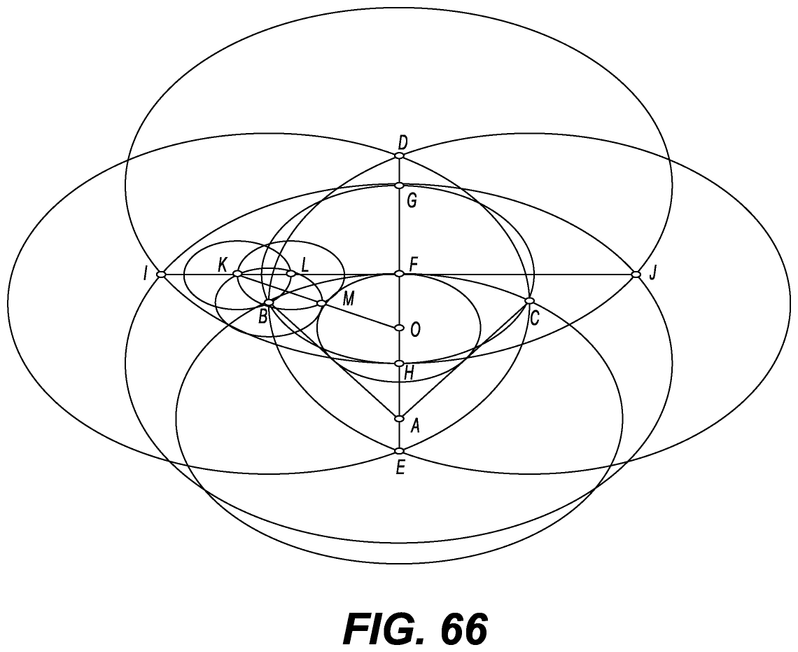

Referring to FIG. 66, the fourth step of the inscribed circle construction can construct the inscribed circle within the circular sector. FIG. 66 can illustrate the construction of the inscribed circle in the sector ACFB. The construction of the inscribed circle can consist of two sub-steps. A first sub-step can construct a line KM and can extend the line to intersect with the line DE, where M can be the intersection point of the circle L and the circle B constructed in the third step. A second sub-step can construct the inscribed circle with a center point O passing through the point F, where the point O can be the intersection point of the lines KM and DE.

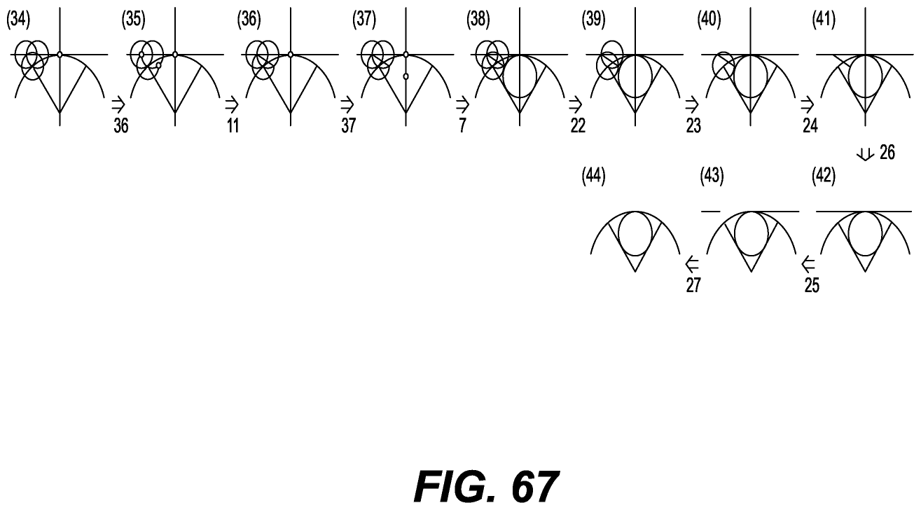

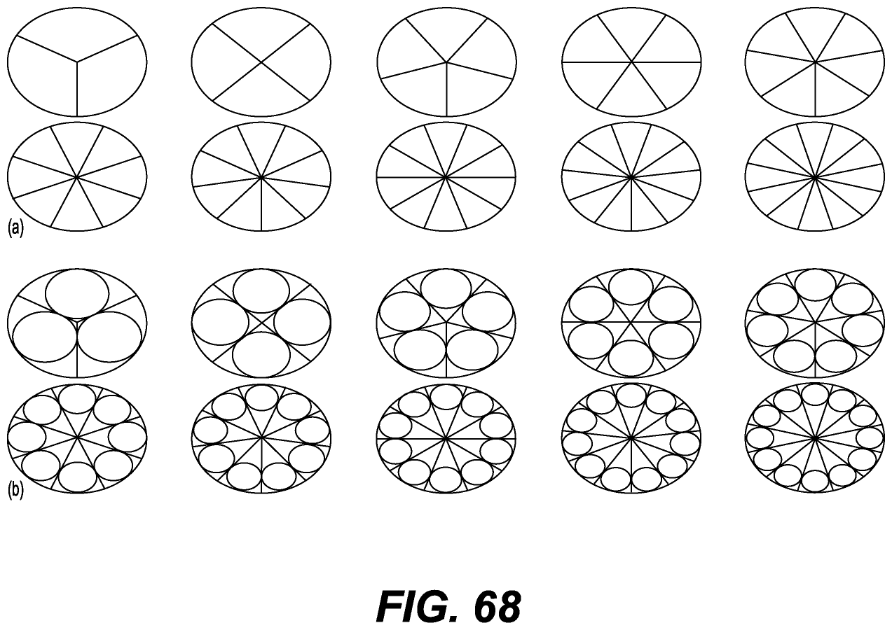

Referring to FIG. 67, the Shape Machine 200 can implement the construction of the inscribed circle within the circular sector in ten steps. FIG. 67 can illustrate the construction of the inscribed circle within the circular sector. The implementation of the fourth step in the Shape Machine 200 can include nine shape rules and one intersection operator rule. A thirty-fifth rule application can make two black points at the intersections of the descriptors of all yellow circles and all red circles. A thirty-sixth rule application can instantiate a blue line by connecting two black points and can remove the two black points. A thirty-seventh rule application can make a black point at the intersections of the descriptors of all blue lines. A thirty-eighth rule application can instantiate a black circle with a black point as the center point and passing through a blue point and can remove the black point and the blue point. A thirty-ninth rule application can remove all blue circles. A fortieth rule application can remove all red circles. A forty-first rule application can remove all yellow circles. A forty-second rule application can remove all blue lines. A forty-third rule application can remove all yellow lines. A forty-fourth rule application can remove all red lines.

With continued reference to FIG. 67, rule applications thirty-nine through forty-four can be applied to remove scaffold shapes used for the procedural constructions. Some scaffold shapes can be removed while instantiating new shapes. For example, rule application thirty-eight can instantiate an inscribed circle while removing two black points. The grammar can be optimized so that temporary shapes can be removed earlier and the number of rules can be reduced.

The application of the four steps above in one iteration can inscribe one circle in a circular sector. To inscribe three circles for an initial rosette that is divided into three circular sectors, the grammar can be applied in three iterations. Different numbers of initial divisions can include corresponding numbers of iterations of the shape grammar respectively.

Referring to FIG. 68, the Shape Machine 200 can generate variations of scaffolds for Gothic rosette patterns by applying the inscribed circle construction grammar for different numbers of initial circle divisions. FIG. 68 can illustrate ten variations of scaffolds corresponding to ten different divisions of an initial circle, ranging from three-fold to twelve-fold divisions.

With continued reference to FIG. 68, a first row of FIG. 68 can illustrate ten initial shapes in the form of n-sector scaffolds. Each initial shape can comprise a circle divided into a corresponding number of equal sectors by radial lines extending from a center point to the circumference of the circle. The number of sectors can range from three sectors on the left to twelve sectors on the right.

A second row of FIG. 68 can illustrate ten subdivisions resulting from applying the shape grammar for the same number of iterations as the number of divisions of the rosette. Each subdivision can include inscribed circles positioned within each circular sector, where each inscribed circle can be tangent to the radial lines defining the sector and tangent to the outer circle. The number of inscribed circles in each subdivision can correspond to the number of sectors in the initial shape. The application of the four construction steps in one iteration can inscribe one circle in a circular sector. To inscribe three circles for an initial rosette that is divided into three circular sectors, the grammar can be applied in three iterations. Different numbers of initial divisions can include corresponding numbers of iterations of the shape grammar respectively.

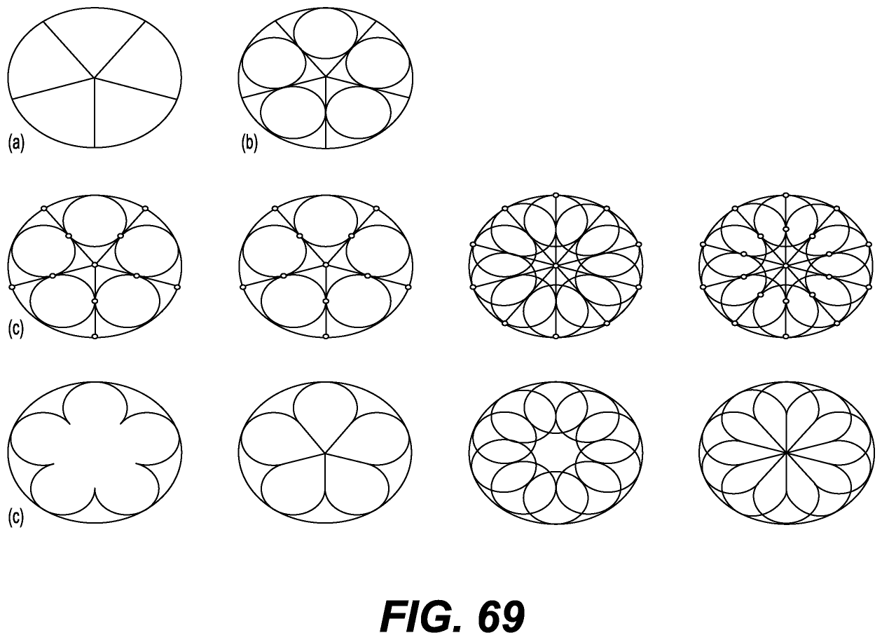

Referring to FIG. 69, the Shape Machine 200 can develop scaffolds into various Gothic rosette patterns by adding and subtracting lines and arcs during a detailing phase. FIG. 69 can illustrate progressive development of circular rosette patterns from a pentagonal scaffold. FIG. 69 can depict an initial shape, a scaffold with inscribed circles, different approaches to achieve variations of Gothic rosette patterns, and resulting variations of Gothic rosette patterns.

With continued reference to FIG. 69, the detailing phase can represent a second phase of the construction for Gothic rosette patterns. The scaffold can be developed into various patterns by adding and subtracting lines and arcs. Shapes to be removed can be indicated in a first attribute such as a first color, and shapes to be added can be indicated in a second attribute such as a second color. The different approaches to detailing can produce different variations of Gothic rosette patterns from the same pentagonal scaffold.

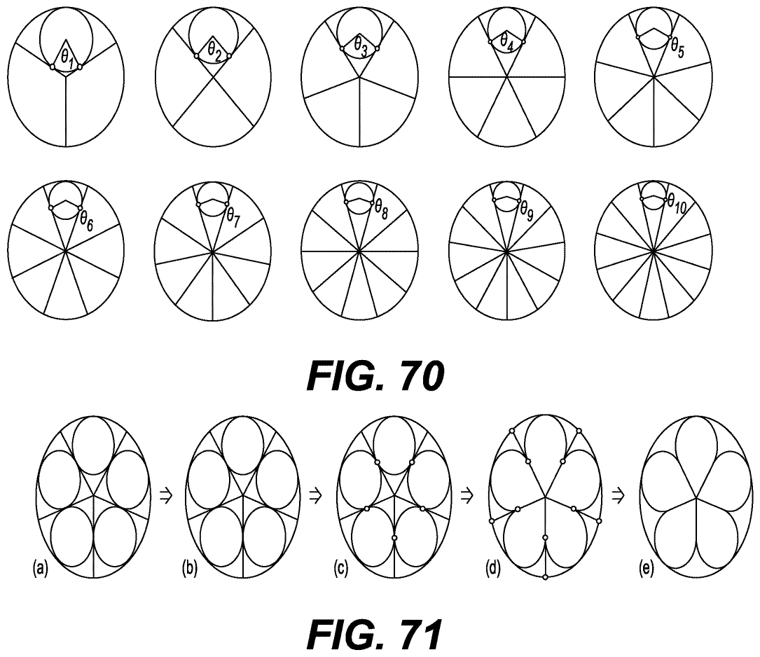

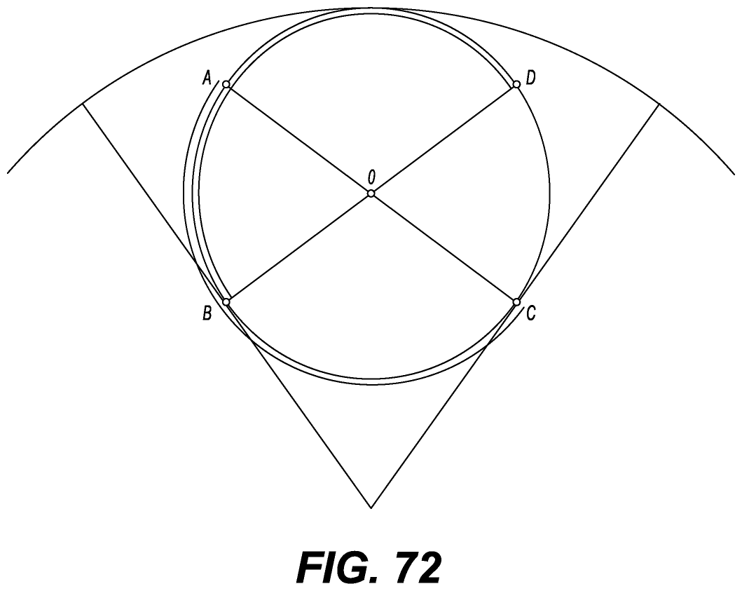

Referring to FIGS. 70-71, the Shape Machine 200 can address challenges associated with removing arcs from inscribed circles for different scaffolds during the detailing phase. FIGS. 70-71 can illustrate variations of circular shapes divided into sectors with inscribed elements, where arcs of the inscribed circles can have different radians for different scaffold divisions. No linear transformation can map an arc to another arc when the radians of the arcs are not identical. The Shape Machine 200 can address this challenge by using multiple steps of constructions with intersection operator rules.

With continued reference to FIGS. 70-71, the ornamentation of a circular sector of a Gothic rosette and the detailing of the circular sector can consist of four steps. A first step can differentiate an exterior circle and inscribed circles with different colors or attributes. A second step can identify arcs that are parts of the inscribed circles that are between two tangent points and closer to a center of the initial circle, and can subtract the identified arcs from the inscribed circles. A third step can identify line segments that are between inscribed circles and the exterior circle, and can subtract the identified line segments. A fourth step can remove all temporary colors or attributes.

Referring to FIG. 72, the Shape Machine 200 can implement the subtraction of arcs from inscribed circles in two parts. FIG. 72 can illustrate a geometric construction with a circle and an inscribed quadrilateral showing the removal of an arc that sweeps from a point A to a point C and the addition of an arc that sweeps from a point B to a point D. A first part of the subtraction can subtract an arc ABC that is half of the circle. A second part of the subtraction can add an arc DAB that is half of the circle. The two-part subtraction approach can enable the Shape Machine 200 to remove arcs of different radians from inscribed circles across different scaffold divisions.

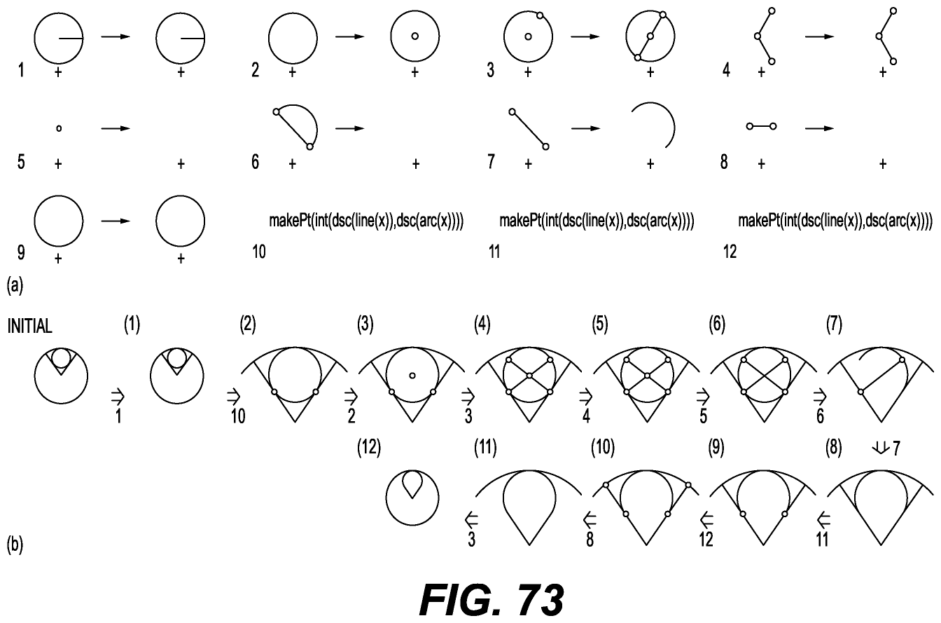

Referring to FIG. 73, the Shape Machine 200 can implement the foiling detailing for each circular sector of a Gothic rosette using a combination of shape rules and intersection operator rules. FIG. 73 can illustrate a set of shape grammar rules and a production sequence for constructing a foil motif in a circular sector of a Gothic Rosette window.

With continued reference to FIG. 73, a first part of FIG. 73 can illustrate twelve rules including nine shape rules and three intersection operator rules. The shape rules can define geometric transformations that add, remove, or modify geometric elements such as points, lines, arcs, and circles. The intersection operator rules can use operators including a makePt operator, an int operator, a dsc operator, a line operator, and an arc operator to compute intersection points from descriptors of shape elements.

As further shown in FIG. 73, a second part of FIG. 73 can illustrate a production sequence in twelve steps. The production sequence can begin with an initial shape comprising a circular sector containing an inscribed circle and can proceed through intermediate states to a final result comprising a foil motif within the circular sector. The steps can be connected by arrows indicating the order of rule application, with numbers below each arrow indicating which rule from the first part of FIG. 73 is applied at each step.

To detail all inscribed circles for all circular sectors of a rosette window, the rule applications can be processed for multiple iterations. For different scaffolds, different numbers of iterations can be included. The number of iterations for detailing can correspond to the number of circular sectors in the rosette scaffold.

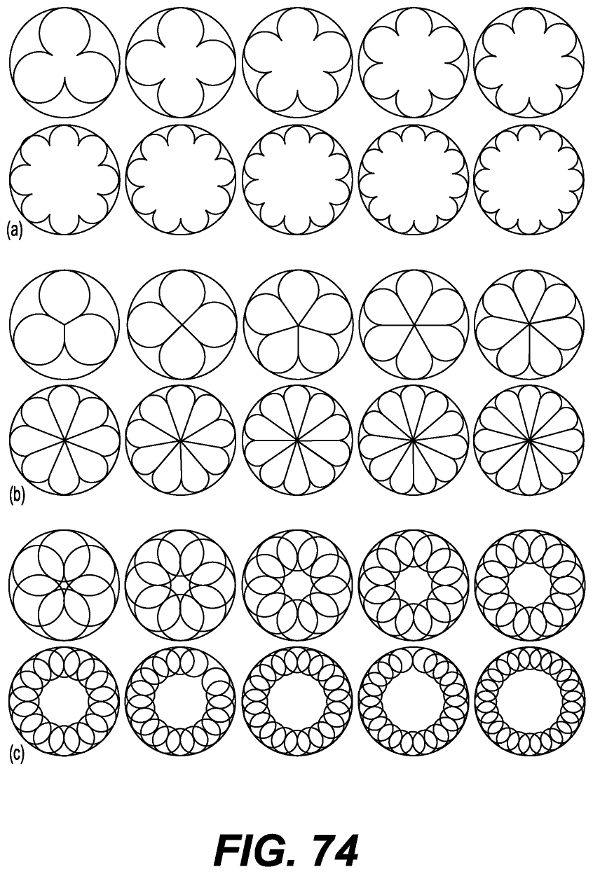

Referring to FIG. 74, the Shape Machine 200 can generate variations of n-foil Gothic rosette windows by applying the scaffold construction grammar and the detailing grammar. FIG. 74 can illustrate three rows of ten variations of n-foil Gothic rosette windows, ranging from trefoil patterns to twelve-foil patterns.

With continued reference to FIG. 74, a first row of FIG. 74 can illustrate ten circular patterns featuring petal-like or flower-shaped designs with curved lobes pointing inward toward a center, where each successive pattern from left to right can contain an increasing number of lobes ranging from three to twelve. A second row of FIG. 74 can display ten circular patterns with similar curved elements arranged in a different configuration, where curved segments can create overlapping or interlocking shapes with diagonal lines crossing through the center, progressing from three-fold to twelve-fold symmetry. A third row of FIG. 74 can present ten circular patterns composed of multiple overlapping circles arranged around a central point, creating rosette formations that can increase in complexity from left to right, with the number of constituent circles increasing from three to twelve across the row.

As further shown in FIG. 74, the third variation in the third row can be produced by applying the grammar to an initial shape and applying the grammar again to the initial shape rotated by half of the sector angle. Each column across all three rows can correspond to the same number of divisions, demonstrating how different detailing approaches applied to the same n-sector scaffold can produce distinct Gothic rosette pattern variations. Further detailing of the grammar to include the generation of nested foils, circles, and offset bands to denote material width can proceed along the procedures specified.

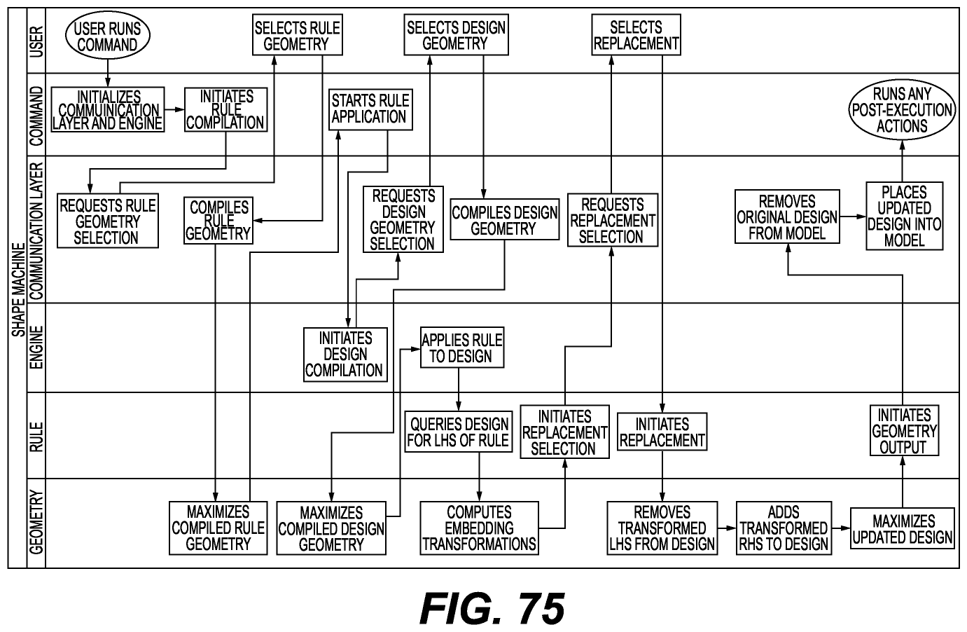

Referring to FIG. 75, a process flow for a search-and-replace command in the Shape Machine 200 can illustrate the interaction between multiple layers of the system architecture. The process flow can depict the coordination between a User layer, a Command layer, a Communication Layer, an Engine layer, a Rule layer, and a Geometry layer. The layered process flow can demonstrate how commands can initiate processes with the Shape Machine 200 and facilitate operations that are to be performed.

The process can begin at the User layer where a user runs a command. The Command layer can initialize the communication layer 300 and the Shape Machine 200 engine in response to the user running the command. The Command layer can then initiate rule compilation, which can prompt the communication layer 300 to request rule geometry selection from the User.

With continued reference to FIG. 75, once the user selects rule geometry, the communication layer 300 can compile the rule geometry. The Engine layer can then initiate design compilation, causing the communication layer 300 to request design geometry selection from the User. After the user selects design geometry, the communication layer 300 can compile the design geometry.

The Command layer can start rule application, which can cause the Engine to apply the rule to the design. The Rule layer can then query the design for the left-hand-side shape of the rule and can initiate replacement selection. The communication layer 300 can request replacement selection from the User in response to the Rule layer initiating replacement selection.

When the user selects a replacement, the Rule layer can initiate the replacement process. The Geometry layer can perform several operations including maximizing compiled rule geometry using the maximal line modeler 600, maximizing compiled design geometry, computing embedding transformations using the shape embedding engine 700, removing the transformed left-hand-side shape from the design, adding the transformed right-hand-side shape to the design, and maximizing the updated design.

As further shown in FIG. 75, the Rule layer can then initiate geometry output, which can cause the communication layer 300 to remove the original design from the model and place the updated design into the model. The Command layer can run post-execution actions, completing the search-and-replace operation. The process flow can demonstrate the layered architecture of the Shape Machine 200, showing how user interactions can flow through command processing, communication handling, engine operations, rule application, and geometry calculations to accomplish shape embedding and replacement operations within a CAD environment.

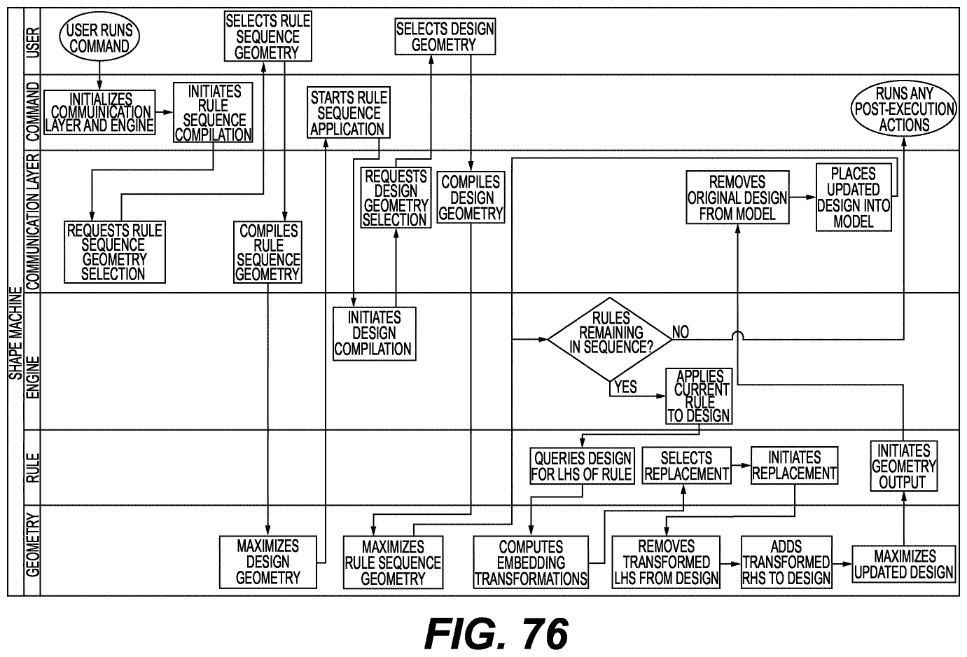

Referring to FIG. 76, a process flow for a sequence of search-and-replace commands can illustrate how the Shape Machine 200 can execute predefined sequences of replacement rules. Rule sequences can be applied to a design in order by the engine. Rule sequences can be compiled by the communication layer 300 and a format of rule sequences can be plugin or application specific. Rule sequences can be compiled at a command level or communication layer 300 but executed at an engine level.

The process flow shown in FIG. 76 can be organized into multiple horizontal swim lanes representing a User layer, a Command layer, a Communication Layer, a Shape Machine layer, an Engine layer, a Rule layer, and a Geometry layer. The process can begin in the User layer where a user runs a command. The user can then select rule sequence geometry and select design geometry.

With continued reference to FIG. 76, in the Command layer, the system can initialize the communication layer 300 and the Shape Machine 200 engine, can initiate rule sequence compilation, and can start rule sequence application. The Communication Layer can handle requests for rule sequence geometry selection, can compile rule sequence geometry, can request design geometry selection, and can compile design geometry.

In the Shape Machine layer, the system can initiate design compilation. The Engine layer can contain a decision point that checks whether rules remain in the sequence. If rules remain, the process can proceed to apply the current rule to the design. If no rules remain, the process can move toward completion.

The Rule layer can handle querying the design for the left-hand-side shape of the rule, selecting a replacement, initiating the replacement, and initiating geometry output. The Geometry layer can perform operations including maximizing rule sequence geometry, maximizing design geometry, computing embedding transformations, removing the transformed left-hand-side shape from the design, adding the transformed right-hand-side shape to the design, and maximizing the updated design.

As further shown in FIG. 76, after all rules in the sequence have been processed and the updated design has been placed into the model, the process can return to the Command layer where post-execution actions can be run. The communication layer 300 can remove the original design from the model and can place the updated design into the model at the conclusion of the process. The process flow can demonstrate the coordinated interaction between the user interface, communication components, shape processing engine, rule application logic, and geometric computation modules during the execution of a sequence of search-and-replace operations.

In some cases, rule sequence commands can run asynchronously. The Shape Machine 200 can execute predefined sequences of replacement rules using the rule sequence commands. Asynchronous rule sequence commands can run in a background thread so that processing can be paused or stopped partway through. Asynchronous commands can run in a separate thread, blocking a user interface thread only when the asynchronous commands update or modify the CAD model or when feedback is requested. Asynchronous commands can use a communication layer 300 created on the asynchronous thread, which can execute behavior on the user interface thread where necessary. To the commands and the Shape Machine 200 engine, the asynchronous communication layer 300 can appear identical to a standard communication layer 300 because the interface can be the same, but the implementation can differ.

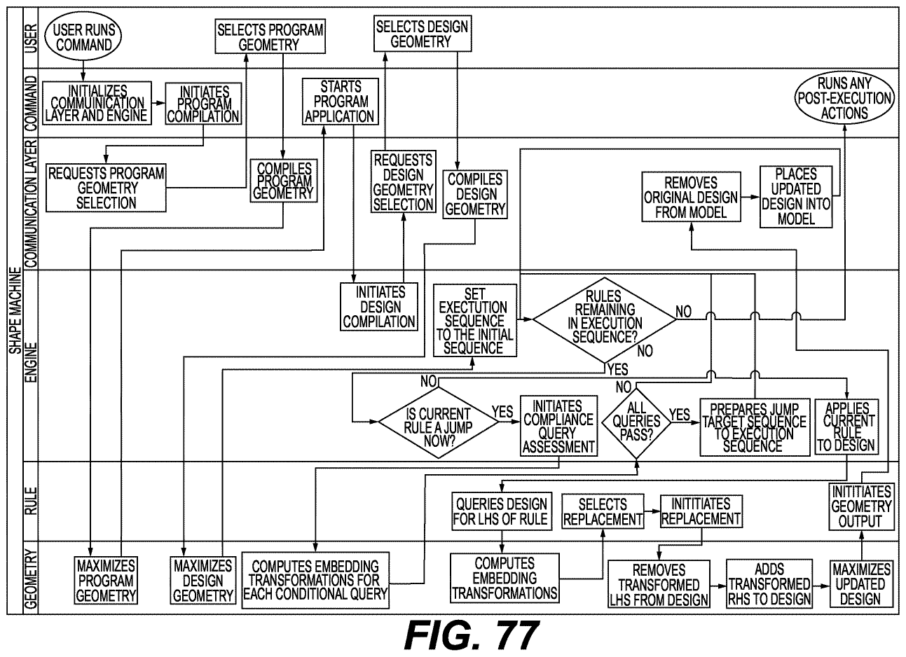

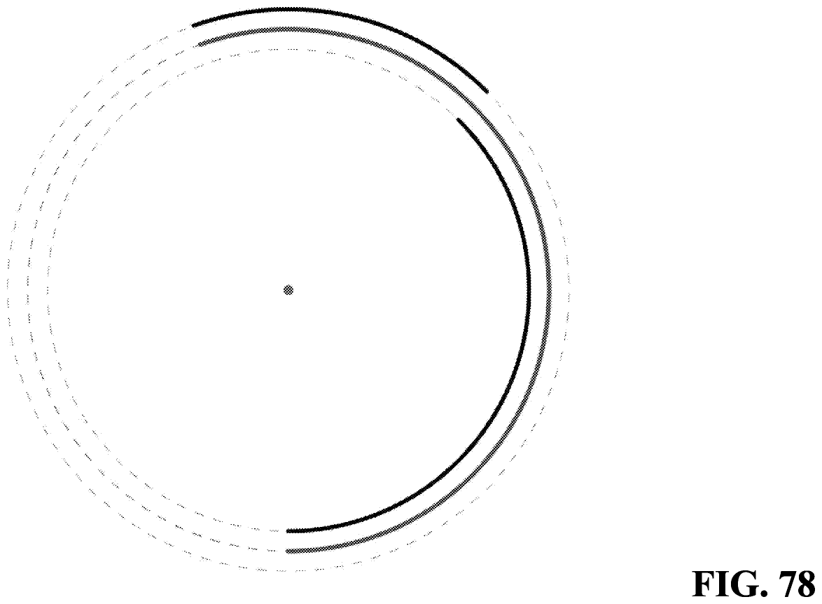

Referring to FIG. 77, a process flow for a program with jump rules and search-and-replace rules can illustrate how the Shape Machine 200 can interpret programs comprising collections of rule sequences. A program can be a collection of rule sequences that can be jumped between using specialized jump rules. Jump rules can be unconditional or can be based on queries made against the design. Conditional queries can check for the presence or absence of a shape in the design at a point of condition assertion, and an associated jump can be taken only if all queries pass.

The process flow shown in FIG. 77 can depict the interaction between a User layer, a Command layer, a Communication Layer, a Shape Machine layer, an Engine layer, a Ruler layer, and a Geometry layer. The process can begin in the User layer where a user runs a command and selects program geometry. The user can then select design geometry.

With continued reference to FIG. 77, in the Command layer, the system can initialize communication with the communication layer 300 and the Shape Machine 200 engine, followed by initiating program compilation. The system can then start the program application. In the Communication Layer, the system can request program geometry selection and can compile the program geometry. The system can then request design geometry selection and can compile the design geometry.

The Shape Machine layer can handle the initiation of design compilation. The system can set an execution sequence to an initial sequence. A decision point can check if rules remain in the execution sequence. If rules remain, the process can check if the current rule is a jump rule. If the current rule is a jump rule, the system can initialize correlation query execution. The process can then check if all queries pass. If all queries pass, the system can prepend a jump target sequence to the execution sequence. The system can then apply the current rule to the design.

As further shown in FIG. 77, in the Ruler layer, the system can query the design for the left-hand-side shape of the rule, can select a replacement, and can initialize the replacement. The Geometry layer can handle the maximization of program geometry and design geometry. The system can compute embedding transformations for each conditional query. The system can also compute embedding transformations for rule application, can remove the transformed left-hand-side shape from the design, can add the transformed right-hand-side shape to the design, and can maximize the updated design.

The process can include feedback loops where the system can remove the original design from the model and can place the updated design into the model. The process can run post-execution actions before completing. The process flow can demonstrate the coordination between different system components during the execution of a program containing both jump rules and search-and-replace rules, showing how the system can handle rule sequencing, conditional queries, and geometry transformations throughout the process.

With jump rules, the Shape Machine 200 can interpret Turing-complete programs. Programs can be compiled by the communication layer 300 and a format of programs can be plugin or application specific. Programs can be compiled at a command level or communication layer 300 but executed at an engine level. The combination of replacement rules and jump rules can enable the Shape Machine 200 to execute complex automated design transformations through sequences of shape replacement operations with branching logic.

Referring to FIG. 78, the maximal line modeler 600 can perform calibration and maximization operations on circular arcs in addition to lines. Arc carriers can encode a center position and a radius of an arc. Concentric arcs can be arcs that share the same center, and cocircular arcs can be arcs that share the same center and the same radius. Cocircular arcs can share the same carrier. The boundary of an arc, like a line, can be a one-dimensional range, where a start of the range can be an angle of one endpoint of the arc and an end of the range can be an angle of the other endpoint of the arc. The range can be set up such that any angle in the range is contained within the span of the arc.

With continued reference to FIG. 78, during calibration of arcs, an average carrier of a group of arcs can be calculated by computing an average center and an average radius of the group. FIG. 78 can illustrate two arcs undergoing calibration and maximization. Original arcs can be shown in black, with carriers of the original arcs including a common center point shown in dashed grey. A calibrated carrier can be computed by averaging the centers and radii of the two arc carriers, producing a calibrated arc carrier shown in dashed red. The two arcs can be projected onto the calibrated carrier and then maximized, with the resulting maximized arcs shown in solid red. The calibration process for arcs can generalize the calibration mechanism described for lines, where an average carrier can be computed for each group of elements on equivalent carriers and element boundaries can be projected onto the average carrier.

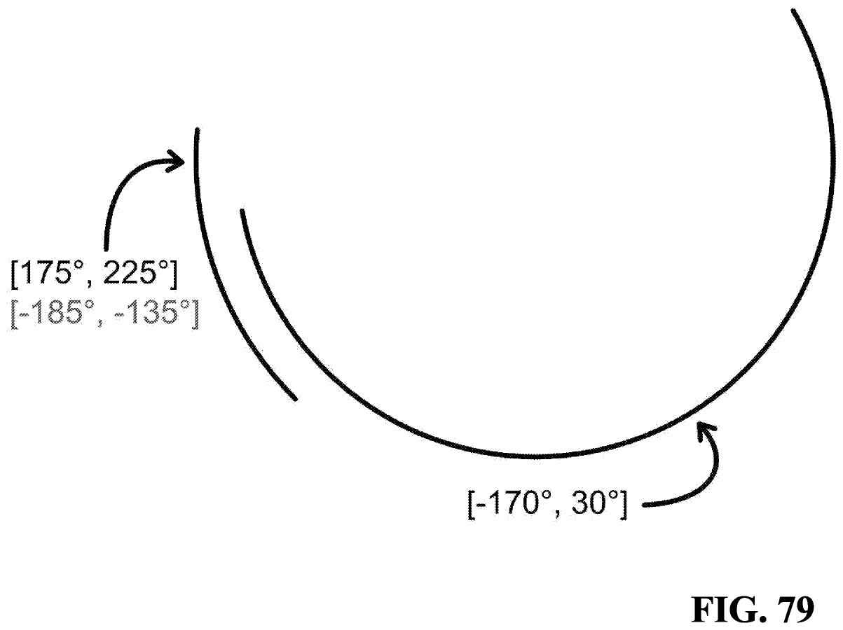

Referring to FIG. 79, maximization with arcs can require additional processing compared to maximization with lines because of a periodic nature of arc boundary ranges. Where maximization with lines can be a process of combining overlapping boundary ranges, maximization with arcs can account for the periodicity of angular boundary ranges. In some cases, one of the boundary ranges can be shifted by 2π or by −2π when initial ranges of two cocircular arcs do not overlap.

With continued reference to FIG. 79, FIG. 79 can illustrate two arcs with angular boundary ranges shown in degrees. A larger arc can span approximately three-quarters of a circle, with a boundary range extending across a horizontal axis such that a lower end of the boundary range is negative. A shorter arc can be positioned at a different angular location, with a boundary range that does not initially overlap with the boundary range of the larger arc. The boundary range of the shorter arc can be shifted by −2π to demonstrate that the ranges of the two arcs overlap when one boundary range is adjusted. The two arcs in FIG. 79 can be separated for visual effect. The shifting of boundary ranges can account for the periodic nature of angular measurements, where an arc that crosses a reference angle such as zero degrees can have a boundary range that spans from a negative angle to a positive angle.

A similar process for shifting boundary ranges can be incorporated in spatial relationship checks to adapt line relationship checks to periodic arcs. The spatial relationship checks for arcs can determine whether two cocircular arcs are equivalent, whether one arc contains another arc, or whether two arcs overlap. The periodic shifting of boundary ranges can enable the maximal line modeler 600 to correctly identify overlapping arcs and perform Boolean union operations to combine the overlapping arcs into maximal arcs.

Under isometry and similarity transformations, an image of an arc can be computed by transforming endpoints and a midpoint of a preimage arc, and the carrier and boundaries of the image arc can be recomputed from the transformed endpoints and midpoint. Circles can be a special case of arc that has no boundary. When a circle is processed by the maximal line modeler 600, the circle can be treated as an arc with a full angular range and no boundary endpoints.

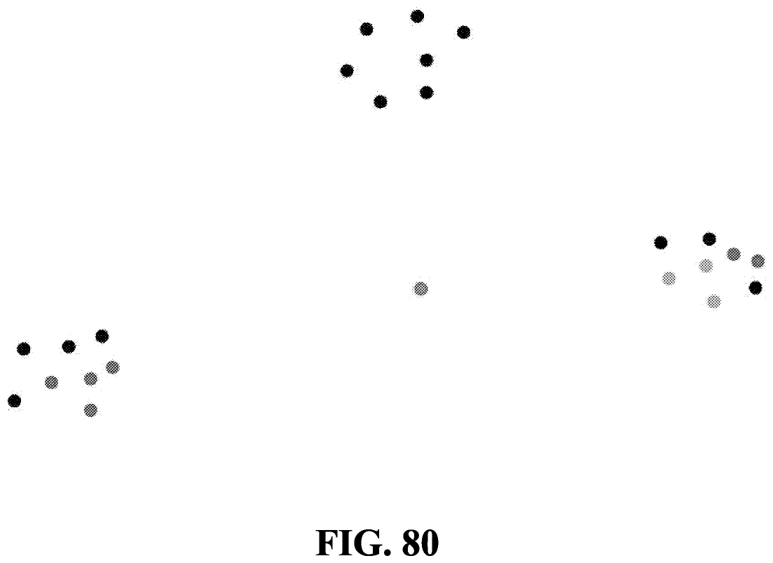

Referring to FIG. 80, the maximal line modeler 600 can perform calibration and maximization operations on points in addition to lines and circular arcs. Points can be a type of geometric element because points can be zero-dimensional. A carrier associated with a point can be identical to the point itself. Point carriers can conform to a paradigm where a carrier defines maximization behavior and an element defines spatial relationship checks and transformation calculations.

FIG. 80 can illustrate a shape made of points before calibration and maximization. The shape can contain multiple clusters of points distributed across a two-dimensional space. A first group of points can appear in an upper center region of the shape, comprising points arranged in a loose cluster. A second group of points can be located in a lower left region, containing points with different attributes such as different colors positioned near each other. A third group of points can appear in a lower right region, comprising points with multiple different attributes clustered together. A fourth element can be a single point positioned in a center region of the shape. Distances within each group can be exaggerated in FIG. 80 for visual effect to demonstrate how points within a small tolerance of each other can be grouped together during a calibration process.

With continued reference to FIG. 80, point maximization can start by grouping all points that are within a small distance of each other. The grouping can be determined with a pairwise distance calculation. The pairwise distance calculation can compute distances between each pair of points in the shape and can identify groups of points where the distance between points within each group is smaller than a specified tolerance. The tolerance can address precision errors caused by floating-point arithmetic in CAD geometry, where points that should be coincident can differ by small amounts due to numerical representation limitations.

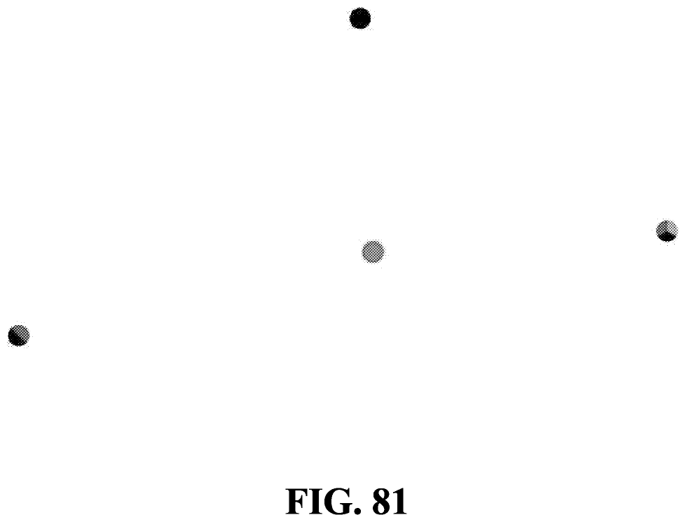

Referring to FIG. 81, calibrated points can be created from the groups of points identified during the pairwise distance calculation. An average location of each group can be used as a new carrier for each group. A new point element can be created on the new carrier for each attribute found in the group. FIG. 81 can illustrate a shape made of four calibrated points corresponding to the four groups shown in FIG. 80.

With continued reference to FIG. 81, groups containing multiple attributes can create one point for each attribute present in the group. For example, a group containing points with a first attribute and a second attribute can produce a calibrated point having both the first attribute and the second attribute at the averaged location. A group containing points with a first attribute, a second attribute, and a third attribute can produce a calibrated point having all three attributes at the averaged location. The multiple attributes at a single calibrated location can be depicted as colored sections of the respective point in FIG. 81.

The spatial relationship checks for points can be straightforward compared to spatial relationship checks for lines and arcs. Two points can be either coincident or not coincident. Points can transform as a vector would under a given transformation matrix. The maximal line modeler 600 can process points through the same calibration paradigm used for lines and arcs, where elements on equivalent carriers can be grouped, an average carrier can be computed for each group, and element boundaries can be projected onto the average carrier. For points, the average carrier can be the average location of the group, and the boundary can be the point location itself because points are zero-dimensional.

As further shown in FIG. 81, elements with different attributes can be incomparable for spatial relationship checks but can still be grouped during calibration and maximization. The grouping of points during calibration can remove duplicate points and can average out floating-point errors that arise from numerical precision limitations in the CAD system. The calibrated points can then be used in subsequent processing by the shape embedding engine 700, where registration points can be derived from intersections of carriers associated with maximal elements including maximal lines, maximal arcs, and maximal points. Intersections of carriers in a shape can be calibrated in the same way that points are calibrated, to remove duplicates and to average out floating-point errors, and carriers that contributed to intersections in each group can be reassociated with the calibrated intersections.

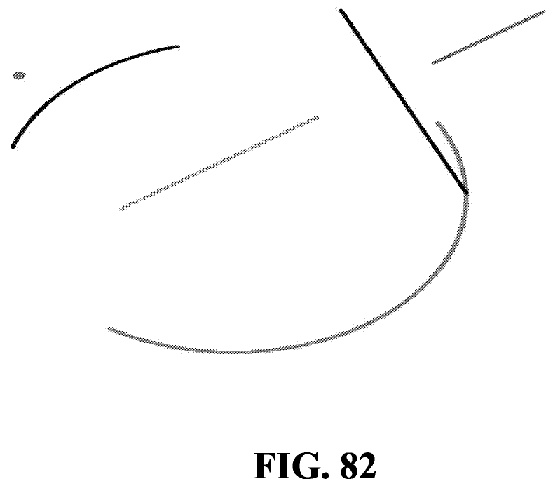

Referring to FIG. 82, a shape can comprise a combination of points, lines, and circular arcs as geometric elements. The Shape Machine 200 can process shapes comprising mixed element types, where each element type can be associated with a carrier and a boundary. A carrier can encode geometric information about an element, comparable to an equation of the element. A boundary of an element can encode an extent of the element along the carrier of the element. For line elements, the carrier can comprise a hyperplane equation and the boundary can comprise endpoint coordinates. For arc elements, the carrier can encode a center position and a radius, and the boundary can comprise an angular range defined by angles of endpoints of the arc. For point elements, the carrier can be identical to the point location, and the boundary can be the point location because points are zero-dimensional.

With continued reference to FIG. 82, the shape can include a black curved arc segment, an orange diagonal line segment, a black diagonal line, a blue diagonal line segment, a blue dot representing a point element, and a magenta curved arc. The different colors of the geometric elements can represent different attributes associated with the elements. The attributes can include a layer name, a color, a unique name, and a linetype. Each carrier can also contain a set of all element attributes present in elements contained within the carrier.

A shape signature can be a deferred and cached property of a shape, computed by the shape embedding engine 700 when requested and cached for later use. The shape signature can be computed in a four-step process. The shape signature can be referred to herein as a signature of the shape.

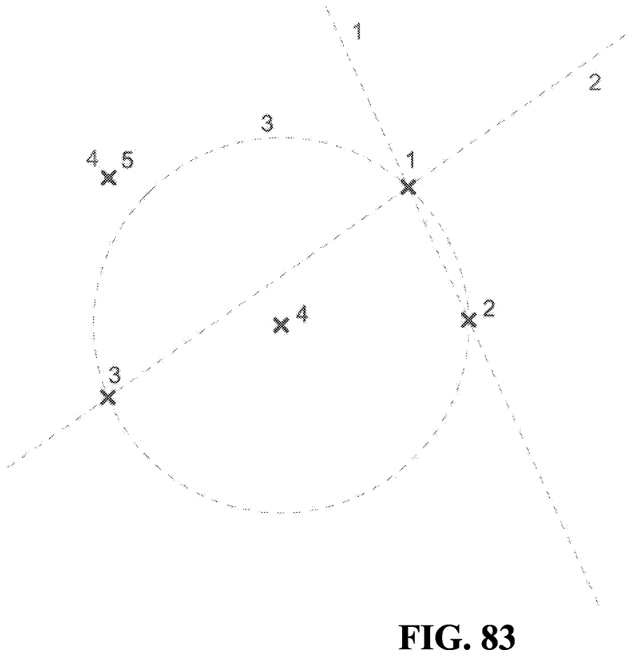

Referring to FIG. 83, a first step of the shape signature computation can compute all intersections of carriers in the shape. The intersection calculations can be defined per carrier type. Centers of arc carriers and locations of point carriers can be included in an intersections list in addition to intersections between line carriers, between line carriers and arc carriers, and between arc carriers. FIG. 83 can illustrate carriers and registration point locations of the shape shown in FIG. 82. Carriers can be shown as dashed grey lines extending beyond boundaries of the shape elements the carriers represent. Five carriers can be present in FIG. 83, numbered 1 through 5, where carrier 4 can be a point carrier. Registration point locations can be marked with crosses and numbered 1 through 5.

With continued reference to FIG. 83, carrier 1 can extend diagonally from an upper left region toward a lower right region of the shape. Carrier 2 can extend from an upper center region toward a lower right region. Carrier 3 can be positioned in an upper portion of the shape. Carrier 4 can represent a point carrier located in a left portion of the shape. Carrier 5 can appear as a circular dashed line in a lower central portion of the shape, representing an arc carrier. Registration point 1 can be located at an intersection of carriers 1, 2, and 3. Registration point 2 can be positioned at an intersection of carriers 2 and 5. Registration point 3 can be located at an intersection of carriers 1 and 5. Registration point 4 can be positioned in a left portion of the shape corresponding to carrier 4. Registration point 5 can correspond to a center of the circular carrier 5.

A second step of the shape signature computation can calibrate the intersections in the same manner that points are calibrated, to remove duplicates and to average out floating-point errors. Carriers that contributed to intersections in each group can be reassociated with the calibrated intersections. In the example of FIG. 83, registration point 1 can be created as a result of calibrating three intersections, where the intersections between carriers 1 and 2, carriers 1 and 3, and carriers 2 and 3 can be grouped and calibrated to produce a single registration point location.

Referring to FIG. 84, a third step of the shape signature computation can create registration points at each calibrated intersection. Each registration point can include properties that encode geometric and attribute information associated with the carriers passing through the registration point. FIG. 84 can illustrate registration point signatures corresponding to five registration points of the shape shown in FIG. 83.

With continued reference to FIG. 84, two spokes can be created for each line carrier passing through an intersection. A spoke can encode information about a half of the line carrier on one side of the registration point. Each line carrier can create two spokes because each spoke can represent one half of the carrier extending in opposite directions from the registration point. A spoke can include a vector direction of the half-carrier and a map from each element attribute present on the carrier to a spoke type. The spoke type can indicate whether a line with a particular attribute on the half-carrier meets the registration point, whether all lines with the particular attribute on the half-carrier do not meet the registration point, or whether no lines with the particular attribute exist on the half-carrier. In a case where no lines with a particular attribute exist on one half-carrier, the other half-carrier can contain a line with the particular attribute.

As further shown in FIG. 84, registration points created by arc carriers can include information about radii of the arc carriers. Registration points created by point carriers can be provided with a radius of zero. Registration points created by point and arc carriers can also contain a set of all attributes found on the carriers that created the registration points. The attributes can be referred to herein as direct attributes.

The registration point signatures shown in FIG. 84 can include direct attributes depicted as labels such as “Black,” “Pink,” and “Blue,” corresponding to the attributes of the geometry associated with the carriers passing through the corresponding registration points. Radii sets can be depicted in notation adjacent to each registration point signature. For registration point 1, the signature can show direct attributes of “Black” and “Pink” and a radii set of {10}. For registration point 2, the signature can display four spokes extending in different directions, with direct attributes of “Black” and “Pink” and a radii set off{10}. For registration point 3, the signature can show two spokes with direct attributes of “Black” and “Pink” and a radii set of {10}. For registration point 4, the signature can present direct attributes of “Black” and “Pink” and a radii set of {10} with no visible spokes. For registration point 5, the signature can show a direct attribute of “Blue” and a radii set of {0}, corresponding to a point carrier.

A fourth step of the shape signature computation can create a hypergraph incidence matrix for the entire signature. Registration points can correspond to vertices of the hypergraph, and carriers can correspond to hyperedges of the hypergraph. The hypergraph incidence matrix can contain a row for each registration point and a column for each carrier, where a value of one in row i and column j can indicate that registration point i was created by carrier j.

The shape embedding engine 700 can use the hypergraph incidence matrix during a registration point matching process. Registration points can be considered neighbors if there is a column where both registration points' corresponding cells are shaded, indicating that both registration points were created by the same carrier. The neighbor relationships can be used during breadth-first-search exploration of the hypergraph when matching registration points of a query shape to registration points of a design.

The shape signature can enable the shape embedding engine 700 to compare shapes comprising mixed element types including lines, circular arcs, and points. The registration point derivation and reduction process 710 can compute intersections of carriers for all element types. The registration point weight calculation process 720 can calculate weights for registration points based on spokes, direct attributes, and radii sets. The registration point ranking process 730 can rank registration points based on the calculated weights to reduce a search space for shape embedding operations.

Referring to FIG. 85, a fourth step of a shape signature computation can create a hypergraph incidence matrix for an entire shape signature. Registration points can correspond to vertices of a hypergraph, and carriers can correspond to hyperedges of the hypergraph. The hypergraph incidence matrix can contain a row for each registration point and a column for each carrier. A value of one in row i and column j can indicate that registration point i was created by carrier j. A value of zero in row i and column j can indicate that carrier j did not contribute to the creation of registration point i.

With continued reference to FIG. 85, the hypergraph incidence matrix can include five rows corresponding to five registration points numbered 1 through 5 and four columns corresponding to four carriers numbered 1 through 4. Shaded cells in the matrix can indicate that the carrier in the corresponding column contributed to the creation of the registration point in the corresponding row. Unshaded cells can indicate that the carrier did not contribute to the creation of the registration point.

Two registration points can be considered neighbors when there is a column in the hypergraph incidence matrix where both registration points' corresponding cells are shaded. The neighbor relationship can indicate that both registration points were created by the same carrier. The shape embedding engine 700 can use the neighbor relationships encoded in the hypergraph incidence matrix during a registration point matching process to traverse from one registration point to adjacent registration points that share a common carrier.

The shape embedding engine 700 can use the hypergraph incidence matrix to perform a breadth-first-search exploration of the hypergraph when matching registration points of a left-hand-side shape to registration points of a design. The breadth-first-search exploration can begin at an anchor registration point and can traverse to neighboring registration points by following hyperedges in the hypergraph incidence matrix. The order of traversal on the left-hand-side shape can be determined by the significance of the registration points, where a more significant registration point can be visited before a less significant registration point at the same depth from the anchor. Traversal on the design can be decided by the order in which the registration points were created.

With continued reference to FIG. 85, the hypergraph incidence matrix can encode connected component information for the shape signature. A registration point that is in the same connected component as the anchor can be matched to a design registration point that is in the same connected component as the design registration point matched to the anchor. Two registration points can be in the same connected component when there is a path of hyperedges from one registration point to the other registration point. A registration point of the left-hand-side shape that is not connected to the anchor can still be matched to a design registration point that is connected to the design registration point matched to the anchor.

The hypergraph incidence matrix can support additional distance-based constraints during the traversal. When the embedding transformation is limited to an isometry, the distances between the registration points of the left-hand-side shape can further restrict the potential matches so that the distances between matched registration points in the design match the distances between the corresponding registration points in the left-hand-side shape. When the embedding transformation is limited to a similarity, the ratios between the distances can match. The distance-based constraints can further restrict the number of candidate transformations to check during the breadth-first-search exploration.

As further shown in FIG. 85, the hypergraph incidence matrix can enable the shape embedding engine 700 to reduce the number of candidate transformation matrices that are computed and verified during the embedding checking process 780. By traversing the hypergraph from the anchor registration point and checking neighbor relationships encoded in the hypergraph incidence matrix, the shape embedding engine 700 can identify candidate registration point matches without exhaustively comparing all possible combinations of registration points between the left-hand-side shape and the design.

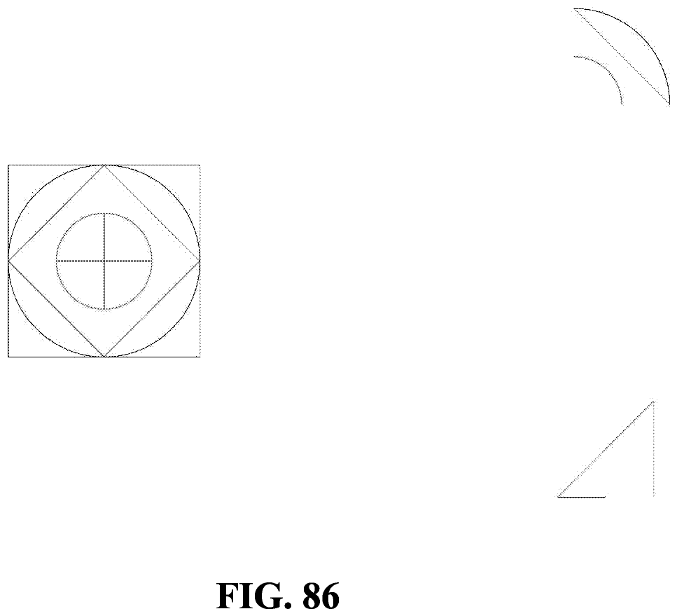

Referring to FIG. 86, a design and two query shapes can illustrate how the shape embedding engine 700 matches query signatures against a design signature during shape embedding calculations. FIG. 86 can depict a design on a left side of the figure and two query shapes on a right side of the figure. The design can comprise a composite shape including a square outline, a circle inscribed within the square, a smaller circle at a center of the square, a rotated inner square in a diamond orientation, and diagonal lines connecting corners of the outer square through the center. The design can include geometric elements rendered in different attributes, such as different colors, including teal, yellow, blue, magenta, and black. A first query shape can be positioned in an upper right portion of FIG. 86 and can comprise a partial arc shape with intersecting lines. A second query shape can be positioned in a lower right portion of FIG. 86 and can comprise a right triangle shape. The geometric elements in the query shapes can also include different attributes such as different colors.

With continued reference to FIG. 86, the design and the two query shapes can each comprise a combination of points, lines, and circular arcs as geometric elements. Each geometric element can be associated with a carrier and a boundary. A carrier can encode geometric information about an element, comparable to an equation of the element. A boundary of an element can encode an extent of the element along the carrier of the element. For line elements, the carrier can comprise a hyperplane equation and the boundary can comprise endpoint coordinates. For arc elements, the carrier can encode a center position and a radius, and the boundary can comprise an angular range defined by angles of endpoints of the arc. For point elements, the carrier can be identical to a point location, and the boundary can be the point location because points are zero-dimensional. Each carrier can also contain a set of all element attributes present in elements contained within the carrier.

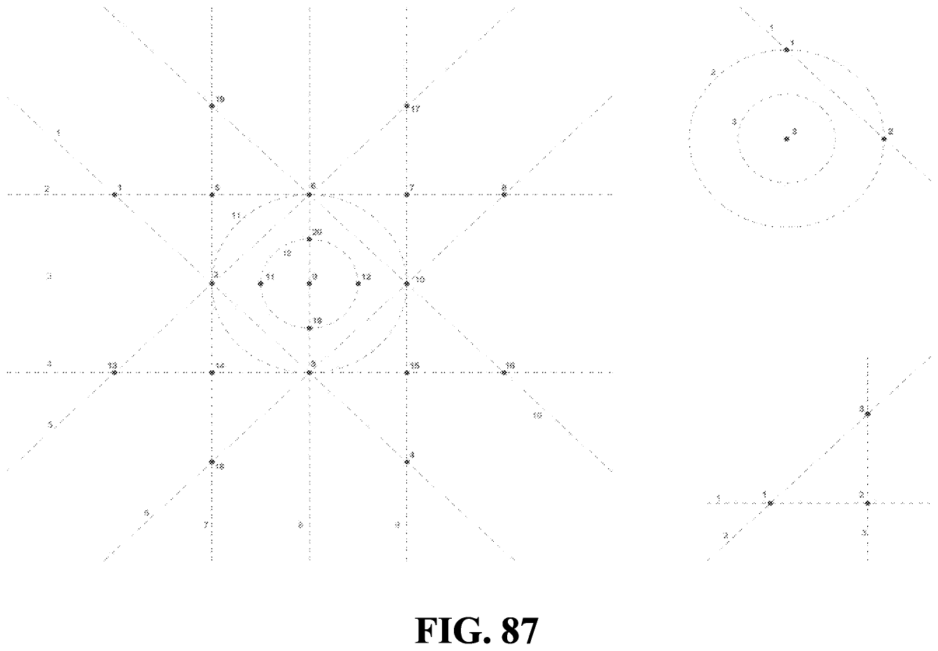

Referring to FIG. 87, signatures of the design and the two query shapes shown in FIG. 86 can be illustrated. FIG. 87 can depict a design signature on a left side of the figure, a first query signature in an upper right portion of the figure, and a second query signature in a lower right portion of the figure. Carriers can be depicted as dashed grey lines extending beyond boundaries of the shape elements the carriers represent. Registration points can be depicted as red points. Carriers can be numbered in grey, and registration points can be numbered in red.

With continued reference to FIG. 87, the design signature can include multiple carriers extending in horizontal, vertical, and diagonal directions, as well as circular carriers corresponding to arc elements. The design signature can include twenty registration points numbered D1 through D20, positioned at locations where carriers intersect. The registration points can occur at intersections of line carriers, at intersections of line carriers and arc carriers, and at centers of arc carriers. The first query signature can include three registration points numbered Q1, Q2, and Q3, with curved dashed lines representing arc carriers that form concentric circular patterns. The second query signature can include three registration points numbered Q1, Q2, and Q3, with dashed lines representing line carriers extending through the registration points in multiple directions.

The shape embedding engine 700 can match query signatures against the design signature by selecting an anchor registration point in the query shape and traversing the hypergraph of the design to find candidate matches. The shape embedding engine 700 can select the anchor registration point based on a significance determination. The significance of a registration point can be determined by multiple factors including: a number of radii at the registration point, a number of direct attributes associated with point and arc carriers that created the registration point, occurrences of direct attributes in the design signature, a number of spokes on the registration point, and occurrences of spoke attributes in the design signature. The shape embedding engine 700 can determine the most significant query registration point by choosing the registration point with the lexicographic maximum of the computed significances.

As further shown in FIG. 87, for the first query signature in the upper right portion of FIG. 87, the registration point Q3 can have two radii and two direct attributes, making Q3 the most significant registration point. The shape embedding engine 700 can select Q3 as the anchor when embedding. Q1 and Q2 can be used as the other two query reference points. When exploring the design signature, the shape embedding engine 700 can first find a potential match for the anchor Q3. In the design signature, the registration point D9 can be the only registration point with two radii, making D9 the only potential match for Q3. The shape embedding engine 700 can proceed from D9 following a breadth-first search order through neighboring registration points in the hypergraph incidence matrix.

With continued reference to FIG. 87, the shape embedding engine 700 can traverse from D9 to neighboring registration points at a depth of one, including D2, D3, D6, D10, D11, D12, D19, and D20, and then to remaining registration points at a depth of two from D9. During the traversal, the shape embedding engine 700 can check each candidate design registration point against the query registration points Q1 and Q2 by comparing signature properties and distance constraints. When the embedding transformation is restricted to an isometry, the distances between the query registration points can further restrict the potential matches so that the distances between matched registration points in the design match the distances between the corresponding registration points in the query. For the first query, the only candidate matches for Q1 and Q2 can be D6 and D10, because all other design registration points do not match the signature checks and the distance checks for isometry embedding. The match candidates for Q3, Q1, and Q2 can be D9, D6, and D10, as well as D9, D10, and D6.

Referring again to FIG. 87, for the second query signature in the lower right portion of FIG. 87, the registration point Q2 can be selected as the anchor based on the significance determination. Q3 and Q1 can be used as the other two reference points. The design registration points D6, D10, and D15 can all be potential matches for Q2. The shape embedding engine 700 can distinguish between candidate registration points based on spoke attributes. For example, although certain design registration points can have spokes with matching attributes, the spoke types can differ between connected and disconnected configurations, causing the shape embedding engine 700 to exclude registration points where the spoke types do not match the query registration point.

With continued reference to FIG. 87, the shape embedding engine 700 can explore from each potential anchor match in the design signature. When exploring from D6, potential candidates for Q3 and Q1 can be identified, but no combination of candidates can satisfy the distance measurements for isometry, causing all candidates to be discarded. When exploring from D10, a similar result can occur where no combination of candidates satisfies the distance constraints. When exploring from D15, the candidates for Q3 can include D6, D7, and D10, and the candidates for Q1 can include D2, D3, D5, D6, and D10. The only combination of candidates that satisfies the distance measurements can be D10 for Q3 and D3 for Q1. The match candidates for Q2, Q3, and Q1 for the second query can be D15, D10, and D3.

The matching process illustrated in FIGS. 86-87 can demonstrate how the shape embedding engine 700 reduces the number of candidate transformation matrices by using registration point signatures, hypergraph traversal, and distance constraints. By selecting the most significant registration point as an anchor and traversing the hypergraph in a breadth-first search order, the shape embedding engine 700 can efficiently identify candidate matches without exhaustively comparing all possible combinations of registration points between the query shape and the design.

Referring to FIG. 88, the shape embedding engine 700 can create phantom registration points to establish a reference frame for computing embedding transformations when a query shape has fewer than three non-collinear registration points. FIG. 88 can illustrate three stages of a shape embedding process showing a query shape and a design, along with respective signatures and phantom registration points used for transformation calculations.

A top portion of FIG. 88 can depict a query shape comprising a horizontal line segment and a design comprising a square shape. The query shape can be referred to herein as a small query because the query shape has fewer than three non-collinear registration points. The design can include registration points at corners and midpoints of the square shape.

A middle portion of FIG. 88 can depict respective signatures of the query shape and the design. Line carriers can be shown as dashed grey lines extending beyond boundaries of the shape elements the line carriers represent. Registration points can be depicted as dots at locations where carriers intersect. The signature of the design can include dashed lines extending beyond the boundaries of the square shape both horizontally and vertically, with dots marking registration points at corners and along the extended dashed lines.

A bottom portion of FIG. 88 can depict phantom registration points created for the query signature and the design signature. A phantom registration point can be created for the query signature to establish a valid reference frame. The phantom registration point on the query signature can be shown in a different visual indicator such as a different color. Everywhere that a valid match candidate can be found for the query signature in the design, a corresponding phantom registration point can be created, including a mirror image of the corresponding phantom registration point, to support the calculation of embedding transformations.

With continued reference to FIG. 88, the shape embedding engine 700 can handle two cases for creating phantom registration points based on a number of registration points in the query shape. In a first case, when the query shape has two registration points, the shape embedding engine 700 can create a phantom registration point to form a right angle with the two existing registration points. A corresponding phantom registration point can be created against all pairs of two design registration points that match the two query registration points.

In a second case, when the query shape has one registration point, the shape embedding engine 700 can create phantom registration points using spokes on the registration point. For each spoke on the registration point, a first phantom registration point can be created in a direction of the spoke at a distance of one unit from the actual registration point. A second phantom registration point can be created to form a right angle with the actual registration point and the first phantom registration point.

The shape embedding engine 700 can create corresponding phantom registration points on the design signature. For each spoke on each design registration point that the query anchor can match to, corresponding phantom registration points can be created. Both legs of the right angles created on the design signature can be the same length as the legs of the right angle created on the query signature. Two right angles can be created on the design signature for each match candidate: a first right angle corresponding to a direct transformation and a second right angle corresponding to an indirect transformation. A first leg of the first right angle and a first leg of the second right angle can be the same. A second leg of the second right angle can be flipped across the first matched design registration point relative to a second leg of the first right angle.

The reference frame created on the query shape can be a right angle with legs of the same length. The phantom registration points created on the design can be transformed according to indeterminate parameters specified by user input or calculated parameter ranges. The registration points and phantom registration points used to create the right angles can be used in the transformation calculation as if the registration points and phantom registration points were all actual registration points.

As further shown in FIG. 88, the phantom registration points can enable the shape embedding engine 700 to compute embedding transformations for query shapes that would otherwise lack sufficient registration points for the transformation calculation. When replacing a found shape with a new shape, the shape that gets placed into the design can be transformed in the same way as the query shape when embedded. The reference frames established by the phantom registration points can ensure that all possible replacement transformations are accounted for, including both direct transformations and indirect transformations that incorporate reflection operations.

The disclosed technology can be further understood according to the following clauses:

Clause 1: A system for shape computation in a computer-aided design environment, comprising:
one or more processors; and
a memory storing instructions that, when executed by the one or more processors, cause the system to:
receive, via a communication layer, a shape rule comprising a left-hand-side shape and a right-hand-side shape from a computer-aided design application;
receive, via the communication layer, a design comprising a plurality of geometric elements;
convert the plurality of geometric elements into a maximal element representation by grouping elements on equivalent carriers and computing an average carrier for each group;
derive registration points from intersections of carriers associated with the maximal element representation;
calculate a weight for each registration point based on geometric features of maximal elements intersecting at the registration point;
rank the registration points based on the calculated weights to reduce a search space for shape embedding;
compute one or more transformation matrices by matching registration points of the left-hand-side shape to registration points of the design;
determine whether the left-hand-side shape is embedded in the design under a geometric transformation defined by the one or more transformation matrices; and
apply the shape rule to the design by performing a Boolean difference operation to remove a transformed instance of the left-hand-side shape from the design and performing a Boolean union operation to add a corresponding transformed instance of the right-hand-side shape to the design.

Clause 2: The system of clause 1, wherein the communication layer is configured to perform shape rule unpacking, parameter fetching, attribute fetching, and converting model objects from the computer-aided design application to shape machine objects.

Clause 3: The system of clause 1, wherein the instructions further cause the system to apply a calibration mechanism to address precision errors in the geometric elements by projecting endpoints onto a calibrated carrier computed as a bisector of carriers where elements are embedded.

Clause 4: The system of clause 1, wherein the geometric elements comprise one or more of lines, circular arcs, and points.

Clause 5: The system of clause 1, wherein the geometric transformation comprises one of an isometry, a similarity transformation, an affine transformation, or a linear transformation.

Clause 6: The system of clause 1, wherein the instructions further cause the system to:
detect an indeterminate embedding condition when the left-hand-side shape has fewer registration points than required to derive the one or more transformation matrices for a specified transformation type;
create phantom registration points to establish a reference frame for computing the transformation; and
request user input via the communication layer to specify a value for an indeterminate transformation parameter.

Clause 7: The system of clause 1, wherein the maximal element representation comprises maximal lines, wherein each maximal line is associated with a carrier encoding geometric information and a boundary encoding an extent of the maximal line along the carrier.

Clause 8: A method for shape embedding and shape replacement in a computer-aided design system, comprising:
receiving, by one or more processors, a shape rule comprising a left-hand-side shape and a right-hand-side shape;
receiving, by the one or more processors, a design comprising a plurality of geometric elements from a computer-aided design application;
maximizing, by the one or more processors, the plurality of geometric elements by grouping elements on equivalent carriers and replacing each group with a minimal number of maximal elements;
calibrating, by the one or more processors, the maximal elements by computing an average carrier for each group and projecting element boundaries onto the average carrier;
computing, by the one or more processors, registration points at intersections of carriers associated with the maximal elements;
calculating, by the one or more processors, a weight for each registration point based on a number of hyperplanes and maximal elements intersecting at the registration point;
ranking, by the one or more processors, the registration points based on the calculated weights;
sampling, by the one or more processors, registration points from the left-hand-side shape and the design based on the ranking;
deriving, by the one or more processors, transformation matrices from the sampled registration points;
determining, by the one or more processors, whether the left-hand-side shape is embedded in the design under a transformation defined by the transformation matrices; and
applying, by the one or more processors, the shape rule by subtracting a transformed left-hand-side shape from the design and adding a transformed right-hand-side shape to the design.

Clause 9: The method of clause 8, wherein maximizing the plurality of geometric elements comprises:
checking spatial relationships between elements to determine parallelism and collinearity;
grouping elements based on the spatial relationships; and
performing a Boolean union operation with calibration to combine grouped elements into maximal elements.

Clause 10: The method of clause 8, wherein calibrating the maximal elements comprises applying tolerances for angle and distance to address precision errors caused by floating-point arithmetic.

Clause 11: The method of clause 8, wherein computing registration points comprises:
computing intersections of carriers in a shape;
calibrating the intersections to remove duplicates and average out floating-point errors; and
creating a registration point at each calibrated intersection with associated carrier information.

Clause 12: The method of clause 8, further comprising:
detecting an indeterminate embedding condition when the left-hand-side shape has insufficient registration points to derive the transformation matrices;
classifying a case of indeterminate embedding based on a number of registration points and a type of transformation; and
calculating parameter ranges for indeterminate transformation parameters.

Clause 13: The method of clause 8, wherein deriving transformation matrices comprises using a pictorial approach that decomposes high-degree calculations into multiple low-degree calculations to reduce accumulated precision errors.

Clause 14: The method of clause 8, wherein the geometric elements comprise lines, and wherein each line is associated with a carrier comprising a hyperplane equation and a boundary comprising endpoint coordinates.

Clause 15: The method of clause 8, wherein the geometric elements comprise circular arcs, and wherein calibrating the maximal elements comprises computing an average center and an average radius for a group of arcs on equivalent carriers.

Clause 16: A non-transitory computer-readable medium storing instructions that, when executed by one or more processors, cause the one or more processors to:
receive a shape rule comprising a left-hand-side shape and a right-hand-side shape from a computer-aided design application via a communication layer;
receive a design comprising geometric elements from the computer-aided design application;
convert the geometric elements into a maximal element representation comprising maximal lines, maximal arcs, or maximal points by:
grouping elements on equivalent carriers;
computing an average carrier for each group; and
replacing each group with a minimal number of maximal elements having the average carrier;
compute a shape signature for the design, the shape signature comprising registration points derived from carrier intersections and registration point weights based on geometric features at each registration point;
match registration points of the left-hand-side shape to registration points of the design to compute candidate transformation matrices;
verify each candidate transformation matrix by applying the transformation to the left-hand-side shape and checking whether the transformed shape is embedded in the design; and
apply the shape rule by performing Boolean operations to subtract a transformed left-hand-side shape from the design and add a transformed right-hand-side shape to the design.

Clause 17: The non-transitory computer-readable medium of clause 16, wherein the instructions further cause the one or more processors to:
rank registration points in the left-hand-side shape and the design based on calculated weights; and
select a registration point in the left-hand-side shape that matches to a least number of registration points in the design to reduce a number of candidate transformation matrices.

Clause 18: The non-transitory computer-readable medium of clause 16, wherein the instructions further cause the one or more processors to apply a calibration mechanism comprising:
determining whether two elements are collinear within a tolerance based on angular difference and endpoint distance;
computing a calibrated carrier as a bisector of carriers where the two elements are embedded; and
projecting endpoints of the elements onto the calibrated carrier.

Clause 19: The non-transitory computer-readable medium of clause 16, wherein the instructions further cause the one or more processors to:
detect an indeterminate embedding condition based on a number of registration points in the left-hand-side shape and a type of geometric transformation;
create phantom registration points to establish a reference frame when the left-hand-side shape has insufficient registration points; and
compute the candidate transformation matrices using the phantom registration points.

Clause 20: The non-transitory computer-readable medium of clause 16, wherein the communication layer is configured to facilitate communication between a shape machine engine and the computer-aided design application, and wherein the communication layer is abstracted to support integration with different computer-aided design platforms.

Machine readable storage including machine-readable instructions, when executed, to implement a method or realize an apparatus in any of the examples of the present application.

Various techniques, or certain aspects or portions thereof, may take the form of program code (i.e., instructions) embodied in tangible media, such as floppy diskettes, CD-ROMs, hard drives, a non-transitory computer readable storage medium, or any other machine-readable storage medium wherein, when the program code is loaded into and executed by a machine, such as a computer, the machine becomes an apparatus for practicing the various techniques. In the case of program code execution on programmable computers, the computing device may include a processor, a storage medium readable by the processor (including volatile and non-volatile memory and/or storage elements), at least one input device, and at least one output device. The volatile and non-volatile memory and/or storage elements may be a RAM, an EPROM, a flash drive, an optical drive, a magnetic hard drive, or another medium for storing electronic data. The eNB (or other base station) and UE (or other mobile station) may also include a transceiver component, a counter component, a processing component, and/or a clock component or timer component. One or more programs that may implement or utilize the various techniques described herein may use an application programming interface (API), reusable controls, and the like. Such programs may be implemented in a high-level procedural or an object-oriented programming language to communicate with a computer system. However, the program(s) may be implemented in assembly or machine language, if desired. In any case, the language may be a compiled or an interpreted language, and combined with hardware implementations.

It should be understood that many of the functional units described in this specification may be implemented as one or more components, which is a term used to more particularly emphasize their implementation independence. For example, a component may be implemented as a hardware circuit comprising custom very large scale integration (VLSI) circuits or gate arrays, off-the-shelf semiconductors such as logic chips, transistors, or other discrete components. A component may also be implemented in programmable hardware devices such as field programmable gate arrays, programmable array logic, programmable logic devices, or the like.

Components may also be implemented in software for execution by various types of processors. An identified component of executable code may, for instance, comprise one or more physical or logical blocks of computer instructions, which may, for instance, be organized as an object, a procedure, or a function. Nevertheless, the executables of an identified component need not be physically located together, but may comprise disparate instructions stored in different locations that, when joined logically together, comprise the component and achieve the stated purpose for the component.

Indeed, a component of executable code may be a single instruction, or many instructions, and may even be distributed over several different code segments, among different programs, and across several memory devices. Similarly, operational data may be identified and illustrated herein within components, and may be embodied in any suitable form and organized within any suitable type of data structure. The operational data may be collected as a single data set, or may be distributed over different locations including over different storage devices, and may exist, at least partially, merely as electronic signals on a system or network. The components may be passive or active, including agents operable to perform desired functions.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another, but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein, but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

1. A system for shape computation in a computer-aided design environment, comprising:
one or more processors; and
a memory storing instructions that, when executed by the one or more processors, cause the system to:
receive, via a communication layer, a shape rule comprising a left-hand-side shape and a right-hand-side shape from a computer-aided design application;
receive, via the communication layer, a design comprising a plurality of geometric elements;
convert the plurality of geometric elements into a maximal element representation by grouping elements on equivalent carriers and computing an average carrier for each group;
derive registration points from intersections of carriers associated with the maximal element representation;
calculate a weight for each registration point based on geometric features of maximal elements intersecting at the registration point;
rank the registration points based on the calculated weights to reduce a search space for shape embedding;
compute one or more transformation matrices by matching registration points of the left-hand-side shape to registration points of the design;
determine whether the left-hand-side shape is embedded in the design under a geometric transformation defined by the one or more transformation matrices; and
apply the shape rule to the design by performing a Boolean difference operation to remove a transformed instance of the left-hand-side shape from the design and performing a Boolean union operation to add a corresponding transformed instance of the right-hand-side shape to the design.

2. The system of claim 1, wherein the communication layer is configured to perform shape rule unpacking, parameter fetching, attribute fetching, and converting model objects from the computer-aided design application to shape machine objects.

3. The system of claim 1, wherein the instructions further cause the system to apply a calibration mechanism to address precision errors in the geometric elements by projecting endpoints onto a calibrated carrier computed as a bisector of carriers where elements are embedded.

4. The system of claim 1, wherein the geometric elements comprise one or more of lines, circular arcs, and points.

5. The system of claim 1, wherein the geometric transformation comprises one of an isometry, a similarity transformation, an affine transformation, or a linear transformation.

6. The system of claim 1, wherein the instructions further cause the system to:
detect an indeterminate embedding condition when the left-hand-side shape has fewer registration points than required to derive the one or more transformation matrices for a specified transformation type;
create phantom registration points to establish a reference frame for computing the transformation; and
request user input via the communication layer to specify a value for an indeterminate transformation parameter.

7. The system of claim 1, wherein the maximal element representation comprises maximal lines, wherein each maximal line is associated with a carrier encoding geometric information and a boundary encoding an extent of the maximal line along the carrier.

8. A method for shape embedding and shape replacement in a computer-aided design system, comprising:
receiving, by one or more processors, a shape rule comprising a left-hand-side shape and a right-hand-side shape;
receiving, by the one or more processors, a design comprising a plurality of geometric elements from a computer-aided design application;
maximizing, by the one or more processors, the plurality of geometric elements by grouping elements on equivalent carriers and replacing each group with a minimal number of maximal elements;
calibrating, by the one or more processors, the maximal elements by computing an average carrier for each group and projecting element boundaries onto the average carrier;
computing, by the one or more processors, registration points at intersections of carriers associated with the maximal elements;
calculating, by the one or more processors, a weight for each registration point based on a number of hyperplanes and maximal elements intersecting at the registration point;
ranking, by the one or more processors, the registration points based on the calculated weights;
sampling, by the one or more processors, registration points from the left-hand-side shape and the design based on the ranking;
deriving, by the one or more processors, transformation matrices from the sampled registration points;
determining, by the one or more processors, whether the left-hand-side shape is embedded in the design under a transformation defined by the transformation matrices; and
applying, by the one or more processors, the shape rule by subtracting a transformed left-hand-side shape from the design and adding a transformed right-hand-side shape to the design.

9. The method of claim 8, wherein maximizing the plurality of geometric elements comprises:
checking spatial relationships between elements to determine parallelism and collinearity;
grouping elements based on the spatial relationships; and
performing a Boolean union operation with calibration to combine grouped elements into maximal elements.

10. The method of claim 8, wherein calibrating the maximal elements comprises applying tolerances for angle and distance to address precision errors caused by floating-point arithmetic.

11. The method of claim 8, wherein computing registration points comprises:
computing intersections of carriers in a shape;
calibrating the intersections to remove duplicates and average out floating-point errors; and
creating a registration point at each calibrated intersection with associated carrier information.

12. The method of claim 8, further comprising:
detecting an indeterminate embedding condition when the left-hand-side shape has insufficient registration points to derive the transformation matrices;
classifying a case of indeterminate embedding based on a number of registration points and a type of transformation; and
calculating parameter ranges for indeterminate transformation parameters.

13. The method of claim 8, wherein deriving transformation matrices comprises using a pictorial approach that decomposes high-degree calculations into multiple low-degree calculations to reduce accumulated precision errors.

14. The method of claim 8, wherein the geometric elements comprise lines, and wherein each line is associated with a carrier comprising a hyperplane equation and a boundary comprising endpoint coordinates.

15. The method of claim 8, wherein the geometric elements comprise circular arcs, and wherein calibrating the maximal elements comprises computing an average center and an average radius for a group of arcs on equivalent carriers.

16. A non-transitory computer-readable medium storing instructions that, when executed by one or more processors, cause the one or more processors to:
receive a shape rule comprising a left-hand-side shape and a right-hand-side shape from a computer-aided design application via a communication layer;
receive a design comprising geometric elements from the computer-aided design application;
convert the geometric elements into a maximal element representation comprising maximal lines, maximal arcs, or maximal points by:
grouping elements on equivalent carriers;
computing an average carrier for each group; and
replacing each group with a minimal number of maximal elements having the average carrier;
compute a shape signature for the design, the shape signature comprising registration points derived from carrier intersections and registration point weights based on geometric features at each registration point;
match registration points of the left-hand-side shape to registration points of the design to compute candidate transformation matrices;
verify each candidate transformation matrix by applying the transformation to the left-hand-side shape and checking whether the transformed shape is embedded in the design; and
apply the shape rule by performing Boolean operations to subtract a transformed left-hand-side shape from the design and add a transformed right-hand-side shape to the design.

17. The non-transitory computer-readable medium of claim 16, wherein the instructions further cause the one or more processors to:
rank registration points in the left-hand-side shape and the design based on calculated weights; and
select a registration point in the left-hand-side shape that matches to a least number of registration points in the design to reduce a number of candidate transformation matrices.

18. The non-transitory computer-readable medium of claim 16, wherein the instructions further cause the one or more processors to apply a calibration mechanism comprising:
determining whether two elements are collinear within a tolerance based on angular difference and endpoint distance;
computing a calibrated carrier as a bisector of carriers where the two elements are embedded; and
projecting endpoints of the elements onto the calibrated carrier.

19. The non-transitory computer-readable medium of claim 16, wherein the instructions further cause the one or more processors to:
detect an indeterminate embedding condition based on a number of registration points in the left-hand-side shape and a type of geometric transformation;
create phantom registration points to establish a reference frame when the left-hand-side shape has insufficient registration points; and
compute the candidate transformation matrices using the phantom registration points.

20. The non-transitory computer-readable medium of claim 16, wherein the communication layer is configured to facilitate communication between a shape machine engine and the computer-aided design application, and wherein the communication layer is abstracted to support integration with different computer-aided design platforms.
